(19) United States
(12) Patent Application Publication
(10) Pub. No.: US 2023/0022263 A1
(43) Pub. Date: Jan. 26, 2023

(54) N-TYPE DOPANTS FOR PHOTOACTIVE REGIONS OF ORGANIC PHOTOVOLTAICS

(71) Applicant: King Abdullah University of Science and Technology, Thuwal (SA)

(72) Inventors: Thomas ANTHOPOULOS, Thuwal (SA); Mohamad Insan NUGRAHA, Thuwal (SA); Yuliar FIRDAUS, Thuwal (SA); Yuanbao LIN, Thuwal (SA)

(21) Appl. No.: 17/772,397

(22) PCT Filed: Oct. 28, 2020
(86) PCT No.: PCT/IB2020/060092

§ 371 Date: Apr. 27, 2022

Related U.S. Application Data
(60) Provisional application No. 62/926,744, filed on Oct. 28, 2019.

(51) Int. Cl. H01L 51/42; H01L 51/00

(52) U.S. Cl. CPC H01L 51/4253; H01L 51/0067; H01L 51/0072; H01L 51/0059

(57) ABSTRACT

Embodiments include photoactive regions of organic photovoltaic cells including an n-type dopant or a mixture of n-type dopants, one or more electron donor materials, and one or more electron acceptor materials. Embodiments further include n-type dopants, photoactive regions of organic photovoltaics comprising n-type dopants, methods of preparing photoactive regions comprising n-type dopants, organic photovoltaics comprising n-type doped photoactive regions, and the like.

### BACKGROUND OF THE INVENTION

Organic photovoltaics (OPVs) are a promising solar energy-harvesting technology that are light weight and have mechanical flexibility, with the potential for low manufacturing cost due to their broad compatibility with large-area processing techniques, among numerous attractive attributes. In recent years, significant effort has been dedicated to the design of new materials with improved charge carrier mobility, optimized light absorption characteristics, and carefully tuned bulk-heterojunction (BHJ) microstructures. As a result, power conversion efficiency (PCE) values in excess of 18% and 17% for single-junction and tandem OPVs, respectively, have been recently achieved. Despite such progress, the aforementioned levels of performance are still lower than the predicted PCE limits, which are predicted to surpass 20% and 25% for single-junction and tandem OPV cells, respectively. Continuous development of new materials with simultaneous optimization of the device through engineering are examples of approaches presently being pursued for improving the OPV performance with the ultimate aim of reaching the theoretically predicted PCE limits.

The intentional introduction of molecular dopants has been used extensively to enhance the charge transport properties of organic semiconductors, particularly in the field of organic thin-film transistors (OTFTs) for which some of the highest carrier mobilities have been enabled via doping. Molecular doping relies on charge transfer interaction(s) between the dopant and the host semiconductor, which ultimately results in the formation of free carriers. In the field of OPVs, intentional p-type doping of the charge-transporting interlayers has been studied and shown to be a viable strategy to enhance the cell's PCE by improving the efficiency of carrier extraction from the photoactive layer. However, the introduction of molecular dopants directly into the active layer of OPVs has received significantly less attention, often leading to different conclusions, while also being limited to p-type dopants. Irrespective of the exact mechanism and the doping approaches adopted, ample opportunity thus exists to explore n-type dopants and examine their suitability for OPV applications.

### SUMMARY OF THE INVENTION

In a first aspect, photoactive regions of organic photovoltaic cells are provided. The photoactive regions can comprise n-type dopants combined with one or more of electron acceptor materials, electron donor materials, hole-scavenging materials, solvents, and additives. The n-type dopants can be provided with any one of the aforementioned materials in any combination, in a single layer or in multiple layers, to form bulk-heterojunctions, mixed heterojunctions, planar-heterojunctions, hybrid planar-mixed heterojunctions, and the like.

In embodiments, the n-type dopants may be represented by formula I:

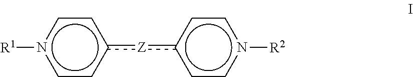

where:

[symbol] is a single or double bond;

Z is nothing, substituted or unsubstituted carboaryl, substituted or unsubstituted heteroaryl, substituted or unsubstituted alkenyl, substituted or unsubstituted cycloalkylene, or substituted or unsubstituted alkynylene;

R¹ and R² may be identical or different and each may be independently selected from a lone pair of electrons, hydrogen atom, substituted or unsubstituted alkyl, substituted or unsubstituted cycloalkyl, substituted or unsubstituted aryl, substituted or unsubstituted aralkyl, substituted or unsubstituted alkaryl, and substituted or unsubstituted heteroaryl.

In embodiments, the n-type dopants may be represented by formula II:

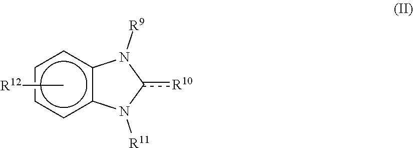

where:

[symbol] is a single or double bond;

R⁹ and R¹¹ may be identical or different and each may be independently selected from nothing, hydrogen, and substituted or unsubstituted alkyl;

R¹⁰ is a substituted or unsubstituted aryl or substituted or unsubstituted heteroaryl; and

R¹² is nothing or a substituent.

In embodiments, the n-type dopant may be represented by formula III:

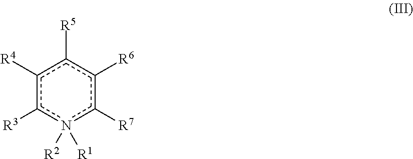

where:

[symbol] is a single or double bond;

each of R¹ to R⁷ is independently a hydrogen, a substituted or unsubstituted C₁ to C₄ alkyl, or an amine, and/or at least two of R¹ to R⁷ bind with each other to form a 5- or 6-membered fused ring structure, wherein the 5- or 6-membered fused ring structure is optionally substituted, optionally comprises one or more nitrogen heteroatoms, and is optionally fused to one or more additional aliphatic or aromatic 5- or 6-membered ring structures, each ring structure optionally comprising one or more nitrogen heteroatoms and optionally comprising one or more substituents.

In another aspect, methods of preparing photoactive regions comprising the n-type dopants and/or their derivatives are provided. Non-limiting examples of suitable methods include solution doping, solvent-immersion doping, vapor doping, thermal-evaporation doping, variations thereof, combinations thereof, and the like.

In further aspects, organic photovoltaic cells are provided. The organic photovoltaic cells comprise photoactive regions in which one or more of the n-type dopants disclosed herein and/or their derivatives are combined with one or more of electron acceptor materials, electron donor materials, hole-scavenging materials, solvents, additives, and the like. The organic photovoltaic cells can be configured in any of a multitude of architectures, including, but not limited to, the following: organic photovoltaic cells with bulk-heterojunction normal structures; organic photovoltaic cells with planar-heterojunction normal structures; organic photovoltaic cells with bulk-heterojunction inverted structures; organic photovoltaic cells with planar-heterojunction inverted structures; organic photovoltaic cells with tandem normal structures; and organic photovoltaic cells with tandem inverted structures, and the like.

The details of one or more examples are set forth in the description below. Other features, objects, and advantages will be apparent from the description and from the claims.

### BRIEF DESCRIPTION OF THE DRAWINGS

This written disclosure describes illustrative embodiments that are non-limiting and non-exhaustive. In the drawings, which are not necessarily drawn to scale, like numerals describe substantially similar components throughout the several views. Like numerals having different letter suffixes represent different instances of substantially similar components. The drawings illustrate generally, by way of example, but not by way of limitation, various embodiments discussed in the present document.

Reference is made to illustrative embodiments that are depicted in the figures, in which:

FIG. 1 is a schematic diagram of an organic photovoltaic cell, according to one or more embodiments of the present disclosure.

FIGS. 2A-2B are schematic diagrams of organic photovoltaic cells with (A) a normal structure and (B) an inverted structure, according to one or more embodiments of the present disclosure.

FIGS. 3A-3C are schematic diagrams of organic photovoltaic cells with (A) a normal tandem structure, (B) an inverted tandem structure, and (C) an organic/silicon tandem structure, according to one or more embodiments of the present disclosure.

FIGS. 4A-4B are schematic diagrams of organic photovoltaic devices, according to one or more embodiments of the present disclosure.

FIGS. 5A-5E show (A) the chemical structures of PM6, IT-4F, and benzyl viologen (BV); (B) the schematics illustrating the process of BV doping into BHJ film; (C) energy level diagram of BV, IT-4F, and other acceptors; the work-functions (WF) were measured using the Kelvin probe in the glove box; (D) relative electron paramagnetic resonance (EPR) spectra of various films with or without BV; and (E) absorption coefficient profiles of PM6:IT-4F blend films doped with different weight ratios of BV, according to one or more embodiments of the present disclosure.

FIGS. 6A-6F show (A)-(E) photoelectron spectroscopy in air (PESA) measurement of certain electron-acceptor materials; and (F) the chemical structure and highest occupied molecular orbital (HOMO) orbitals of BV molecule calculated via density functional theory (DFT), respectively, (C: gray, H: white, N: blue spheres), according to one or more embodiments of the present disclosure.

FIGS. 7A-7B show absorption profiles of neat (A) PM6 and (B) IT-4F films doped with 0 wt. %, 0.4 wt. % and 0.004 wt. % BV, according to one or more embodiments of the present disclosure.

FIGS. 8A-8D show (A) J-V curves of OPV cells based on PM6:IT-4F doped with different weight ratios of BV; and external quantum efficiency (EQE), internal quantum efficiency (IQE), reflectance, and parasitic absorption spectra of OPV cells based on PM6:IT-4F doped with (B) 0 wt. %, (C) 0.4 wt. % and (D) 0.004 wt. % weight of BV, according to one or more embodiments of the present disclosure.

FIGS. 9A-9F show (A) J-V characteristics of the PM6:IT-4F BHJ cells before and after BV doping at two different weight ratios; the inset shows the schematic of the cell's architecture; (B) EQE and (C) IQE spectra of the OPV cells; (D) light intensity dependence of short-circuit current density (J_{SC}) measured for the same cells; (E) bimolecular recombination rate constant (k_{rec}) inferred from charge carrier lifetime (z) and charge carrier density (n), as a function of n; and (F) the 1000 hours lifetime results of the OPVs based on PM6:IT-4F with continuous testing in a dry nitrogen glove box, according to one or more embodiments of the present disclosure.

FIGS. 10A-10F show experimental dark current densities as a function of voltage for (A)-(C) hole-only devices and (D)-(F) electron-only devices made with blend films of PM6:IT-4F doped with 0 wt. % (w/o), 0.4 wt. % 0.004 wt. % BV; the experimental data were fitted using the single carrier space-charge limited current (SCLC) model as described herein, according to one or more embodiments of the present disclosure.

FIGS. 11A-11F show J-V curves vs. light intensity for OPV cells doped with (A) 0 wt. %, (B) 0.4 wt. %, and (C) 0.004 wt. %; (D) charge carrier density vs. light intensity, and (E) charge carrier lifetime (z); and (F) charge carrier lifetime (z) vs. charge carrier density, according to one or more embodiments of the present disclosure.

FIGS. 12A-12C show component dynamics as extracted by the multivariate curve resolution alternating least-squares analysis (MCR-ALS) analysis for excitons and charge carriers at different fluences for: (A) 0 wt. %, (B) 0.4 wt. %, and (C) 0.004 wt. % BV, according to one or more embodiments of the present disclosure.

FIGS. 13A-13G show topography atomic force microscopy (AFM) images of PM6:IT-4F BHJ layers doped with (A) 0 wt. %, (B) 0.4 wt. %, and (C) 0.004 wt. % BV (scale bar: 1 m); (D)-(F) topography AFM images with colour bar corresponding in (A)-(C); and (G) surface height histograms extracted from the AFM images in (A)-(C), according to one or more embodiments of the present disclosure.

FIGS. 14A-14C show transmission electron microscopy (TEM) images of PM6:IT-4F (1:1, w/w) doped with: (A) 0 wt. % (w/o), (B) 0.004 wt. % and (C) 0.4 wt. % of BV, according to one or more embodiments of the present disclosure.

FIGS. 15A-15B show (A) 2-D Grazing-Incidence Wide-Angle X-ray Scattering (GIWAXS) images of the neat PM6 and neat IT-4F films; and (B) In-plane and out-of-plane line cut profiles, according to one or more embodiments of the present disclosure.

FIGS. 16A-16D show (A) 2-D GIWAXS images of the PM6:IT-4F films doped with 0 wt. %, 0.4 wt. %, and 0.004 wt. % BV; and (B)-(D) in-plane and out-of-plane line cut profiles, according to one or more embodiments of the present disclosure.

FIGS. 17A-17C show (A) chemical structures of PM6, Y6, and PC₇₁BM, (B) J-V curves, and (C) EQE curves of OPV cells based on PM6:Y6:PC₇₁BM doped with different weight ratios of BV, according to one or more embodiments of the present disclosure.

FIGS. 18A-18C show (A) chemical structures of PM6 and Y6, (B) J-V curves, and (C) EQE curves of OPV cells based on PM6:Y6 doped with different weight ratios of BV, according to one or more embodiments of the present disclosure.

FIGS. 19A-19C show (A) chemical structures of PM6 and IT-2Cl, (B) J-V curves, and (C) EQE curves of OPV cells based on PM6:IT-2Cl doped with different weight ratios of BV, according to one or more embodiments of the present disclosure.

FIGS. 20A-20C show (A) chemical structures of PTB7-Th and EH-IDTBR, (B) J-V curves, and (C) EQE curves of OPV cells based on PTB7-Th:EH-IDTBR doped with different weight ratios of BV, according to one or more embodiments of the present disclosure.

FIGS. 21A-21C show (A) chemical structures of PTB7-Th and PC₇₁BM, (B) J-V curves, and (C) EQE curves of OPV cells based on PTB7-Th:PC₇₁BM doped with different weight ratios of BV, according to one or more embodiments of the present disclosure.

FIGS. 22A-22C show (A) a summary of the PCE values of different BHJ systems doped with different weight ratios of BV (ªthe optimal BV concentration for the PTB7-Th:EH-IDTBR and PTB7-Th:PC₇₁BM systems was 0.002 wt. %); (B) J-V curves of OPVs based on PM6:Y6 and PM6:Y6:PC₇₁BM systems before and after doping with 0.004 wt. % BV; and (C) a comparison of reported PCE values for OPVs based on p-doped BHJ layers, according to one or more embodiments of the present disclosure.

FIG. 23 show chemical structures of diquat (DQ), ethyl viologen (EV), and (4-(1,3-dimethyl-2,3-dihydro-1H-benzoimidazol-2-yl)phenyl) dimethylamine (N-DMBI), according to one or more embodiments of the present disclosure.

FIGS. 24A-24B show (A) J-V curves and (B) EQE curves of OPV cells based on PM6:IT-4F doped with different weight ratios of DQ, according to one or more embodiments of the present disclosure.

FIG. 25 shows J-V curves of OPV cells based on PM6:Y6:PC₇₁BM doped with different weight ratios of DQ, according to one or more embodiments of the present disclosure.

FIG. 26 shows J-V curves of OPV cells based on PM6:IT-4F doped with different weight ratios of EV, according to one or more embodiments of the present disclosure.

FIG. 27 shows J-V curves of OPV cells based on PM6:IT-4F doped with different weight ratios of N-DMBI, according to one or more embodiments of the present disclosure.

### DETAILED DESCRIPTION

### Definitions

The terms recited below have been defined as described below. All other terms and phrases in this disclosure shall be construed according to their ordinary meaning as understood by one of skill in the art.

As used herein, the term “organic photovoltaic” or “OPV” refers to any cell, assembly of cells, or device that uses conductive organic materials for light absorption and/or charge transport. Examples of suitable organic materials include, but are not limited to, polymers, small molecules, oligomers, and monomers. Organic solar cells are an example of OPVs.

As used herein, the term “photoactive region” refers to a region of an OPV comprising one or more materials that can absorb photons or light to produce excitons.

As used herein, a material is referred to as an “electron donor material” or “donor material” when the charge carriers, which can be formed as a result of light absorption and charge separation at a heterojunction, are transported within the material in the form of holes. The term “donor material” thus includes materials having holes as the majority current or charge carriers. A material is referred to as an “electron acceptor material” or “acceptor material” when the charge carriers, which similarly can be formed as a result of light absorption and charge separation at a heterojunction, are transported within the material in the form of electrons. The term “acceptor material” thus includes materials having electrons as the majority current or charge carriers.

As used herein, the term “heterojunction” generally refers to any interface region between an electron acceptor material and electron donor material.

As used herein, the term “planar-heterojunction” refers to a heterojunction between an electron acceptor material and electron donor material when the interface between the electron acceptor material and electron donor material is formed between the two substance layers, namely one layer of the electron acceptor material and one layer of the electron donor material, e.g., in a bilayer configuration

As used herein, the term “bulk-heterojunction” refers to a photoactive region of an organic photovoltaic cell, in which an electron acceptor material and electron donor material are blended or at least partially mixed, such that the interface between the electron donor material and electron acceptor material comprises a multitude of interface sections distributed over the volume of the material. For example, a bulk-heterojunction can have a single continuous interface between the electron donor material and the electron acceptor material, although multiple interfaces typically exist in actual devices. Mixed and bulk-heterojunctions can have multiple donor-acceptor interfaces as a result of having plural domains of material. A distinction between a mixed and a bulk-heterojunction lies in degrees of phase separation between donor and acceptor materials. In a mixed heterojunction, there is very little or no phase separation (the domains are very small, e.g. less than a few nanometers), whereas in a bulk heterojunction, there is significant phase separation (e.g., forming domains with sizes of a few nanometers to 100 nm).

As used herein, “mobility” refers to a measure of the velocity with which charge carriers, for example, holes (or units of positive charge) and electrons (or units of negative charge), move through a material, optionally under the influence of an electric field.

As used herein, the “fill factor (FF)” of a solar cell is the ratio (given as a percentage) of the actual maximum obtainable power, (Pₘ or Vₘₚ*Jₘₚ), to the theoretical (not actually obtainable) power, (J_{sc}*V_{oc}). Accordingly, FF can be determined using the equation:

FF=(Vₘₚ*Jₘₚ)/(J_{sc}*V_{oc})

where Jₘₚ and Vₘₚ represent the current density and voltage at the maximum power point (Pₘ), respectively, this point being obtained by varying the resistance in the circuit until JV is at its greatest value; and J_{sc}, and V_{oc} represent the short circuit current and the open circuit voltage, respectively. Fill factor is considered a key parameter in evaluating the performance of solar cells.

As used herein, the “open-circuit voltage (V_{oc})” of a solar cell is the difference in the electrical potentials between the anode and the cathode of the solar cell when there is no external load connected.

As used herein, the “power conversion efficiency (PCE)” of a solar cell is the percentage of power converted from absorbed light to electrical energy. The PCE of a solar cell can be calculated by dividing the maximum power point (Pₘ) by the input light irradiance (E, in W/m²) under standard test conditions (STC) and the surface area of the solar cell (A_{c} in m²). STC typically, but not exclusively, refers to a temperature of 25° C. and an irradiance of 1000 W/m² with an air mass 1.5 (AM 1.5) spectrum.

As used herein, “solution-processable” refers to compounds (e.g., polymers), materials, or compositions that can be used in various solution-phase processes including spin-coating, printing (e.g., inkjet printing, gravure printing, offset printing, and the like), spray coating, electrospray coating, drop casting, dip coating, blade coating, and the like.

As used herein, “heteroatom” means an atom of any element other than carbon or hydrogen. Examples of heteroatoms include nitrogen, oxygen, boron, phosphorus, and sulfur. As discussed herein, heteroatoms, such as nitrogen, may have hydrogen substituents and/or any permissible substituents of organic compounds described herein which satisfy the valences of the heteroatoms.

The term “aliphatic” when used without the “substituted” modifier signifies that the compound/group so modified is an acyclic or cyclic, but non-aromatic hydrocarbon compound or group. When the term is used with the “substituted” modifier one or more hydrogen atom has been independently replaced by any of the substituents disclosed herein.

As used herein, the term “alkyl” refers to a straight- or branched-chain or cyclic hydrocarbon radical or moiety comprising only carbon and hydrogen atoms, containing no unsaturation, and having 30 or fewer carbon atoms. The term “cycloalkyl” refers to aliphatic cyclic alkyls having 3 to 10 carbon atoms in single or multiple cyclic rings, preferably 5 to 6 carbon atoms in a single cyclic ring. Non-limiting examples of suitable alkyl groups include methyl group, ethyl group, propyl group, isopropyl group, cyclopropyl group, butyl group, isobutyl group, sec-butyl group, tert-butyl group, cyclobutyl group, pentyl group, neo-pentyl group, cyclopentyl group, hexyl group, cyclohexyl group, 2-ethylhexyl, cyclohexylmethyl group, heptyl group, octyl group, nonyl group, decyl group, dodecyl group, tridecyl group, tetradcyl group, pentadecyl group, hexadecyl group, heptadecyl group, octadecyl group, nonadecyl group, cyclopentyl group, cyclohexyl group, and the like. Additional examples of cycloalkyl groups include cyclopropyl, cyclobutyl, cyclopentyl, cyclohexyl, cycloheptyl, cyclopentenyl, cyclohexenyl, cyclohexadienyl, cycloheptatrienyl, norbornyl, norpinyl, norcaryl, adamantyl, and spiro[4.5]decanyl groups, as well as their homologs, isomers, and the like. Preferably, the alkyl group is selected from methyl group, ethyl group, butyl group, helptyl group, octadecyl group, and the like. Alkyls can be substituted or unsubstituted. When the term is used with the “substituted” modifier, one or more hydrogen atoms has been independently replaced by any of the substituents disclosed herein.

As used herein, the term “heteroalkyl” refers to an alkyl as defined above having at least one carbon atom replaced by a heteroatom. Non-limiting examples of suitable heteroatoms include nitrogen, oxygen, and sulfur. Examples of cycloheteroalkyl groups include, among others, morpholinyl, thiomorpholinyl, pyranyl, imidazolidinyl, imidazolinyl, oxazolidinyl, pyrazolidinyl, pyrazolinyl, pyrrolidinyl, pyrrolinyl, tetrahydrofuranyl, tetrahydrothiophenyl, piperidinyl, piperazinyl, and the like. Heteroalkyls can be substituted or unsubstituted. When the term is used with the “substituted” modifier, one or more hydrogen atoms has been independently replaced by any of the substituents disclosed herein, or a substituent is bonded to a heteroatom, or both.

As used herein, the term “alkenyl” refers to a straight- or branched-chain hydrocarbon radical or moiety comprising only carbon and hydrogen atoms and having at least one carbon-carbon double bond, which can be internal or terminal. Non-limiting examples of alkenyl groups include: —CH═CH₂ (vinyl), —CH═CHCH₃, —CH═CHCH₂CH₃, —CH₂CH═CH₂ (allyl), —CH₂CH═CHCH₃, —CH═CH—C₆H₅, —CH═CH—, —CH═C(CH₃)CH₂—, and —CH═CHCH₂—. The groups, —CH═CHF, —CH═CHCl, —CH═CHBr, and the like. Examples of alkenyl groups include ethenyl, propenyl, butenyl, pentenyl, hexenyl, butadienyl, pentadienyl, hexadienyl groups, and the like. Alkenyls can be substituted or unsubstituted. When the term is used with the “substituted” modifier, one or more hydrogen atoms has been independently replaced by any of the substituents disclosed herein.

As used herein, the term “alkynyl” refers to a straight- or branched-chain hydrocarbon radical or moiety comprising only carbon and hydrogen atoms and having at least one carbon-carbon triple bond, which can be internal or terminal. The groups —C≡CH, —C≡CCH₃, and —CH₂C≡CCH₃, are non-limiting examples of alkynyl groups. Examples of alkynyl groups include ethynyl, propynyl, butynyl, pentynyl, hexynyl, and the like. Alkynes can be substituted or unsubstituted. When the term is used with the “substituted” modifier, one or more hydrogen atoms has been independently replaced by any of the substituents disclosed herein.

As used herein, the term “aryl” refers to a monocyclic or polycyclic aromatic hydrocarbon radical or moiety comprising only carbon and hydrogen atom, wherein the carbon atoms form an aromatic ring structure. If more than one ring is present, the rings may be fused or not fused, or bridged. The term does not preclude the presence of one or more alkyl groups attached to the first aromatic ring or any additional aromatic ring present. The point of attachment can be through an aromatic carbon atom in the ring structure or a carbon atom of an alkyl group attached to the ring structure. Non-limiting examples of aryl groups include phenyl (Ph), toyl, xylyl, methylphenyl, (dimethyl)phenyl, —C₆H₄—CH₂CH₃ (ethylphenyl), naphthyl, and the monovalent group derived from biphenyl. Further examples of aryl groups having only aromatic carbocyclic ring(s) include phenyl, 1-naphthyl (bicyclic), 2-naphthyl (bicyclic), anthracenyl (tricyclic), phenanthrenyl (tricyclic), pentacenyl (pentacyclic), and like groups. Examples of polycyclic ring systems in which at least one aromatic carbocyclic ring is fused to one or more cycloalkyl and/or cycloheteroalkyl rings include, among others, benzo derivatives of cyclopentane (i.e., an indanyl group, which is a 5,6-bicyclic cycloalkyl/aromatic ring system), cyclohexane (i.e., a tetrahydronaphthyl group, which is a 6,6-bicyclic cycloalkyl/aromatic ring system), imidazoline (i.e., a benzimidazolinyl group, which is a 5,6-bicyclic cycloheteroalkyl/aromatic ring system), and pyran (i.e., a chromenyl group, which is a 6,6-bicyclic cycloheteroalkyl/aromatic ring system). Other examples of aryl groups include benzodioxanyl, benzodioxolyl, chromanyl, indolinyl groups, and the like. When the term is used with the “substituted” modifier, one or more hydrogen atoms has been independently replaced by any of the substituents disclosed herein.

As used herein, the term “heteroaryl” refers to an aryl having at least one aromatic carbon atom in the ring structure replaced by a heteroatom. Non-limiting examples of suitable heteroatoms include nitrogen, oxygen, and sulfur. The term does not preclude the presence of one or more alkyl groups attached to the first aromatic ring or any additional aromatic ring present. The point of attachment can be through an aromatic carbon atom or aromatic heteroatom in the aromatic ring structure or a carbon atom of an alkyl group attached to the aromatic ring structure. Non-limiting examples of heteroaryl groups include furanyl, benzofuranyl, isobenzylfuranyl, imidazolyl, indolyl, isoindolyl, indazolyl, methylpyridyl, oxazolyl, pyridyl, pyrrolyl, pyrimidyl, pyrazinyl, quinolyl, quinazolyl, quinoxalinyl, thienyl, and triazinyl. Additional examples of heteroaryl groups include, for example, the 5- or 6-membered monocyclic and 5-6 bicyclic ring systems shown below:

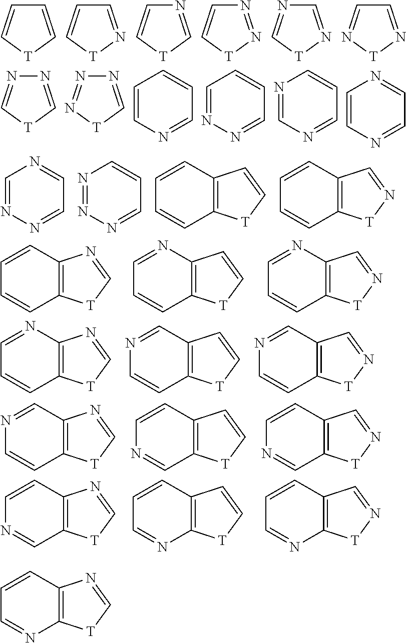

wherein T is O, S, NH, N-alkyl, N-aryl, N-(arylalkyl) (e.g., N-benzyl), SiH₂, SiH(alkyl), Si(alkyl)₂, SiH(arylalkyl), Si(arylalkyl)₂, or Si(alkyl)(arylalkyl). Examples of such heteroaryl rings include pyrrolyl, furyl, thienyl, pyridyl, pyrimidyl, pyridazinyl, pyrazinyl, triazolyl, tetrazolyl, pyrazolyl, imidazolyl, isothiazolyl, thiazolyl, thiadiazolyl, isoxazolyl, oxazolyl, oxadiazolyl, indolyl, isoindolyl, benzofuryl, benzothienyl, quinolyl, 2-methylquinolyl, isoquinolyl, quinoxalyl, quinazolyl, benzotriazolyl, benzimidazolyl, benzothiazolyl, benzisothiazolyl, benzisoxazolyl, benzoxadiazolyl, benzoxazolyl, cinnolinyl, IH-indazolyl, 2H-indazolyl, indolizinyl, isobenzofuyl, naphthyridinyl, phthalazinyl, pteridinyl, purinyl, oxazolopyridinyl, thiazolopyridinyl, imidazopyridinyl, furopyridinyl, thienopyridinyl, pyridopyrimidinyl, pyridopyrazinyl, pyridopyridazinyl, thienothiazolyl, thienoxazolyl, thienoimidazolyl groups, and the like. Further examples of heteroaryl groups include 4,5,6,7-tetrahydroindolyl, tetrahydroquinolinyl, benzothienopyridinyl, benzofuropyridinyl groups, and the like. Heteroaryls can be substituted or unsubstituted. When the term is used with the “substituted” modifier, one or more hydrogen atoms has been independently replaced by any of the substituents disclosed herein, or a substituent is bonded to a heteroatom, or both.

As used herein, the term “aralkyl” refers to an alkyl having at least one hydrogen atom replaced by an aryl or heteroaryl group. Non-limiting examples of aralkyls are: phenylmethyl (benzyl, Bn) and 2-phenyl-ethyl. The point of attachment can be through a carbon atom of the alkyl group or through an aromatic carbon atom or aromatic heteroatom in the aromatic ring structure of the aryl or heteroaryl group attached to the alkyl group. Aralkyls can be substituted or unsubstituted. When the term is used with the “substituted” modifier, one or more hydrogen atoms has been independently replaced by any of the substituents disclosed herein, or a substituent is bonded to a heteroatom, or both.

As used herein, the term “alkaryl” refers to an aryl or heteroaryl having at least one hydrogen atom replaced by an alkyl or heteroalkyl group. The point of attachment can be an aromatic carbon atom or aromatic heteroatom in the aromatic ring structure or a carbon atom of an alkyl group attached to the ring structure. Alkaryls can be substituted or unsubstituted. When the term is used with the “substituted” modifier, one or more hydrogen atoms has been independently replaced by any of the substituents disclosed herein, or a substituent is bonded to a heteroatom, or both.

As used herein, the term “haloaryl” refers to an aryl or heteroaryl having at least one hydrogen atom replaced by a halogen. The point of attachment can be an aromatic carbon atom or aromatic heteroatom in the aromatic ring structure or a carbon atom of an alkyl group attached to the ring structure. Haloaryls can be substituted or unsubstituted. When the term is used with the “substituted” modifier, one or more hydrogen atoms has been independently replaced by any of the substituents disclosed herein, or a substituent is bonded to a heteroatom, or both.

As used herein, the term “alkoxy” refers to the group —OR, wherein R is an alkyl or heteroalkyl group. Non-limiting examples of alkoxy groups include: —OCH₃, —OCH₂CH₃, —OCH₂CH₂CH₃, —OCH(CH₃)₂, —OCH(CH₂)₂, —OC₃H₆, —OC₄H₈, —OC₅H₁₀, —OC₆H₁₂, —OCH₂C₃H₆, —OCH₂C₄H₈, —OCH₂C₅H₁₀, —OCH₂C₆H₁₂, and the like. The terms “alkenyloxy”, “alkynyloxy”, “aryloxy”, “aralkoxy”, “heteroaryloxy”, and “acyloxy” refer to the group —OR, wherein R is an alkenyl, alkynyl, aryl, aralkyl, heteroaryl, or acyl group, respectively. Examples include without limitation aryloxy groups such as —O-Ph and aralkoxy groups such as —OCH₂-Ph (—OBn) and —OCH₂CH₂-Ph. Alkoxys, alkenyloxys, alkynyloxys, aryloxys, aralkoxys, heteroaryloxys, and acyloxys can each be substituted or unsubstituted. When those terms are used with the “substituted” modifier, one or more hydrogen atoms has been independently replaced by any of the substituents disclosed herein, or a substituent is bonded to a heteroatom, or both.

As used herein, the term “acyl” refers to the group —C(O)R, wherein R is a hydrogen, alkyl, aryl, aralkyl, or heteroaryl group. Non-limiting examples of acyl groups include: —CHO, —C(O)CH₃ (acetyl, Ac), —C(O)CH₂CH₃, —C(O)CH₂CH₂CH₃, —C(O)CH(CH₃)₂, —C(O)CH(CH₂)₂, —C(O)C₆H₅, —C(O)C₆H₄—CH₃, —C(O)CH₂C₆H₅, and —C(O)(imidazolyl). The groups, —C(O)CH₂CF₃, —CO₂H (carboxyl), —CO₂CH₃ (methylcarboxyl), —CO₂CH₂CH₃, —C(O)NH₂ (carbamoyl), and —CON(CH₃)₂, are non-limiting examples of substituted acyl groups.

As used herein, “amine” and “amino” (and its protonated form) are art-recognized and refer to both unsubstituted and substituted amines, e.g., a moiety that can be represented by the general formula NRR′R″, represented by the structure:

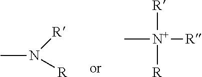

wherein R, R′, and R″ each independently represent a hydrogen, a heteroatom, an alkyl, a heteroalkyl, an alkenyl, —(CH₂)ₘ—Rc or R and R′ taken together with the N atom to which they are attached complete a heterocycle having from 4 to 8 atoms in the ring structure; Rc represents an aryl, a cycloalkyl, a cycloalkenyl, a heterocycle or a polycycle; and m is zero or an integer in the range of 1 to 8, and substituted versions thereof.

The term “alkylamino” when used without the “substituted” modifier refers to the group —NHR, in which R is an alkyl, as that term is defined above. Non-limiting examples of alkylamino groups include: —NHCH₃ and —NHCH₂CH₃. The term “dialkylamino” when used without the “substituted” modifier refers to the group —NRR′, in which R and R′ can be the same or different alkyl groups, or R and R′ can be taken together to represent an alkanediyl. Non-limiting examples of dialkylamino groups include: —N(CH₃)₂, —N(CH₃)(CH₂CH₃), and N-pyrrolidinyl. The terms “alkoxyamino”, “alkenylamino”, “alkynylamino”, “arylamino”, “aralkylamino”, “heteroarylamino”, and “alkylsulfonylamino” when used without the “substituted” modifier, refers to groups, defined as —NHR, in which R is alkoxy, alkenyl, alkynyl, aryl, aralkyl, heteroaryl, and alkylsulfonyl, respectively. A non-limiting example of an arylamino group is —NHC₆H₅. The term “amido” (acylamino), when used without the “substituted” modifier, refers to the group —NHR, in which R is acyl, as that term is defined above. A non-limiting example of an amido group is —NHC(O)CH₃. The term “alkylimino” when used without the “substituted” modifier refers to the divalent group ═NR, in which R is an alkyl, as that term is defined above. When any of these terms is used with the “substituted” modifier one or more hydrogen atom has been independently replaced by —OH, —F, —Cl, —Br, —I, —NH₂, —NO₂, —CO₂H, —CO₂CH₃, —CN, —SH, —OCH₃, —OCH₂CH₃, —C(O)CH₃, —N(CH₃)₂, —C(O)NH₂ or —OC(O)CH₃. The groups —NHC(O)OCH₃ and —NHC(O)NHCH₃ are non-limiting examples of substituted amido groups.

As used herein, the terms “halide,” “halo,” and “halogen” refer to —F, —Cl, —Br, or —I.

As used herein, the term “substituent” and “substituted” refers to all permissible substituents of the compounds described herein. In the broadest sense, the permissible substituents include acyclic and cyclic, branched and unbranched, carbocyclic and heterocyclic, aromatic and nonaromatic substituents of organic compounds. Examples of substituents include, without limitation, nothing, alkyl, substituted alkyl, cycloalkyl, substituted cycloalkyl, heteroalkyl, substituted heteroalkyl, alkenyl, substituted alkenyl, alkynyl, substituted alkynyl, aryl, substituted aryl, heteroaryl, substituted heteroaryl, aralkyl, substituted aralkyl, alkaryl, substituted alkaryl, haloaryl, substituted haloaryl, alkoxy, substituted alkoxy, alkenyloxy, substituted alkenyloxy, alkynyloxy, substituted alkynyloxy, aryloxy, substituted aryloxy, aralkoxy, substituted aralkoxy, heteroaryloxy, substituted heteroaryloxy, acyloxy, substituted acyloxy, acyl, substituted acyl, halo (—F, —Cl, —Br, —I, etc.), hydrogen (—H), carboxyl (—COOH), hydroxy (—OH), oxo (═O), hydroxyamino (—NHOH), nitro (—NO₂), cyano (—CN), isocyanate (—N═C═O), azido (—N₃), phosphate (e.g., —OP(O)(OH)₂, —OP(O)(OH)O—, deprotonated forms thereof, etc.), mercapto (—SH), thio (═S), thioether (═S—), sulfonamido (—NHS(O)₂—), sulfonyl (—S(O)₂—), sulfinyl (—S(O)₂—), any combinations thereof, and the like.

Additional examples of substituents include, but are not limited to, —NC, —S(R⁰)₂⁺, —N(R⁰)₃⁺, —SO₃H, —SO₂R⁰, —SO₃R⁰, —SO₂NHR⁰, —SO₂N(R⁰)₂, —COR⁰, —COOR⁰, —CONHR⁰, CON(R⁰)₂, C₁₋₄₀ haloalkyl groups, C₆₋₁₄ aryl groups, and 5-14 membered electron-poor heteroaryl groups; where R⁰ is a C₁₋₂₀ alkyl group, a C₂₋₂₀ alkenyl group, a C₂₋₂₀ alkynyl group, a C₁₋₂₀ haloalkyl group, a C₁₋₂₀ alkoxy group, a C₆₋₁₄ aryl group, a C₃₋₁₄ cycloalkyl group, a 3-14 membered cycloheteroalkyl group, and a 5-14 membered heteroaryl group, each of which can be optionally substituted as described herein. Additional examples of substituents include, but are not limited to, —OR⁰, —NH₂, —NHR⁰, —N(R⁰)₂, and 5-14 membered electron-rich heteroaryl groups, where R⁰ is a C₁₋₂₀ alkyl group, a C₂₋₂₀ alkenyl group, a C₂₋₂₀ alkynyl group, a C₆₋₁₄ aryl group, or a C₃₋₁₄ cycloalkyl group.

### N-Type Dopants

In one aspect of the present invention, n-type dopants are disclosed herein that can be incorporated into a photoactive region of an organic photovoltaic cell. It was surprisingly discovered that the n-type dopants, when incorporated into photoactive regions, consistently improved the performance of organic photovoltaic cells. For example, organic photovoltaic cells with a photoactive region comprising an n-type dopant, electron donor material, and electron acceptor material, among other things, consistently observed improved charge generation, charge transport, charge extraction efficiency, reduced carrier recombination losses, and increased power conversion efficiencies. As will be discussed below, numerous n-type dopants were found to improve and enhance the performance of the organic photovoltaic cell.

A viologen compound is an example of a suitable n-type dopant in accordance with the present invention. Accordingly, embodiments include viologens, viologen compounds, and viologen derivatives as the n-type dopant. For example, in certain embodiments, viologen compounds of formula I may be utilized as n-type dopants:

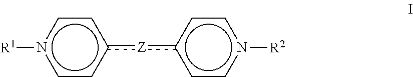

where:

[symbol] is a single or double bond;

Z is nothing, substituted or unsubstituted carboaryl, substituted or unsubstituted heteroaryl, substituted or unsubstituted alkenyl, substituted or unsubstituted cycloalkylene, or substituted or unsubstituted alkynylene;

R¹ and R² may be identical or different and each may be independently selected from a lone pair of electrons, hydrogen atom, substituted or unsubstituted alkyl, substituted or unsubstituted cycloalkyl, substituted or unsubstituted aryl, substituted or unsubstituted aralkyl, substituted or unsubstituted alkaryl, and substituted or unsubstituted heteroaryl.

In certain embodiments, R¹ and R² are identical and represent a substituted or unsubstituted C₁ to C₃₀ alkyl, substituted or unsubstituted C_{≥5} aryl, substituted or unsubstituted C₇ to C₁₈ aralkyl, substituted or unsubstituted C₇ to C₁₈ alkaryl, and substituted or unsubstituted C_{≥5} heteroaryl, each of R¹ and R² optionally and independently substituted with one or more of halo, oxo, hydroxy, aldehyde, carboxyl, carbonyl, acyl, amino, hydroxyamino, nitro, cyano, isocyanate, phosphonyl, mercapto, thio, thioether, sulfonamide, sulfonyl, sulfinyl, vinyl, allyl, substituted or unsubstituted alkyl, substituted or unsubstituted alkenyl, substituted or unsubstituted alkynyl, substituted or unsubstituted cycloalkyl, substituted or unsubstituted heterocycloalkyl, substituted or unsubstituted aryl, substituted or unsubstituted heteroaryl, substituted or unsubstituted alkoxy, substituted or unsubstituted alkenyloxy, and substituted or unsubstituted alkynyloxy.

In certain embodiments, R¹ and R² are identical or different, each independently represent a substituted or unsubstituted C₁ to C₁₈ alkyl, and a neutral viologen compound is provided. Suitable alkyls are defined above. Preferred alkyl groups include unsubstituted alkyls selected from methyl, ethyl, n-propyl, n-butyl, n-heptyl, n-octyl, n-decyl, and n-octadecyl. Specific examples of these viologen compounds are shown below:

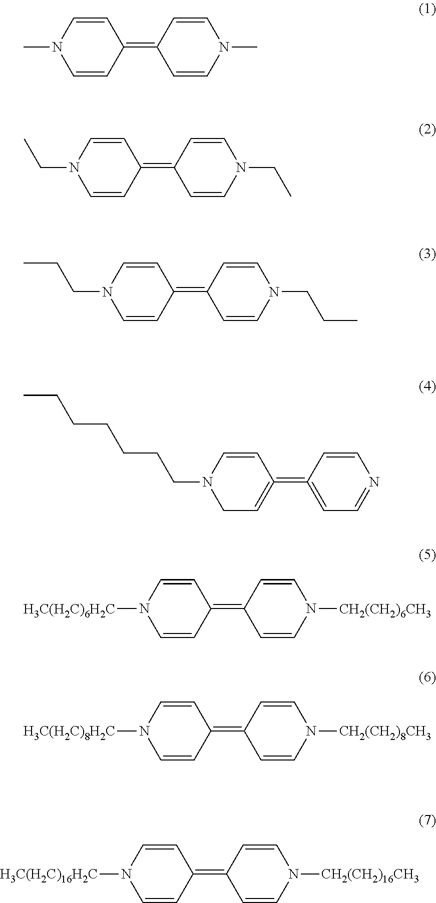

In certain embodiments, the n-type dopant(s) include benzyl viologen (BV), which may be represented by compound (8) below. In certain embodiments, the n-type dopant(s) include ethyl viologen (EV), which may be represented by compound (2) above.

In certain embodiments, R¹ and R² are identical, each represent a substituted or unsubstituted C₇ to C₁₈ aralkyl, and a neutral viologen compound is provided. Suitable aralkyls are defined above. Preferred aralkyls include benzyl, phenylethyl, diphenylmethyl. Specific examples of these viologen compounds are shown below:

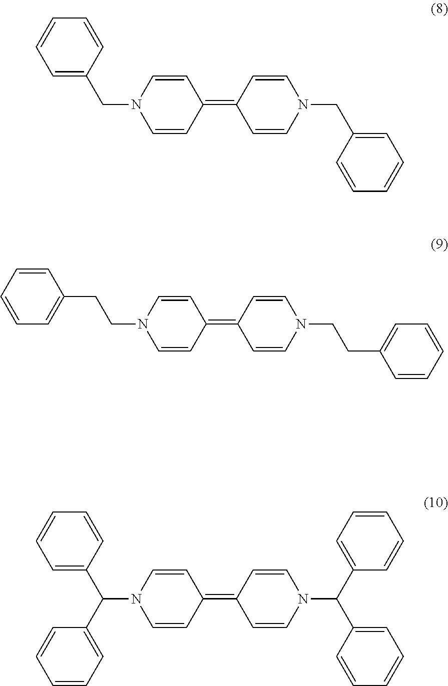 [SMILES: C1=CN(Cc2ccccc2)C=CC1=C1C=CN(Cc2ccccc2)C=C1 ; C1=CN(CCc2ccccc2)C=CC1=C1C=CN(CCc2ccccc2)C=C1 ; C1=CN(C(c2ccccc2)c2ccccc2)C=CC1=C1C=CN(C(c2ccccc2)c2ccccc2)C=C1]

In certain embodiments, R¹ and R² are identical or different, each independently represent a substituted or unsubstituted aryl, and a neutral viologen compound is provided. Suitable aryls are defined above. Preferred aryls include unsubstituted phenyls and phenyls substituted with methyl, ethyl, or vinyl.

The viologen compounds of formula I are capable of undergoing multiple one-electron oxidations or reductions. Accordingly, the viologen compound of formula I may be provided in an oxidized or reduced state. In an oxidized state, each nitrogen heteroatom of the pyridinium rings bears a positive charge, yielding a dicationic form (V²⁺) of the viologen compound. The viologen compound in such an oxidized state can accept electrons and be reduced. In a reduced state, one of the nitrogen heteroatoms of the pyridinium rings bears a positive charge, yielding a monocationic form (V⁺) of the viologen compound, or both of the nitrogen atoms bear a neutral charge, yielding a neutral (V) form of the viologen compound. Accordingly, the viologen compound of formula I is shown with generic bonding to accommodate variances in charge resulting from oxidation and/or reduction and therefore shall be understood to include viologen compounds in an oxidized state and reduced state. Although not shown, one or more counterions may optionally be present to balance charge(s) depending on whether the compound is in an oxidized state (V²⁺) or reduced state (V⁺).

In embodiments, the viologen compounds of formula I can be characterized as reducing-agent dopants. In general, redox doping involves (partial) transfer of an electron from a dopant to an organic molecule, which leads to the formation of a pair of radical anion and cation (or charge-transfer complex in the case of partial transfer). The electron transfer from the highest occupied molecular orbital (HOMO) of the dopant to the lowest unoccupied molecular orbital (LUMO) of the host semiconductor leads to n-doping. Dopants with a shallower HOMO level than the LUMO of the host semiconductor are generally beneficial for efficient n-doping. Examples of n-type dopants characterized as reducing-agent dopants include benzyl viologen and viologen derivatives, such as alkyl viologens, among others. Although shallow HOMO level of dopants can be favorable for efficient n-doping, the downside can be poor ambient air stability of the n-dopants. During synthesis of neutral BV, water can be used as the main medium dissolving the initial BV precursor, before it undergoes reduction oxidation reaction in bilayer water/organic solvents. This synthesis condition advantageously allows excellent air stability of BV and viologen derivatives, while preserving great solubility of BV and viologen derivatives in broad classes of organic solvents.

A benzimidazole compound is another example of a suitable n-type dopant in accordance with the present invention. The benzimidazole compounds may be represented by formula II:

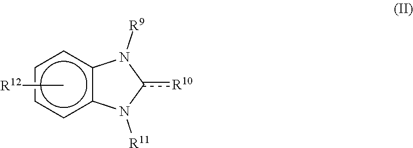

where:

[symbol] is a single or double bond;

R⁹ and R¹¹ may be identical or different and each may be independently selected from nothing, hydrogen, and substituted or unsubstituted alkyl;

R¹⁰ is a substituted or unsubstituted aryl or substituted or unsubstituted heteroaryl; and

R¹² is nothing or a substituent.

In certain embodiments, R⁹ and R¹¹ are identical and represent an alkyl containing 8 carbon atoms or less, preferably 4 carbon atoms or less, more preferably 3 carbon atoms or less; R¹⁰ represents a phenyl group substituted with dialkylamino groups, diaralkylamino groups, diarylamino groups, or dialkarylamino groups; and R² is nothing. Suitable dialkylamino groups, diaralkylamino groups, diarylamino groups, and dialkarylamino groups are defined above. Preferred substituents include dimethylamino groups and diphenylamino groups. Specific examples of these benzimidazole compounds are shown below:

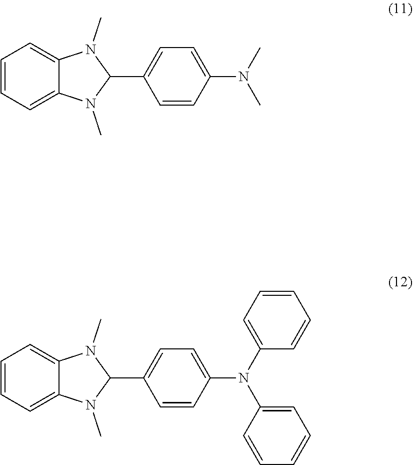 [SMILES: CN(C)c1ccc(C2N(C)c3ccccc3N2C)cc1 ; CN1c2ccccc2N(C)C1c1ccc(N(c2ccccc2)c2ccccc2)cc1]

In certain embodiments, the n-type dopant(s) include 4-(2,3-Dihydro-1,3-dimethyl-1H-benzimidazol-2-yl)-N, N-dimethylbenzenamine (N-DMBI), which may be represented by compound (11) above.

In certain embodiments, R⁹ is a substituted or unsubstituted alkyl containing carbon atoms or less, preferably 4 carbon atoms or less, more preferably 3 carbon atoms or less; R¹⁰ is a heteroaryl group containing at least one substituent that binds with R¹¹ to form at least a 5-membered ring, wherein the heteroaryl group and at least 5-membered ring are optionally each independently fused to one or more cycloalkyls, aryls, and heteroaryls; and R¹² is nothing. Suitable alkyls, heteroaryls, cycloalkyls, and aryls are defined above. A specific example of these benzimidazoles is shown below:

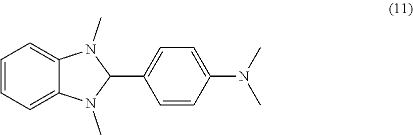 [SMILES: CN(C)c1ccc(C2N(C)c3ccccc3N2C)cc1]

In certain embodiments, the following benzimidazole derivatives can be used as n-type dopants: 4-(2,3-Dihydro-1,3-dimethyl-1H-benzimidazol-2-yl)-N,N-dimethylbenzenamine (N-DMBI), 4-(1,3-Dimethyl-2,3-dihydro-1H-benzoimidazol-2-yl)-N,N-diphenylaniline (N-DPBI), and (12a,18a)-5,6,12,12a,13,18,18a,19-octahydro-5,6-dimethyl-13,18[1′,2′]-benzenobisbenzimidazo [1,2-b:2′,1′-d]benzo[i][2.5]benzodiazo-cine potassium triflate adduct (DMBI-BDZC). Benzimidazole derivative molecules such as N-DMBI, N-DPBI, and DMBI-BDZC are air stable n-type dopants that allow doping of organic semiconductor host by anion (e.g. hydride, H—) transfer to the semiconductor host.

A mono- or poly-cyclic aliphatic or aromatic ring structure comprising at least one nitrogen heteroatom is another example of suitable n-type dopants in accordance with the present invention. Such compounds may be represented by formula III:

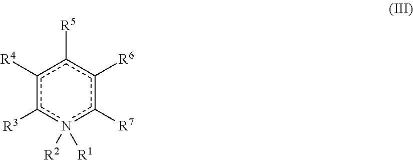

where:

[symbol] is a single or double bond;

each of R¹ to R⁷ is independently a hydrogen, a substituted or unsubstituted C₁ to C₄ alkyl, or an amine, or at least two of R¹ to R⁷ bind with each other to form a 5- or 6-membered fused ring structure, wherein the 5- or 6-membered fused ring structure is optionally substituted, optionally comprises one or more nitrogen heteroatoms, and is optionally fused to one or more additional aliphatic or aromatic 5- or 6-membered ring structures, each ring structure optionally comprising one or more nitrogen heteroatoms and optionally comprising one or more substituents.

In certain embodiments, the compounds of formula III include:

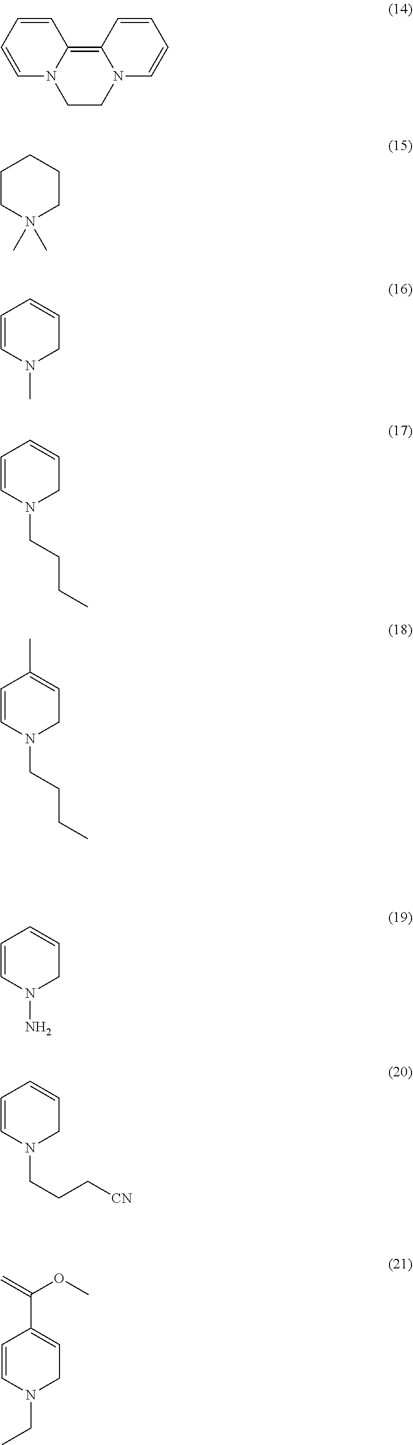

In certain embodiments, the n-type dopant(s) include diquat (DQ), which may be represented by compound (14) above.

Other examples of n-type dopants in accordance with the present invention include, but are not limited to, the compounds shown below:

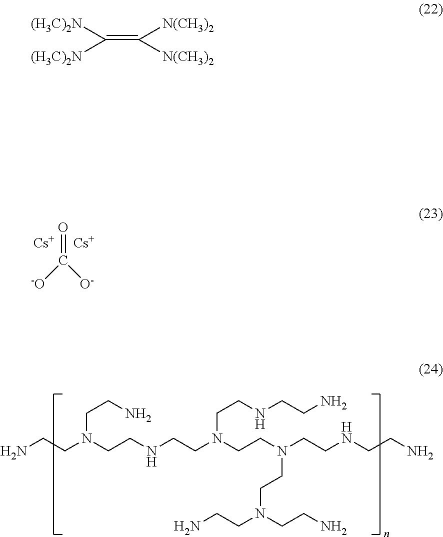

where n is at least 1.

### N-Type Doped-Photoactive Regions

In another aspect of the present invention, photoactive regions of organic photovoltaic cells are provided. A photoactive region can comprise one or more of the following components: (1) at least one of the n-type dopants described above, including any derivatives thereof, (2) one or more electron donor materials, (3) one or more electron acceptor materials, (4) one or more hole-scavenging materials, (5) one or more additives, and (6) one or more solvents. Each of these components, either individually or collectively, in any combination, can be included or incorporated into a single layer or multiple layers to obtain single-component systems, binary systems, ternary systems, tandem devices, and so on. In this way, each of the components (1) to (6) can be independently included, excluded, or combined in one or more layers to form bulk heterojunctions, mixed heterojunctions, planar heterojunctions, hybrid planar-mixed heterojunctions, and the like.

Accordingly, the configurations and/or structures of the photoactive regions are not particularly limited. In embodiments, the photoactive region includes a bulk heterojunction layer comprising at least one n-type dopant blended with one or more electron donor materials and one or more electron acceptor materials. In embodiments, the photoactive region includes an n-type dopant distributed or incorporated in a bulk heterojunction layer comprising one or more electron donor materials and one or more electron acceptor materials. In embodiments, the photoactive region includes a planar heterojunction bilayer comprising a first layer in contact with a second layer, wherein the first layer comprises at least one n-type dopant and one or more electron acceptor materials and wherein the second layer comprises one or more electron donor materials, or vice versa with respect to the first layer and second layer. These shall not be limiting as other configurations are possible and fully within the scope of the present disclosure.

The n-type dopants provided above, including any derivatives thereof, can be present in the photoactive region. The content of the n-type dopant in the photoactive region, including any one or more layers thereof, can be in the range of about 0.0001 wt. % or greater. As used herein, the wt. % is calculated as a weight percentage of the solid weight mass of the electron donor material or electron acceptor material, or the electron donor material and electron acceptor material, if both are present. Accordingly, values greater than 100 wt. % are within the scope of the present disclosure (e.g., 1,000 wt. % or less). In certain embodiments, the n-type dopant content can be any incremental range or value between 0.0001 wt. % and 100 wt. %. In certain embodiments, the n-type dopant content of the photoactive region is about 50 wt. %, about 45 wt. %, about 40 wt. %, about 35 wt. %, about 30 wt. % or less, about 25 wt. % or less, about 20 wt. % or less, about 15 wt. % or less, about 10 wt. % or less, about 5 wt. % or less, or about 1 wt. % or less. In certain embodiments, the n-type dopant content is about 1 wt. %, about 0.9 wt. %, about 0.8 wt. %, about 0.7 wt. %, about 0.6 wt. %, about 0.5 wt. %, about 0.4 wt. %, about 0.3 wt. %, about 0.2 wt. %, about 0.1 wt. %, about 0.05 wt. %, about 0.01 wt. %, about 0.009 wt. %, about 0.008 wt. %, about 0.007 wt. %, about 0.006 wt. %, about 0.005 wt. %, about 0.004 wt. %, about 0.003 wt. %, about 0.002 wt. %, about 0.001 wt. %, about 0.0009 wt. %, and so on.

The electron donor materials and electron acceptor materials are not particularly limited. In general, the electron donor materials and/or electron acceptor materials can be selected from polymers (e.g., conjugated polymers, copolymers, block copolymers, etc.), small molecules, oligomers, and monomers. In certain embodiments, it may be advantageous for the electron acceptor and/or donor materials to be solution-processable to simply fabrication processes, but being solution-processable is not a requirement of the present invention. The content of the electron acceptor materials and electron donor materials in the photoactive region, including any one or more layers thereof, can be any incremental range or value between 0.0001 wt. % and 100 wt. %, where the wt. % is calculated based on the total mass of the photoactive region.

Suitable electron donor materials include, but are not limited to, polythiophene derivative, poly(para-phenylene) derivative, polyfullerene derivative, polyacetylene derivative, polypyrrole derivative, polyvinylcarbazole derivative, polyaniline derivative, polyphenylenevinylene derivative, combinations thereof, and the like. In certain embodiments, the electron donor materials are selected from: poly[(2,6-(4,8-bis(5-(2-ethylhexyl-3-fluoro)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-c′]dithiophene-4,8-dione)] (known as PM6 or PBDB-T-2F), poly([2,6′-4,8-di(5-ethylhexylthienyl)benzo[1,2-b;3,3-b]dithiophene]{3-fluoro-2[(2-ethylhexyl)carbonyl]thieno[3,4-b]thiophenediyl}) (PTB7-Th), poly[(2,6-(4,8-bis(5-(2-ethylhexyl)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-c′]dithiophene-4,8-dione)] (PBDB-T), poly[(2,6-(4,8-bis(5-(2-ethylhexyl-3-chloro)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-c′]dithiophene-4,8-dione)] (known as PM7 or PBDB-T-2Cl), poly(3-hexylthiophene) (P3HT), poly[4,8-bis-(2-ethyl-hexyl-thiophene-5-yl)-benzo[1,2-b:4,5-b′]di-thiophene-2,6-diyl]-alt-[2-(2′-ethyl-hexanoyl)-thieno[3,4-b]thiophen-4,6-diyl] (PBDTTT-CT), poly[N-9′-hepta-decanyl-2,7-carbazole-alt-5,5-(4′,7′-di-2-thienyl-2′,1′,3-′-enzothiadiazole)] (PCDTBT), poly[6-fluoro-2,3-bis-(3-octyloxyphenyl) quinoxaline-5,8-diyl-alt-thiophene-2,5-diyl] (FTQ), subphthalocyanine (SubPC), copper phthalocyanine (CuPc), Zinc phthalocyanine (ZnPc), poly(3-hexylthiophene) (P3HT), poly(3-octylthiophene) (P30T), poly(3-hexyloxythiophene) (P3DOT), poly(3-methylthiophene) (PmeT), poly(3-dodecylthiophene) (P3DDT), poly(3-dodecylthienylenevinylene) (PDDTV), poly(3,3 dialkylquarterthiophene) (PQT), poly-dioctyl-fluorene-co-bithiophene (F8T2), Poly[[4,8-bis[(2-ethylhexyl)oxy]benzo[1,2-b:4,5-b′]dithiophene-2,6-diyl][-3-fluoro-2-[(2-ethylhexyl)carbonyl]thieno[3,4-b]thiophenediyl]] (PTB7), poly-(2,5-bis(3-alkylthiophene-2-yl)thieno[3,2-b]thiophene) (PBTTT-C12), poly[2,7-(9,9′-dihexylfluorene)-alt-2,3-dimethyl-5,7-dithien-2-yl-2,1,3-b-enzothiadiazole](PFDDTBT), poly{[2,7-(9,9-bis-(2-ethylhexyl)-fluorene)]-alt-[5,5-(4,7-di-20-thienyl-2,1,-3-benzothiadiazole)]} (BisEH-PFDTBT), poly{[2,7-(9,9-bis-(3,7-dimethyl-octyl)-fluorene)]-alt-[5,5-(4,7-di-20-th-ienyl-2,1,3-benzothiadiazole)]} (BisDMO-PFDTBT), poly[N-9″-hepta-decanyl-2,7-carbazole-alt-5,5-(4′,7′-di-2-thienyl-2′,1′,-3′-benzothiadiazole)] (PCDTBT), poly[4,8-bis-substituted-benzo[1,2-b:4,5-b′]dithiophene-2,6-diyl-alt-4-substituted-thieno[3,4-b]thio-phene-2,6-diyl] (PBDTTT-C-T), Poly(benzo[1,2-b:4,5-b′]dithiophene-alt-thieno[3,4-c]pyrrole-4,6-dione (PBDTTPD), poly((4,4-dioctyldithieno(3,2-b:2′,3′-d)silole)-2,6-diyl-alt-(2,1,3-benzo-thiadiazole)-4,7-diyl) (PSBTBT), derivatives thereof, combinations thereof, and the like.

Suitable electron acceptor materials include, but are not limited to, fullerenes (e.g., C₆₀, C₇₀ fullerenes, etc.), fullerene derivatives, non-fullerenes, non-fullerene derivatives, small molecular, polymer acceptor, oligomers, perylenes, perylene derviatives, 2,7-dicyclohexyl benzo[lmn][3,8]phenanthroline derivatives, 1,4-diketo-3,6-dithienylpyrrolo[3,4-c:]pyrrole (DPP) derivatives, tetracyanoquinodimethane (TCNQ) derivatives, poly(p-pyridyl vinylene) (PpyV) derivatives, 9,9′-bifluorenylidene (99BF) derivatives, benzothiadiazole (BT) derivatives, combinations thereof, and the like. In certain embodiments, the electron acceptor materials are selected from: 2,2′-((2Z,2′Z)-((12,13-bis(2-ethylhexyl)-3,9-diundecyl-12,13-dihydro-[1,2,5]thiadiazolo[3,4-e]thieno[2,″30″: 4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile (Y6), [6,6]-phenyl-C71-butyric acid methyl ester (PC₇₁BM), 2,2′-((2Z, 2′Z)-((6,6,12,12-tetrakis(4-hexylphenyl)-6,12-dihydro-s-indaceno[1,2-b:5,6-b′]dithieno[3,2-b]thiophene-2,8-diyl)bis(methaneylylidene))bis(dichloro-3-oxo-2,3-dihydro-1H-indene-2,1-diylidene))dimalononitrile (IT-2C), 2,2′-((2Z, 2′Z)-((6,6,12,12-tetrakis(4-hexylphenyl)-6,12-dihydro-s-indaceno[1,2-b:5,6-b′]dithieno[3,2-b]thiophene-2,8-diyl)bis(methaneylylidene))bis(5,6-dichloro-3-oxo-2,3-dihydro-1H-indene-2,1-diylidene))dimalononitrile (IT-4Cl), IT-4F, ((5Z,5′Z)-5,5′-(((4,4,9,9-tetraoctyl-4,9-dihydro-s-indaceno[1,2-b:5,6-b′]dithiophene-2,7-diyl)bis(benzo[c][1,2,5]thiadiazole-7,4-diyl))bis(methanylylidene))bis(3-ethyl-2-thioxothiazolidin-4-one)) (O-IDTBR) or its structural analogue comprising 2-ethylhexyl side chains (5E, 5′E)-5,5′-(((4,4,9,9-tetrakis(2-ethylhexyl)-4,9-dihydro-s-indaceno[1,2-b:5,6-b′]dithiophene-2,7-diyl)bis(benzo[c][1,2,5]thiadiazole-7,4-diyl))bis(methaneylylidene))bis(3-ethyl-2-thioxothiazolidin-4-one) (EH-IDTBR), poly[[4,8-bis[5-(2-ethylhexyl)thiophene-2-yl]benzo[1,2-b;4,5-b′]dithiophene-2,6-diyl][3-fluoro-2-[(2-ethylhexyl)carbonyl]-thieno[3,4-b]thiophenediyl]], [6,6]-phenyl-C61-butyric acid (PC61BM), [6,6]-(4-fluoro-phenyl)-C61-butyric acid methyl ester (FPCBM), [6,6]-phenyl-C71 butyric acid methyl ester (PC₇₁BM), indene-C60 bisadduct (IC60BA), indene-C70 bisadduct (IC70BA), fullerene-C60, fullerene-C70, carbon nanotubes (CNT), a carbon onion, 3,4,9,10-perylenetetracarboxylic-bis-benzimidazole (PTCBI), perylenetetracarboxylic dianhydride (PTCDA), P(NDI2OD-T2), PNDIT, PNDIS-HD, PNDTI-BT-DT, PPDI2T, PPDIC, PPDIDTT, YF25, NIDCS-HO, NIBT, Bis-PDI-T-MO, SDIPBI, PDI-2DTT, PDI, derivatives thereof, combinations thereof, and the like. In certain embodiments, non-fullerene acceptors from Duan, et al., Progress in non-fullerene acceptor based organic solar cells, Solar Energy Materials and Solar Cells 193 (2019) 22-65, which is hereby incorporated by reference in its entirety, are used.

In certain embodiments, the electron acceptor materials include one or more of the following non-fullerene materials: rhodanine-benzothiadiazole-coupled indacenodithiophene (IDTBR); indacenodithieno[3,2-b]thiophene, IT), end-capped with 2-(3-oxo-2,3-dihydroinden-1-ylidene)malononitrile (INCN) groups (ITIC); indaceno[1,2-b:5,6-b′]dithiophene and 2-(3-oxo-2,3-dihydroinden-1-ylidene)malononitrile (IEIC); 2,2′-((2Z,2′Z)-((5,5′-(4,4,9,9-tetrakis(4-hexylphenyl)-4,9-dihydro-s-indaceno[1,2-b:5,6-b′]dithiophene-2,7-diyl)bis(4-((2-ethylhexyl)-oxy)thiophene-5,2-diyl))bis(methanylylidene))bis(3-oxo-2,3-di-hydro-1H-indene-2,1-diylidene))dimalononitrile (IEICO); naphthalene diimide (NDI); bay-linked perylene bisimide (di-PBI); perylene bisimide (PBI); Benzotriazole-Containing End-Capped with Thiazolidine-2,4-dione (TD); Naphthalocyanine (NC); Phthalocyanine (PC); Naphtho[1,2-c:5,6-c′]bis[1,2,5]thiadiazole; (2E,2′E)-3,3′-(2,5-dimethoxy-1,4-phenylene)bis(2-(5-(4-(N-(2-ethylhexyl)-1,8-naphthalimide)yl)thiophen-2-yl)acrylonitrile) (NIDCS-MO); thieno[3,4-b] thiophene and 2-(1,1-dicyanomethylene)rhodanine combination (ATT-1); (3,9-bis(4-(1,1-dicyanomethylene)-3-methylene-2-oxo-cyclopenta[b]thiophen)-5,5,11,11-tetrakis(4-hexylphenyl)-dithieno[2,3-d′:2,3-d′]-s-indaceno[1,2-b:5,6-b′]-dithiophene (ITCC); indanedione; dicyannovinyl; benzothiadiazole; diketopyrolopyrrole; arylene diimide; IDIC; combinations thereof, and the like. In certain embodiments, one or more non-fullerene materials are combined with one or more hole-scavenging materials, wherein the hole-scavenging material promotes the extraction of charges therefrom. In embodiments, the hole-scavenging material extracts a hole from the non-fullerene material and/or may not exhibit the properties or characteristics of a donor material. Examples of suitable hole-scavenging materials include, but are not limited to, thiophene, acene, fluorine, carbazole, indacenodithieno thiophene, indacenothieno thiphene, benzodithiazole, thieny-benzodithiophene-dione, benzotriazole, diketopyrrolopyrrole, and the like.

Solvents can be used to modulate the chemical, electrochemical, physical, and/or mechanical properties of photoactive regions (e.g., flexibility, polarity, etc.). In some instances, solvents may be present or remain in photoactive regions prepared by solution-based processes, among others. In other instances, even if prepared by solution-based processes, solvents may be completely or substantially removed from photoactive regions by processes, such as evaporation. Accordingly, solvents are optionally present in the photoactive region. If present, some examples of suitable solvents include, but are not limited to, alcohol (e.g., methanol, ethanol, isopropanol, iso-butanol, tert-butanol, etc.), ethyl acetate, ethyl ether, acetone, heptane, n-hexane hydrochloric acid, carbon tetrachloride, methylene chloride, chlorobenzene (CB), chloroform (CF), chloronapthalene (CN), pentane, hexane, petroleum ether, cyclopentane, dichloromethane, diethyl ether, tetrahydrofuran, dimethyl formamide, dimethyl sulfoxide, trifluoroacetic acid, dioxane, water, ethanol, xylene, and the like.

Additives can also be used to modulate the chemical, electrochemical, physical, and/or mechanical properties of photoactive regions. Additives are not a requirement of the present invention and thus are optionally present. If present, some examples of suitable additives include, but are not limited to, 1,8-diiodooctane (DIO), chlorobenzene (CB), 4-butanedithiol, 1,6-hexanedithiol, 1,8-octanedithiol, 1,9-nonanedithiol, class of 1,8-di(R)octanes with various functional groups (where R is a functional group), di(ethylene glycol)-diethyl ether, and N-methyl-2-pyrrolidinone, 1,6-diiodohexane, 1,4-diiodobutane, and the like. In some embodiments, the additives and solvents are interchangeable. Accordingly, in certain embodiments, the additives further include the solvents disclosed herein. In certain embodiments, the solvents further include the additives disclosed herein.

In certain embodiments, the photoactive region comprises a bulk heterojunction layer comprising benzyl viologen blended with PM6 and Y6. In certain embodiments, the photoactive region comprises a bulk heterojunction layer comprising benzyl viologen blended with PM6, Y6, and PC₇₁BM. In certain embodiments, the photoactive region comprises a bulk heterojunction layer comprising benzyl viologen blended with PM6 and IT-2Cl. In certain embodiments, the photoactive region comprises a bulk heterojunction layer comprising benzyl viologen blended with PTB7-Th and EH-IDTBR. In certain embodiments, the photoactive region comprises a bulk heterojunction layer comprising benzyl viologen blended with PTB7-Th and PC₇₁BM.

### Preparing N-Type Doped-Photoactive Regions

In further aspects of the present invention, methods of preparing photoactive regions are provided. The methods are not particularly limited and thus suitable methods known in the art can be utilized herein. Examples of suitable methods include dopant formulations prepared by blending, solution doping, solvent-immerse doping, vapor doping, and thermal evaporation doping. These methods are discussed in more detail below. Other methods can be employed without departing from the scope of the present disclosure.

In embodiments, a solution-doping process is provided. In some of these embodiments, at least one n-type dopant is blended with one or more electron acceptor materials or one or more electron donor materials, or both, to form a photoactive region or a layer thereof. A dopant formulation comprising an n-type dopant (or its precursor) can be contacted with a bulk heterojunction (BHJ) solution comprising an electron donor material (or its precursor) and an electron acceptor material (or its precursor), to form an active solution, wherein the dopant formulation and BHJ solution include the same solvent. The active solution can subsequently be applied to a substrate. The contacting can be performed by bringing the dopant formulation and BHJ solution into physical contact, or immediate or close proximity. Examples of contacting include adding, adding drop-wise, pouring, mixing, and the like. The contacting can optionally proceed under stirring or stirring can be performed following the contacting. The applying can be performed using solution-based processes, such as spin-coating, drop-casting, dipping, bar-coating, screen-printing, slot die-coating, spray-coating, depositing (e.g., deposition processing), and the like. The substrate can include or be any layer or material of an organic photovoltaic device or cell (e.g., electrode, electron transporting layer, buffer layer, layer of a photoactive region, etc.).

In embodiments, an n-type dopant is incorporated into a planar heterojunction by mixing the dopant with an electron acceptor material (or its precursor) to form an active solution. For example, in fabricating an organic photovoltaic device of the structure:—ITO/hole transport layer/photoactive region/electron transport layer/Al, the method can be performed by applying a polymer donor solution to a hole transport layer that has been deposited on an ITO substrate, applying an active solution comprising an n-type dopant mixed with an electron acceptor material (or its precursor) to the polymer donor solution layer; and applying (e.g., by depositing), on the active solution layer, an electron transport layer and metal contact. Alternatively, to prepare a planar heterojunction multilayer photoactive region, a dopant solution (e.g., a solution comprising only the dopant and not any electron acceptor and/or donor material) comprising an n-type dopant dissolved in an orthogonal solvent (e.g., orthogonal to the donor and/or acceptor solution), can be applied to the polymer donor solution layer or film, and thereafter an acceptor solution layer can be applied to or deposited on the dopant solution layer or film. The applying can proceed as described above and elsewhere throughout the present disclosure.

In embodiments, a solvent-immerse doping process is provided. An n-type dopant (e.g., N-DMBI, PEI, etc.) can be dissolved in a solvent that is orthogonal to the solvent used to prepare a film comprising at least one of an electron acceptor material and electron donor material. Upon depositing, for example, a BHJ film, the deposited BHJ film can be immersed in a dopant solution comprising the n-type dopant for a duration of at least 1 second or longer, up to a week, preferably about 10 minutes or more.

In embodiments, a vapor doping method is provided, such as solvent annealing treatments (SVA), among others. A BHJ film can be deposited on a substrate and optionally thermally annealed. The BHJ film, either as-cast or thermally-annealed, can be exposed to an n-type dopant in a vapor and/or gas phase to vapor dope the BHJ film. The exposing can proceed in a nitrogen-filled glove box, among other vessels. For example, in certain embodiments, a BHJ film can be introduced into a vessel containing an n-type dopant in a solid or liquid phase. The n-type dopant can be heated using any suitable apparatus to vaporize the n-type dopant, wherein the heating can lead to a partial vapor pressure of the dopant in the vessel.

In embodiments, the n-type dopant deposition can proceed by thermal evaporation, vacuum sublimation, thermal sublimation, thermal annealing, solvent annealing, and combinations thereof. For example, in certain embodiments, the fabrication process can comprise depositing an n-type doped-photoactive region (or any layer thereof) on any layer of a photovoltaic device by co-vaporizing (e.g., vaporizing contemporaneously or simultaneously) one or more n-type dopants with one or more electron acceptor materials and/or one or more electron donor materials. A thermal evaporation or vacuum sublimation process can be utilized to conduct the vaporizing. The source material for each n-type dopant, electron acceptor material, and electron donor material can optionally be independently controlled. For example, separate heat sources (e.g., such as a linear thermal boat) can be used for each source material, each of which may be independently present in a solid or liquid phase. A mask can optionally be used during the vaporization and/or deposition processes. The n-type dopant content, electron acceptor content, and electron donor content can be controlled by varying the deposition rates of each, such that said deposition rates correspond to or achieve the desired ratio of n-type dopants to electron acceptor materials to electron donor materials. One specific example of an n-type dopant that can be utilized in thermal evaporation and/or vacuum sublimation is cesium carbonate (Cs₂CO₃). Other n-type dopants can be utilized without departing from the scope of the present disclosure.

If further embodiments, the fabrication process can proceed by (A) depositing a first layer comprising one or more electron acceptor materials and/or one or more electron donor materials on any layer of a photovoltaic device, wherein the first layer is exclusive of any n-type dopants, optionally annealing the first layer, and vaporizing one or more n-type dopants via thermal evaporation or vacuum sublimation, wherein the vaporizing is sufficient to dope the first layer with the one or more n-type dopants or form a second layer on the first layer; or (B) depositing one or more n-type dopants via thermal evaporation or vacuum sublimation to form a first layer on any layer of a photovoltaic device, and depositing a second layer comprising one or more electron acceptor materials and/or one or more electron donor materials on the first layer, thereby forming a second layer. An annealing step can be performed in either process (A) or (B) to promote or induce diffusion or further diffusion of the one or more n-type dopants into the first layer and/or to reduce the n-type dopant concentration in any layer (e.g., de-dope the first layer in process (A)). The annealing process can be utilized to adjust or control the dopant concentration in any layer. Examples of annealing processes include thermal annealing and solvent annealing. The electron acceptor materials and/or electron donor materials can be deposited using any of the processes disclosed herein or known in the art to form a photoactive region exclusive of, or without, any n-type dopants.

Examples of suitable processes are described in H. Yan et al., Advanced Energy Materials, 2018, 8, 1703672; H. Yan et al., ACE Energy Letters, 2019, 4, 1356; F. A. Larrain et al., Energy & Environmental Science, 2018, 11, 2216; H. Yah et al., ACS Applied Materials & Interfaces, 2019, 11, 4178; S. N. Patel et al., Science Advances, 2017, 3, e1700434; C.-L. Fan et al., Materials, 2016, 9, 46; R. Fujimoto et al., Organic Electronics, 2017, 47, 139; all of which are hereby incorporated by reference in their entirety.

### Organic Photovoltaic Cells

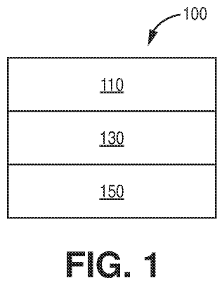

In another aspect of the present invention, organic photovoltaic cells or devices are provided. FIG. 1 is a schematic diagram of an organic photovoltaic cell, according to one or more embodiments of the present disclosure. As shown, the organic photovoltaic cell 100 comprises a photoactive region 130 provided between a first electrode 110 and a second electrode 150. The bulk heterojunction photoactive layer can be adjacent to or in direct physical contact with the first electrode 110 or second electrode 150, or both of the electrodes; or one or more layers can separate the photoactive region 130 from the first electrode 110 or the second electrode 150, or both of the electrodes. The first electrode and second electrode can include an anode or cathode, either or both of which can optionally be transparent, at least partially transparent, or non-transparent. The one or more additional layers are not particularly limited and can depend on the architecture or configuration of the organic photovoltaic cell. Non-limiting examples of such additional layers include substrates (e.g., transparent, at least partially transparent, or non-transparent substrates), hole transport layers, hole conducting layers, electron transport layers, electron conducting layers, exciton-blocking layers, buffer layers, transparent, partially transparent, or non-transparent substrates, and the like. Each of these layers and/or components can be combined in a variety of ways to afford organic photovoltaic cells that can be illuminated with light from any side or surface. For example, light illumination can come from the bottom side, top side, or from both sides (e.g., bifacial in the case of semi-transparent devices).

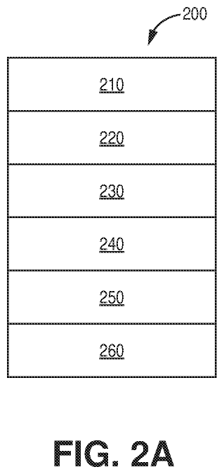

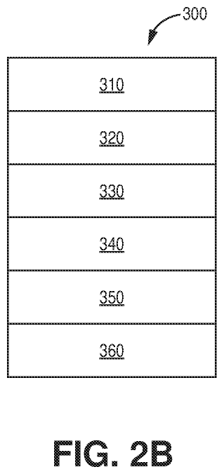

FIG. 2A is a schematic diagram of an organic photovoltaic device with a normal structure, according to one or more embodiments of the present disclosure. In embodiments, an organic photovoltaic cell 200 with a normal structure is provided. For example, the organic photovoltaic cell 200 can have the following structure:

a cathode (top) 210;

an electron transport layer and/or exciton-blocking layer 220;

a photoactive region 230;

a hole transport layer and/or hole conducting layer 240;

an optionally at least partially transparent anode (back) 250;

a substrate 260.

In certain embodiments, an organic photovoltaic cell with a bulk heterojunction (or mixed heterojunction) normal structure is provided. In these embodiments, the organic photovoltaic cell 200 can have the following structure:

a cathode (top) 210;

an electron transport layer and/or exciton-blocking layer 220;

a bulk heterojunction (or mixed heterojunction) photoactive layer 230, wherein the bulk heterojunction (or mixed heterojunction) photoactive layer comprises an n-type dopant blended with one or more electron acceptor materials and one or more electron donor materials;

a hole transport layer and/or hole conducting layer 240;

an optionally at least partially transparent anode (back) 250;

a substrate 260.

In certain embodiments, an organic photovoltaic cell with a planar heterojunction normal structure is provided. In these embodiments, the organic photovoltaic cell 200 can have the following structure:

a cathode (top) 210;

an electron transport layer and/or exciton-blocking layer 220;

a planar heterojunction photoactive bilayer 230, wherein the planar heterojunction photoactive region comprises a first layer and a second layer, wherein the first layer comprises an n-type dopant blended and/or mixed with one or more electron acceptor materials and the second layer comprises one or more electron donor materials;

a hole transport layer and/or hole conducting layer 240;

an optionally at least partially transparent anode (back) 250;

a substrate 260.

FIG. 2B is a schematic diagram of an organic photovoltaic device with an inverted structure, according to one or more embodiments of the present disclosure. In embodiments, an organic photovoltaic cell 300 with an inverted structure is provided. For example, the organic photovoltaic cell 300 can have the following structure:

an anode (top) 310;

a hole transport layer and/or hole conducting layer 320;

a photoactive region 330;

an electron transport layer and/or exciton-blocking layer 340;

an optionally at least partially transparent cathode (back) 350;

a substrate 360.

In certain embodiments, an organic photovoltaic cell 300 with a bulk heterojunction (or mixed heterojunction) inverted structure is provided. In these embodiments, the organic photovoltaic cell 300 can have the following structure:

an anode (top) 310;

a hole transport layer and/or hole conducting layer 320;

a bulk heterojunction (or mixed heterojunction) photoactive layer 330, wherein the bulk heterojunction (or mixed heterojunction) photoactive layer comprises an n-type dopant blended with one or more electron acceptor materials and one or more electron donor materials;

an electron transport layer and/or exciton-blocking layer 340;

an optionally at least partially transparent cathode (back) 350;

a substrate 360.

In certain embodiments, an organic photovoltaic cell 300 with a planar heterojunction inverted structure is provided. In these embodiments, the organic photovoltaic cell 300 can have the following structure:

an anode (top) 310;

a hole transport layer and/or hole conducting layer 320;

a planar heterojunction photoactive bilayer 330, wherein the planar heterojunction photoactive region comprises a first layer and a second layer, wherein the first layer comprises an n-type dopant blended and/or mixed with one or more electron acceptor materials and the second layer comprises one or more electron donor materials;

an electron transport layer and/or exciton-blocking layer 340;

an optionally at least partially transparent cathode (back) 350;

a substrate 360.

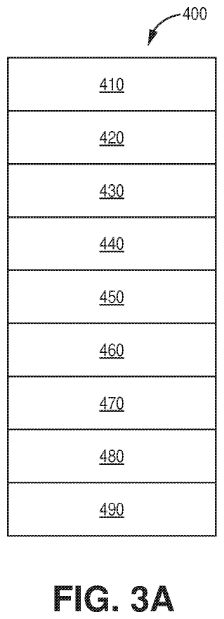

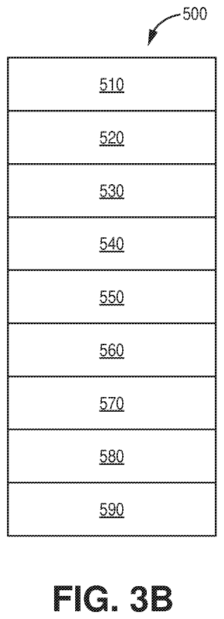

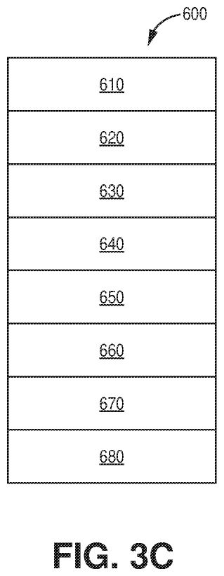

FIG. 3A is a schematic diagram of an organic photovoltaic device with a normal tandem structure, according to one or more embodiments of the present disclosure. In embodiments, an organic photovoltaic cell 400 with a normal tandem structure is provided. For example, the organic photovoltaic cell 400 can have the following structure:

a cathode (top) 410;

an electron transport layer and/or exciton blocking layer 420;

a photoactive region 430 comprising one or more n-type dopants;

a hole transport layer and/or hole conducting layer 440;

an electron transport layer and/or exciton blocking layer 450;

a photoactive region 460 comprising one or more n-type dopants;

a hole transport layer and/or hole conducting layer 470;

an optionally at least partially transparent anode (back) 480;

a substrate 490.

The one or more n-type dopants included in the photoactive regions 430 and 460 can be the same or different, or the photoactive regions 430 and 460 can have at least one n-type dopant that is the same, or the photoactive regions 430 and 460 can have at least one n-type dopant that is different or omitted. For example, in certain embodiments, the photoactive regions 430 and 460 each comprise a single n-type dopant, wherein the n-type dopant included in the photoactive regions 430 and 460 are the same. In certain embodiments, the photoactive regions 430 and 460 each comprise a mixture of two or more n-type dopants, wherein the mixture of n-type dopants included in the photoactive regions 430 and 460 are the same. In certain embodiments, the photoactive regions 430 and 460 each comprise a single n-type dopant, wherein the n-type dopants included in the photoactive regions 430 and 460 are different. In certain embodiments, the photoactive regions 430 and 460 each comprise a mixture of two or more n-type dopants, wherein the mixture of n-type dopants included in the photoactive regions 430 and 460 are different. In certain embodiments, the photoactive regions 430 and 460 each comprise a mixture of two or more n-type dopants, wherein at least one of the n-type dopants included in the photoactive regions 430 and 460 are different or the same. In certain embodiments, the photoactive regions 430 and 460 each comprise a mixture of two or more n-type dopants, wherein at least one of the n-type dopants included in the photoactive region 430 is omitted from the photoactive region 460, or vice versa. The photoactive regions can form or include any type of heterojunction of the present disclosure.

In certain embodiments, the photovoltaic device 400 can comprise a first subcell and a second subcell, wherein the first subcell includes one or more of the following components: the cathode (top) 410; the electron transport layer and/or exciton blocking layer 420; the photoactive region 430 comprising one or more n-type dopants; the hole transport layer and/or hole conducting layer 440; and an optional intermediate layer (not shown); and the second subcell includes one or more of the following components: the optional intermediate layer (not shown), the hole transport layer and/or hole conducting layer 450; the photoactive region 460 comprising one or more n-type dopants; the hole transport layer and/or hole conducting layer (back) 480; and the substrate 490. In certain embodiments, one or more additional subcells (not shown) can be included in the photovoltaic device 400.

FIG. 3B is a schematic diagram of an organic photovoltaic device with an inverted tandem structure, according to one or more embodiments of the present disclosure. In embodiments, an organic photovoltaic cell 500 with an inverted tandem structure is provided. For example, the organic photovoltaic cell 500 can have the following structure:

an anode (top) 510;

a hole transport layer and/or hole conducting layer 520;

a photoactive region 530 comprising one or more n-type dopants;

an electron transport layer and/or exciton-blocking layer 540;

a hole transport layer and/or hole conducting layer 550;

a photoactive region 560 comprising one or more n-type dopants;

an electron transport layer and/or exciton-blocking layer 570;

an optionally at least partially transparent cathode (back) 580;

a substrate 590.

The one or more n-type dopants included in the photoactive regions 530 and 560 can be the same or different, or the photoactive regions 530 and 560 can have at least one n-type dopant that is the same, or the photoactive regions 530 and 560 can have at least one n-type dopant that is different or omitted. For example, in certain embodiments, the photoactive regions 530 and 560 each comprise a single n-type dopant, wherein the n-type dopant included in the photoactive regions 530 and 560 are the same. In certain embodiments, the photoactive regions 530 and 560 each comprise a mixture of two or more n-type dopants, wherein the mixture of n-type dopants included in the photoactive regions 530 and 560 are the same. In certain embodiments, the photoactive regions 530 and 560 each comprise a single n-type dopant, wherein the n-type dopants included in the photoactive regions 530 and 560 are different. In certain embodiments, the photoactive regions 530 and 560 each comprise a mixture of two or more n-type dopants, wherein the mixture of n-type dopants included in the photoactive regions 530 and 560 are different. In certain embodiments, the photoactive regions 530 and 560 each comprise a mixture of two or more n-type dopants, wherein at least one of the n-type dopants included in the photoactive regions 530 and 560 are different or the same. In certain embodiments, the photoactive regions 530 and 560 each comprise a mixture of two or more n-type dopants, wherein at least one of the n-type dopants included in the photoactive region 530 is omitted from the photoactive region 560, or vice versa. The photoactive regions can form or include any type of heterojunction of the present disclosure.

In certain embodiments, the photovoltaic device 500 can comprise a first subcell and a second subcell, wherein the first subcell includes one or more of the following components: the anode (top) 510; the hole transport layer and/or hole conducting layer 520; the photoactive region 530 comprising one or more n-type dopants; the electron transport layer and/or exciton-blocking layer 540; and an optional intermediate layer (not shown); and the second subcell includes one or more of the following components: the optional intermediate layer (not shown); the hole transport layer and/or hole conducting layer 550; the photoactive region 560 comprising one or more n-type dopants; the electron transport layer and/or exciton-blocking layer 570; the optionally at least partially transparent cathode (back) 580; and the substrate 590. In certain embodiments, one or more additional subcells (not shown) can be included in the photovoltaic device 500.

FIG. 3C is a schematic diagram of an organic photovoltaic device with an organic/silicon tandem structure, according to one or more embodiments of the present disclosure. In embodiments, a photovoltaic cell 600 with an organic-silicon tandem structure is provided. For example, the photovoltaic cell 600 can have the following structure:

a cathode (top) 610;

an electron transport layer and/or exciton blocking layer 620;

an organic photoactive region comprising one or more n-type dopants 630;

a hole transport layer and/or hole conducting layer 640;

an optionally at least partially transparent cathode 650;

a silicon photoactive region 660;

an optionally at least partially transparent anode (back) 670;

a substrate 680.

The photoactive regions can form or include any type of heterojunction of the present disclosure.

In certain embodiments, the photovoltaic device 600 can comprise a first subcell and a second subcell, wherein the first subcell includes one or more of the following components: the cathode (top) 610; the electron transport layer and/or exciton blocking layer 620; the organic photoactive region comprising one or more n-type dopants 630; and an optional intermediate layer (not shown); and the second subcell includes one or more of the following components: the optional intermediate layer (not shown); the hole transport layer and/or hole conducting layer 640; the optionally at least partially transparent cathode 650 comprising one or more n-type dopants; the silicon photoactive region 660; the optionally at least partially transparent anode (back) 670; and the substrate 680. In certain embodiments, one or more additional subcells (not shown) can be included in the photovoltaic device 600.

Although not shown, each of the organic photovoltaic devices with tandem structures shown in FIGS. 3A-3C can optionally further comprise an intermediate layer between each subcell. The intermediate layer can provide electrical contact between the subcells (e.g., via efficient recombination or charge collection, preferably without voltage loss). Any intermediate layers known in the art can be utilized herein and thus are not particularly limited. In embodiments, each subcell can be considered to include the intermediate layer, i.e., share the intermediate layer.

The manner in which the subcells are defined is not particularly limited. For example, in certain embodiments, the organic photovoltaic device 400 can comprise as a first subcell one or more of the following components: the cathode (top) 410; the electron transport layer and/or exciton blocking layer 420; the photoactive region 430; the hole transport layer and/or hole conducting layer 440; and the optional intermediate layer (not shown); and as a second subcell one or more of the following components: the optional intermediate layer (not shown); the electron transport layer and/or exciton blocking layer 450; the photoactive region 460; the hole transport layer and/or hole conducting layer 470; the optionally at least partially transparent anode (back) 480; and the substrate 490. While only two subcells are shown in FIGS. 3A-3C, a person of ordinary skill in the art would readily recognize that the organic photovoltaic devices 400, 500, and/or 600 can each independently further comprise one or more additional subcells, in any configuration.

These embodiments are provided as examples. Other embodiments in which the photoactive region is provided as a mixed heterojunction, hybrid planar-mixed heterojunction, and the like, are within the scope of the present disclosure. In addition, other configurations are possible, including, but not limited to, tandem cells, and the like.

The anodes 250, 310, 480, 510, 670 and/or cathodes 210, 350, 410, 580, 610 are each independently optionally transparent, at least partially transparent, or non-transparent. The material(s) used as or for the anodes 250, 310, 480, 510, 670 and/or cathodes 210, 350, 410, 580, 610 is not particularly limited.

Suitable cathode materials include, but are not limited to, metals such as magnesium, calcium, sodium, potassium, titanium, indium, yttrium, lithium, gadolinium, aluminum, silver, gold, copper, tin and lead, or alloys thereof; or multilayer structure materials such as LiF/Al, Ca/Al, Ca/Ag, Mg/Ag, LiO₂/Al, LiF/Fe, Al:Li, Al:BaF₂ and Al:BaF₂:Ba.

Suitable anode materials include, but are not limited to, metals such as vanadium, chromium, copper, zinc or gold, or alloys thereof; metal oxides such as zinc oxides, indium oxides, indium tin oxides (ITO), or indium zinc oxides (IZO); combinations of metals and oxides such as ZnO:Al or SnO₂:Sb; conductive polymers such as poly(3-methylthiophene), poly[3,4-(ethylene-1,2-dioxy)thiophene] (PEDOT), polypyrrole and polyaniline, and the like. In certain embodiments, the anode materials include indium-tin-oxide (ITO), indium-zinc-oxide (IZO), indium-zinc-tin-oxide (IZTO), aluminum-zinc-oxide (AZO), indium-tin-oxide-Ag-indium-tin-oxide (ITO—Ag-ITO), indium-zinc-oxide-Ag-indium-zinc-oxide (IZO—Ag—IZO), indium-zinc-tin-oxide-Ag-indium-zinc-tin-oxide (IZTO—Ag-IZTO), and aluminum-zinc-oxide-Ag-aluminum-zinc-oxide (AZO-Ag-AZO), or a mixture of two or more of the above. These shall not be limiting. Other materials known in the art can be utilized herein as the anodes 250, 310 and/or cathodes 210, 350, without departing from the scope of the present disclosure.

The hole transport layer can include materials selected from: phthalocyanine derivatives, naphthalocyanine derivatives, porphyrin derivatives, aromatic diamine compounds such as N,N′-bis(3-methylphenyl)-(1,1′-biphenyl)-4′-diamine (TPD) and 4,4′-bis[N-(naphthyl)-N-phenyl-amino]biphenyl (α-NPD), oxazole, oxadiazole, triazole, imidazole, imidazolone, stilbene derivatives, pyrazoline derivatives, tetrahydroimidazole, polyarylalkane, butadiene, 4,4′,4″-tris(N-(3-methylphenyl)N-phenylamino)triphenylamine (m-MTDATA), and polymeric materials such as conductive polymers including polyvinylcarbazole, polysilane, aminopyrazine derivatives, polyethylenedioxythiophene poly(styrenesulfonate) (PEDOT:PSS), any combinations thereof, and the like. In certain embodiments, the hole transport layer comprises one or more of the following: PEDOT:PSS (poly(3,4-ethylenedioxythiophene):poly(styrenesulfonate)), TFB (poly[(9,9-dioctylfluorenyl-2,7-diyl)-co-(4,4′-(N-(4-sec-butylphenyl)diphenylamine)]) or PTPD (poly[N,N-bis(4-butylphenyl)-N,N′-bis(phenyl)-benzidine]), Ir-DPBIC (tris-N,N-diphenylbenzimidazol-2-ylideneiridium(III)), N,N′-diphenyl-N,N′-bis(3-methylphenyl)-1,1′-diphenyl-4,4′-diamine (a-NPD), and 2,2′,7,7′-tetrakis(N,N-di-p-methoxyphenylamine)-9,9′-spirobifluorene (spiro-MeOTAD).

The electron transport layer can include materials selected from: bathocuproin, bathophenanthroline and derivatives thereof, silole compound, triazole compound, tris(8-hydroxyquinolinate)aluminium complex, bis(4-methyl-8-quinolinate)aluminium complex, oxadiazole compound, distyrylarylene derivatives, silole compound, TPBI (2,2′,2″-(1,3,5-benzenetrile)tris-[1-phenyl-1H-benzimidazole]).

The substrate may be a flexible polymer substrate selected from the group consisting of: polyethyleneterephthalate (PET); polyethylene naphthalate (PEN); polyethylene (PE); polyethersulfone (PES); polycarbonate (PC); polyarylate (PAT); and polyimide (PI), or steel use stainless (SUS), aluminum, steel, copper, or glass substrate.

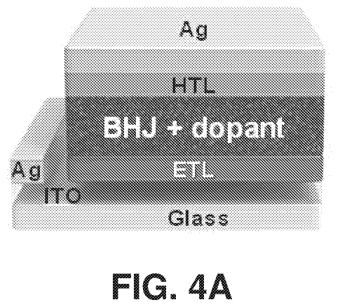

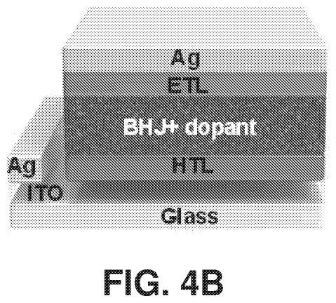

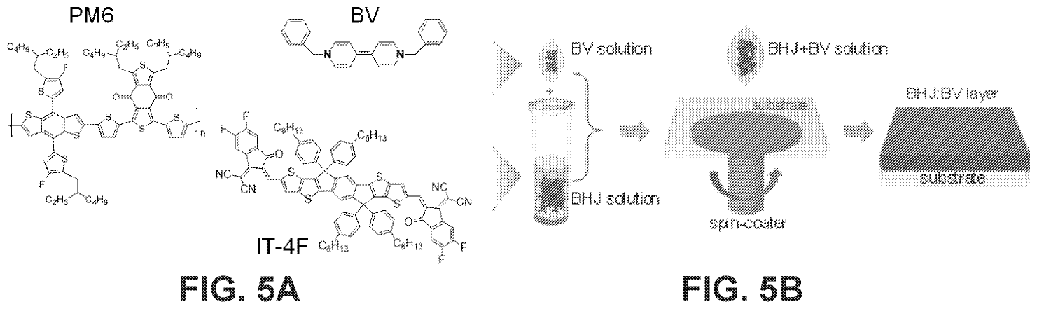

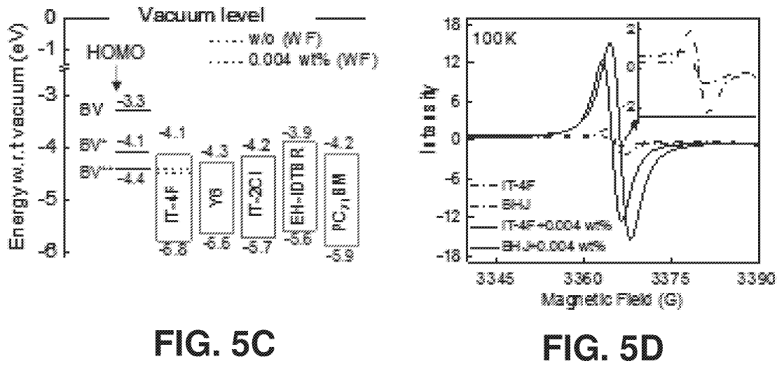

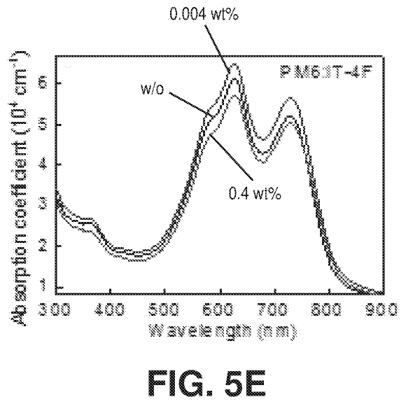

In accordance with one or more embodiments of the present disclosure, an organic photovoltaic cell is provided, as shown in FIG. 4. In certain embodiments, benzyl viologen (BV) (FIG. 5A) can be incorporated, as an n-type dopant, into the bulk heterojunction (BHJ) layer of an organic photovoltaic device (OPV). The benzyl viologen can be blended with at least one of an electron donor material and an electron acceptor material to obtain the bulk heterojunction photoactive layer. The organic photovoltaic cell can further comprise a hole transport layer between the bulk heterojunction photoactive layer and an Ag electrode, and an electron transport layer on an opposing side of the bulk heterojunction photoactive layer between an ITO layer as substrate.

Benzyl viologen can be selected for a variety of different reasons. For example, its excellent solubility in various organic solvents can enable its facile incorporation into a variety of different host materials from solution phase. Non-limiting examples of specific BHJ systems, for which impressive improvements can be observed, include binary PM6:Y6 and ternary PM6:Y6:PC₇₁BM systems, which can obtain maximum PCE values of about 16.0% and about 17.1%, respectively. Other examples of specific BHJ systems include, but are not limited to: PM6:IT-2Cl, (PTB7-Th):EH-IDTBR, and PTB7-Th:PC₇₁BM, for which similarly remarkable performance improvements were consistently obtained.

For example, the n-type dopant benzyl viologen (BV) can be incorporated into a binary BHJ system composed of the donor polymer PM6 and the small-molecule acceptor IT-4F. The cells' power conversion efficiency (PCE) can increase from 13.2% to 14.4% upon incorporation of minute amounts of BV (0.004 wt. %). The presence of BV can simultaneously act as n-type dopant and microstructure modifier. Under BV concentrations, these synergistic effects can result in balanced hole and electron mobilities, higher absorption coefficients, and increased charge-carrier density within the BHJ while significantly improve the cells' shelf lifetime. In certain embodiments, OPV cells based on the ternary PM6:Y6:PC₇₁BM:BV (0.004 wt. %) system can exhibit the maximum PCE of 17.1%, highlighting the potential of BV for further OPV optimization.

In certain embodiments, the addition of minute amounts of BV into various organic electron accepting materials or directly into BHJ systems can achieve efficient n-type doping, while also increasing optical absorption coefficients and overall device photoresponse. For example, in the case of binary OPVs based on a PM6:IT-4F blend, the addition of about 0.004 wt. % of BV can lead to a consistent PCE enhancement from about 13.2% to about 14.4%. The addition of minute amounts of BV (0.004 wt. %) in the BHJ layer can advantageously hinder aggregation, thereby optimizing phase separation, improving molecular packing, and balancing carrier transport/extraction. In certain embodiments, increasing the BV concentration to about 0.4 wt. % or greater can lead to a dramatic PCE drop (9.1%), an effect which can be ascribed to microstructural changes and increased bimolecular recombination.

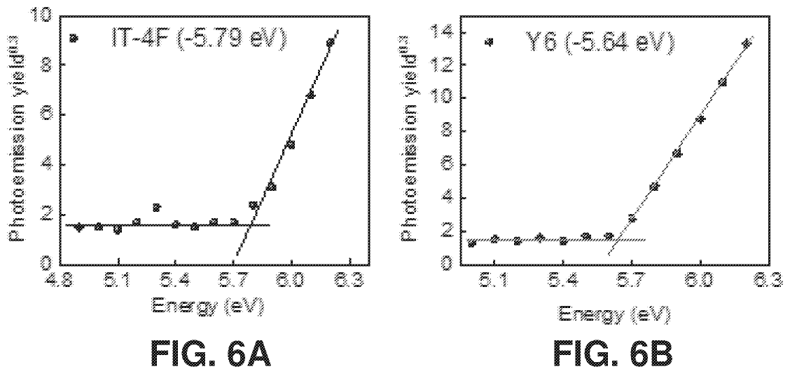

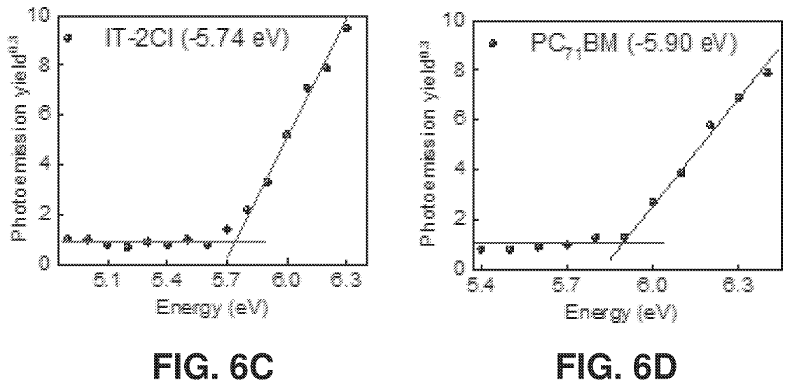

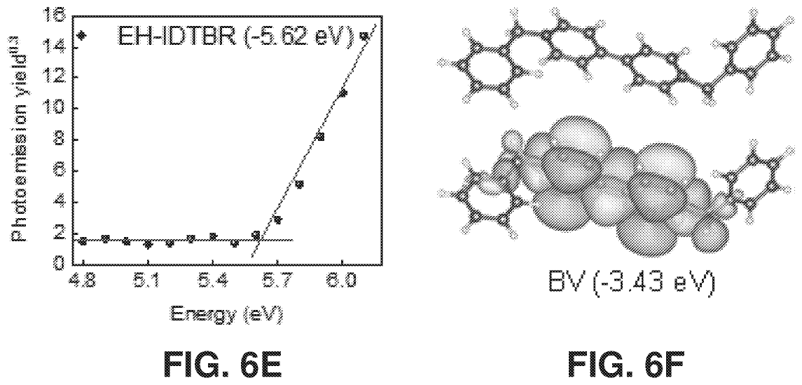

The chemical structures of the polymer donor PM6, the acceptor IT-4F, and BV are shown in FIG. 5A. In certain embodiments, dopant formulations can be prepared by blending the desired amount of BV solution with neat PM6, IT-4F, or PM6:IT-4F blend solutions and stirring at about room temperature for about 2 hours before spin-coating, e.g., onto a substrate (FIG. 5B). The desired concentration of BV can be calculated as a weight percentage of the solid weight mass of the donor and acceptor materials. To determine whether BV can act as an n-type dopant for a particular material, the highest occupied molecular orbital (HOMO) and the lowest unoccupied molecular orbital (LUMO) position of the acceptors can be measured by photoelectron spectroscopy in air (PESA). Results are presented in FIGS. 6A-6F and Table 1. FIG. 5C shows the energy levels of the various materials. The HOMO level of BV was calculated to be about −3.43 eV using density functional theory (DFT), which is quite close to the literature value (−3.3 eV). Advantageously, the HOMO of the neutral BV can be significantly higher than the LUMO of various acceptor molecules, such as IT-4F, Y6, IT-2Cl, EH-IDTBR, and PC₇₁BM. This favourable energy offsets can support the possibility of electron transfer from the HOMO of BV to the LUMO of the acceptors, leading to n-type doping.

TABLE 1
LUMO and HOMO on various materials films
measured by PESA and DFT

| | PESA | | DFT | Ref. |
|---|---|---|---|---|
| | LUMO | HOMO | HOMO | HOMO |
| Material | [eV] | [eV] | [eV] | [eV] |
| BV | — | — | −3.43 | −3.28¹ |
| IT-4F | −4.14 | −5.79 | — | — |
| Y6 | −4.29 | −5.64 | — | — |
| IT-2Cl | −4.17 | −5.72 | — | — |
| EH-IDTBR | −3.92 | −5.59 | — | — |
| PC₇₁BM | −4.15 | −5.90 | — | — |

In certain embodiments, Kelvin Probe (KP) measurements can be utilized to determine the work function (WF) of IT-4F before (w/o) and after BV (about 0.004 wt. %) doping (dash lines in FIG. 5C). In certain embodiments, the WF can increase by 100 meV, from −4.5 to −4.4 eV, indicating increased carrier density, thus n-type doping of the IT-4F. (Table 2) Additional experimental support of the n-type doping effect can be obtained via electron paramagnetic resonance (EPR) measurements. For example, as shown in FIG. 5D, neat IT-4F and PM6:IT-4F blends exhibited very small EPR signals when measured at about 100 K. Upon the addition of small amounts of BV (0.004 wt. %), the EPR signals for both neat and blend films increased by approximately 15 times, suggesting the formation of radical anions due to electron transfer from BV. BV thus can act as an n-type dopant for the IT-4F, as well as the PM6:IT-4F blend.

TABLE 2
Work function of PM6 and IT-4F
measured by Kelvin Probe

| Solid surface | Work function [eV] |
|---|---|
| 0 wt. % | −4.5 |
| IT-4F | |
| 0.004 wt. % | −4.4 |

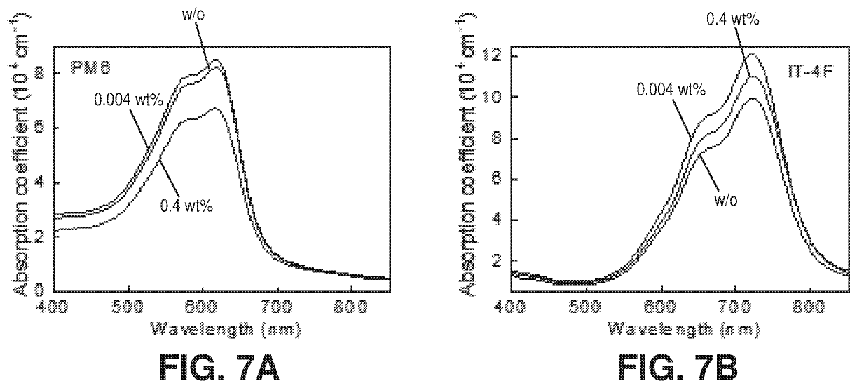

FIG. 5E and FIGS. 7A-7B display the absorption spectra for neat PM6, IT-4F, and PM6:IT-4F blend films. Surprisingly, the addition of minute amounts of BV (0.004 wt. %) can enhance the absorption coefficient (a) of IT-4F by up to about 21% (720 nm). In comparison, about 4% enhancement of a was observed for PM6 (at 620 nm) after the addition of a similar amount of BV. In the case of the PM6:IT-4F blend doped with about 0.004 wt. % BV, a can increase by approximately 7% (630 nm) and 9% (730 nm), when compared to neat PM6:IT-4F layers. Increasing the BV concentration to about 0.4 wt. % or greater can reduce a for PM6 from about 8.2×10⁴ to 6.7×10⁴ cm⁻¹ and, for IT-4F, a can increase by approximately 10% (FIGS. 7A-7B). In the case of PM6:IT-4F layers, the addition of about 0.4 wt. % BV can achieve an overall decrease of a by approximately 7% at 630 nm and 4% at 730 nm. These results show that the presence of BV can affect the electronic properties, as well as the optical properties of the individual materials and their blends.

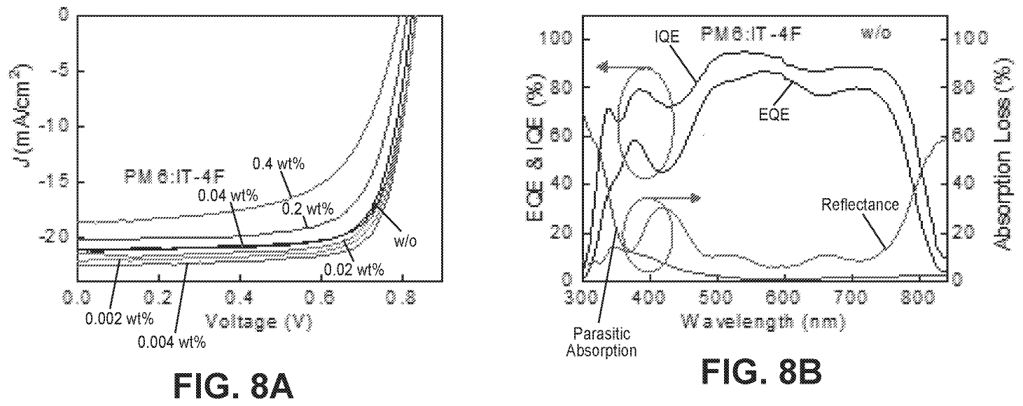

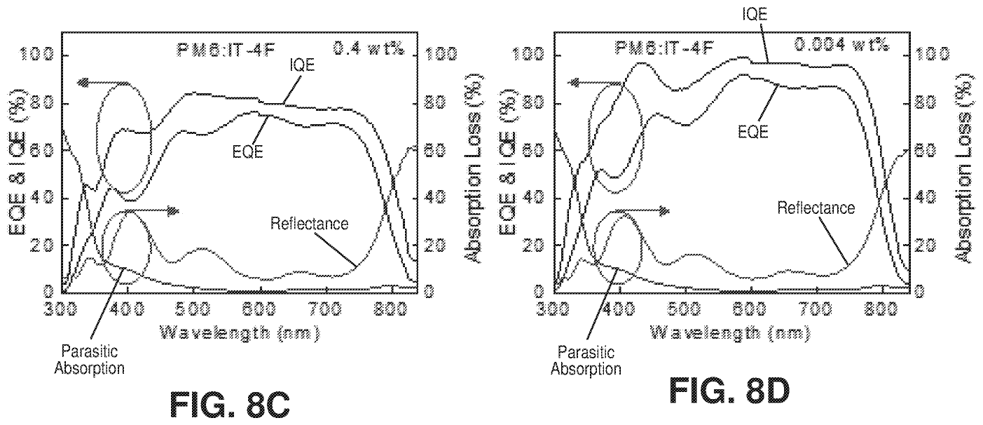

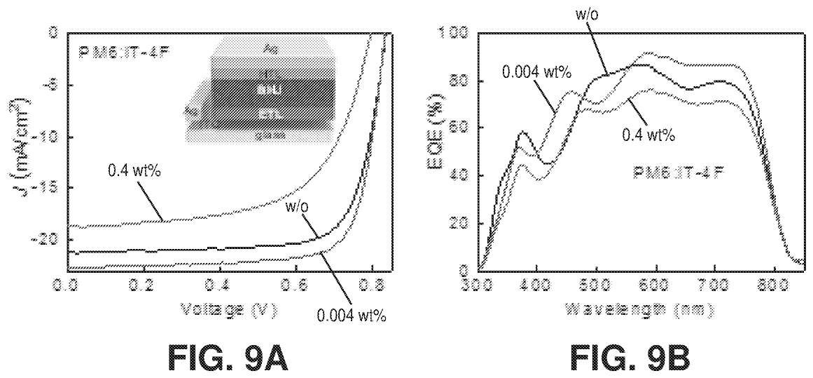

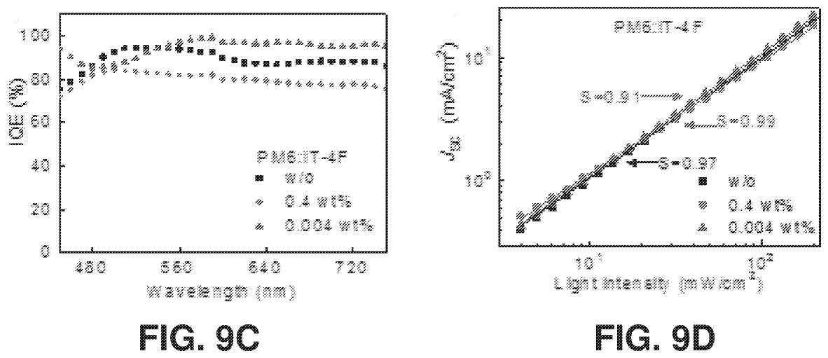

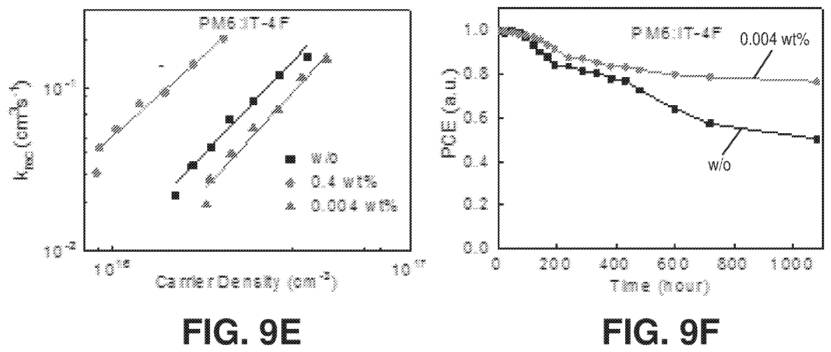

In certain embodiments, the impact of BV doping on the photovoltaic properties of PM6:IT-4F cells based on the inverted device architecture (ITO/ZnO/BHJ/MoO₃/Ag) can be demonstrated. First, the cells' performance can be optimized by changing the BV concentration from 0.002 to 0.4 wt. % (FIG. 8A and Table 3). FIG. 9A presents the current density-voltage (J-V) characteristics of the representative cells based on undoped and BV-doped BHJs. Table 4 summarizes the important device parameters and their statistical distributions.

TABLE 3
Summary of photovoltaic operating parameters for PM6:IT-4F OPVs
doped with different weight ratios of BV, measured under AM 1.5 G
illumination (100 mW/cm²).

| BV | BV | | J_{SC} (Jcal)^{a} | | PCEₘₐₓ |
|---|---|---|---|---|---|
| [wt. %] | [mol %] | V_{OC} [V] | [mA/cm²] | FF | (PCE_{avg})^{b} [%] |
| 0 | 0 | 0.83 | 21.1 (20.5) | 0.75 | 13.2 (12.8 ± 0.2) |
| 0.4 | 51.50 | 0.79 | 18.7 (18.3) | 0.61 | 9.1 (8.8 ± 0.2) |
| 0.2 | 25.75 | 0.81 | 20.3 | 0.71 | 11.7 (11.1 ± 0.4) |
| 0.04 | 5.15 | 0.82 | 21.2 | 0.75 | 13.1 (12.7 ± 0.3) |
| 0.02 | 2.58 | 0.83 | 21.5 | 0.76 | 13.6 (13.1 ± 0.3) |
| 0.004 | 0.52 | 0.83 | 22.7 (22.0) | 0.76 | 14.4 (13.9 ± 0.3) |
| 0.002 | 0.26 | 0.83 | 22.2 | 0.75 | 13.9 (13.3 ± 0.4) |

^{a}J_{cal} values in brackets were calculated from EQE measurements.
^{b}PCE_{avg} values in brackets represent averages from 20 devices.

TABLE 4
Summary of operating parameters of solar cell based on PM6:IT-4F without
(w/o) and with BV dopant (concentration: 0, 0.004, and 0.4 wt. %).

| | BV | BV | | J_{SC} (J_{cal})^{a} | | PCEₘₐₓ (PCE_{avg})^{b} | R_{S} |
|---|---|---|---|---|---|---|---|
| BHJ system | [wt. %] | [mol %] | V_{OC} [V] | [mA/cm²] | FF | [%] | [Ω cm²] |
| | 0 | 0 | 0.83 | 21.1 (20.5) | 0.75 | 13.2 (12.8) | 3.4 |
| PM6:IT-4F | 0.4 | 51.50 | 0.79 | 18.7 (18.3) | 0.61 | 9.1 (8.8) | 6.0 |
| | 0.004 | 0.52 | 0.83 | 22.7 (22.0) | 0.76 | 14.4 (13.9) | 2.7 |

In certain embodiments, undoped devices can exhibit a maximum PCE value of about 13.2% with a short-circuit current (J_{SC}) of about 21.2 mA/cm², an open circuit voltage (V_{OC}) of about 0.83 V, a fill factor (FF) of about 0.75, and series resistance (R_{S}) of about 3.4 Ωcm². This PCE value is comparable to the published result for PM6:IT-4F OPVs (13.2%) based on a similar inverted device architecture. Surprisingly, in certain embodiments, when 0.004 wt. % of BV is added into the BHJ layer, the cell's PCE can increase sharply to about 14.4%. For example, this enhancement can be accompanied by a significantly increased J_{SC} (about 22.7 mA/cm²), a slightly improved FF (about 0.76), and a reduced R_{S} (about 2.7 Ωcm²). In certain embodiments, increasing the BV concentrations to about 0.4 wt. % can degrade performance, resulting in, for example, reduced PCE (about 9.1%), V_{OC} (about 0.79 V), J_{SC} (about 18.7 mA/cm²), and FF (about 0.61), while increasing the R_{S} (about 6.0 Ωcm²).

FIG. 9B displays the external quantum efficiency (EQE) spectra of the PM6:IT-4F cells. In certain embodiments, for both neat and doped devices, integrated current density values deduced from EQE spectra can closely match the values obtained from the J-V measurements within ±4%. Surprisingly, the addition of 0.004 wt. % BV into the BHJ can enhance photoresponse by approximately ≈10.5% in the range of 560-780 nm, as compared to the neat (w/o) device, contributing to a measured 7.6% increase in J_{SC}. In certain embodiments, increasing the BV concentration to about 0.4 wt. % can reduce photoresponse, especially in the spectral range of 500-780 nm, to a J_{SC} reduction of about 11.3% and a significantly lower PCE (about 11.9%). The internal quantum efficiency (IQE) spectra was measured as shown in FIG. 8B-8D. The average IQE of optimally BV-doped cells (0.004 wt. %) is about 94.2% in the range of 450-750 nm, with its maximum value reaching about 99.0% at 580 nm (FIG. 9C). In comparison, the average IQEs for the neat (w/o) and 0.4 wt. % BV-doped cells can be about 89.2% and 79.9%, respectively. The higher average IQEs of the optimally doped cells suggest that a larger portion of the absorbed photons can be converted to free carriers which can then be efficiently collected by the electrodes.

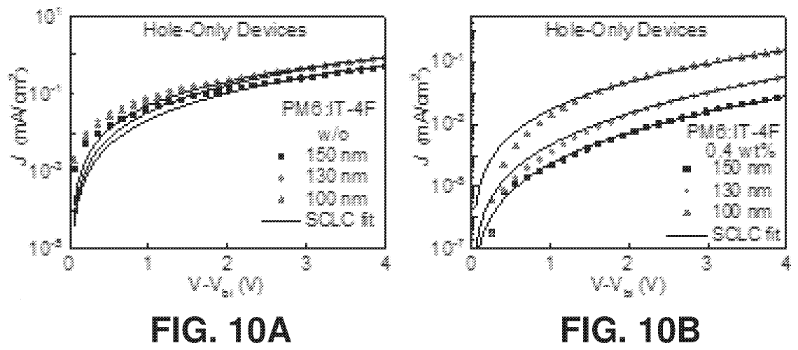

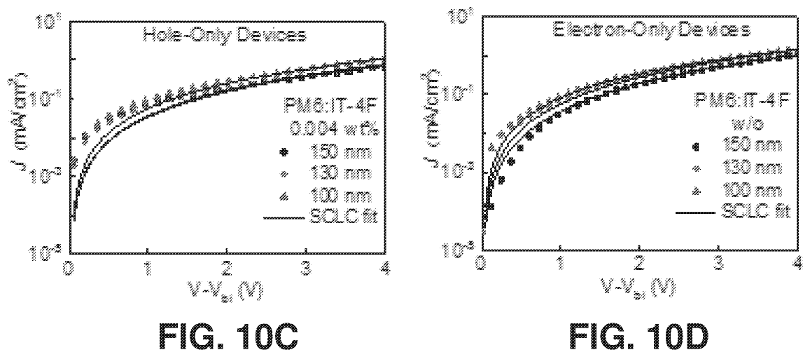

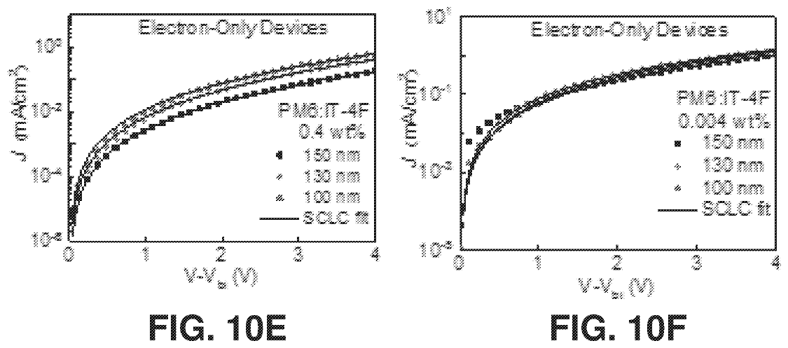

In certain embodiments, the hole/electron mobilities in PM6:IT-4F films, with different layer thicknesses (100-150 nm), can be measured using the space-charge limited current (SCLC) method to evaluate the origin of the performance enhancement upon doping (FIGS. 10A-10F and Table 5). The device structures were glass/ITO/PEDOT:PSS/BHJ/MoO₃/Ag (Hole-only devices) and glass/ITO/ZnO/BHJ/PFN-Br/Ag (Electron-only devices). The electric-field dependent SCLC mobility was estimated using Equation Si:

$$J ( V ) = \frac{9}{8} {ε}_{0} {ε}_{r} {μ}_{0} exp ( 0.89 β \sqrt{\frac{V - {V}_{bi}}{L}} ) \frac{{( V - {V}_{bi} )}^{2}}{{L}^{3}} \qquad ( S1 )$$

| Definition | Variable | Units |
|---|---|---|
| zero-field mobility | μ₀ | cm² V⁻¹ s⁻¹ |
| film thickness | L | cm |
| dark current density | J | mA cm⁻² |
| Voltage | V | V |
| vacuum permittivity | ε₀ (8.854 × 10⁻¹²) | A²s⁴kg⁻¹m⁻³ |
| dielectric constant | εᵣ (3) | |
| field activation factor | β | cm^{1/2}V^{-1/2} |

For BHJ layers with high BV concentration of about 0.4 wt. %, both the hole (μₕ) and electron (μₑ) mobilities can increase with decreasing layer thicknesses. This may not be the case for neat and optimally doped (i.e. 0.004 wt. %) PM6:IT-4F layers, for which the carrier mobilities can remain relatively thickness-independent. Interestingly, for PM6:IT-4F films with about 0.004 wt. % BV (thickness of about 100 nm), the μₕ and μₑ can appear approximately 62% and 121% higher than values measured for the undoped (w/o) layers. This can be attributed to the synergistic effects of doping, including improved charge transport due to trap screening and better molecular packing. In certain embodiments, increasing the BV concentration to about 0.4 wt. % can dramatically reduce the mobility of both carriers (μₕ=3.1×10⁻⁶ cm² V⁻¹ s⁻¹ and μₑ=7.9×10⁻⁶ cm² V⁻¹ s⁻¹). While not wishing to be bound to a theory, the latter effect is believed to be the primary reason for the degradation of the cell's parameters (FIG. 9A and Table 4).

TABLE 5
Zero-field hole and electron mobilities of PM6:IT-4F doped
with 0 wt. % (w/o), 0.4 wt. %, and 0.004 wt. % BV and for
different film thicknesses.

| | Film | | | |
|---|---|---|---|---|
| BV | Thickness | | | |
| [wt. %] | [nm] | μₕ [cm² V⁻¹s⁻¹] | μₑ [cm² V⁻¹s⁻¹] | μₑ/μₕ |
| w/o | 150 | (2.2 ± 0.2) ×10⁻⁴ | (1.3 ± 0.2) ×10⁻⁴ | 0.59 |
| | 130 | (2.3 ± 0.2) ×10⁻⁴ | (1.4 ± 0.5) ×10⁻⁴ | 0.61 |
| | 100 | (2.1 ± 0.5) ×10⁻⁴ | (1.4 ± 0.7) ×10⁻⁴ | 0.66 |
| 0.4 | 150 | (1.7 ± 0.2) ×10⁻⁸ | (5.6 ± 1.6) ×10⁻⁶ | 329.41 |
| | 130 | (1.6 ± 0.8) ×10⁻⁷ | (7.9 ± 1.1) ×10⁻⁶ | 49.38 |
| | 100 | (1.1 ± 0.7) ×10⁻⁶ | (1.4 ± 0.3) ×10⁻⁵ | 12.73 |
| 0.004 | 150 | (2.5 ± 0.6) ×10⁻⁴ | (1.9 ± 0.1) ×10⁻⁴ | 0.76 |
| | 130 | (3.1 ± 0.8) ×10⁻⁴ | (2.7 ± 0.2) ×10⁻⁴ | 0.87 |
| | 100 | (3.4 ± 0.5) ×10⁻⁴ | (3.1 ± 0.7) ×10⁻⁴ | 0.91 |

An unbalanced μₑ/μₕ ratio can affect both the FF and J_{SC} of OPVs. In PM6:IT-4F films containing a high concentration of BV (0.4 wt. %), the μₑ can be significantly higher than u, with the difference becoming more pronounced in thicker layers where the μₑ/μₕ ratio is found to increase from ≈13 (100 nm) to ≈329 (150 nm). Such unbalanced charge transport can lead to space charge build-up and recombination, which may be responsible for observed deterioration in J_{SC} (18.7 mA/cm²) and FF (0.61). A well-balanced μₑ/μₕ ratio of 0.91 can be obtained for BHJs with ultralow BV concentrations (0.004 wt. %) resulting in the higher J_{SC} (22.7 mA/cm²) and slightly enhanced FF (0.76) as compared to undoped cells. Thus, the presence of BV molecules can affect charge transport.

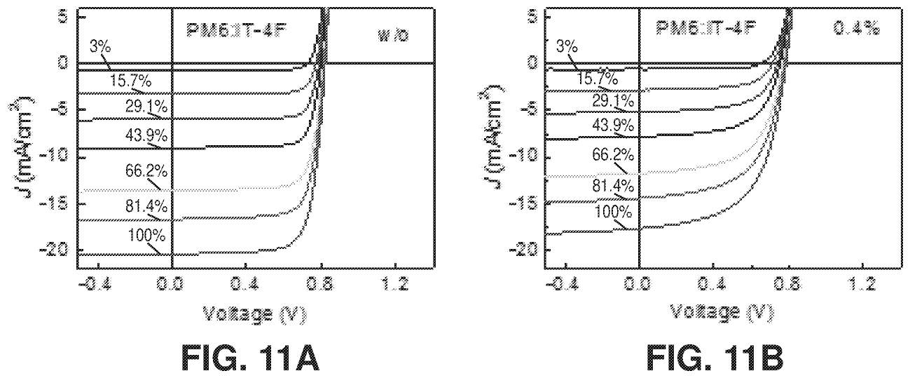

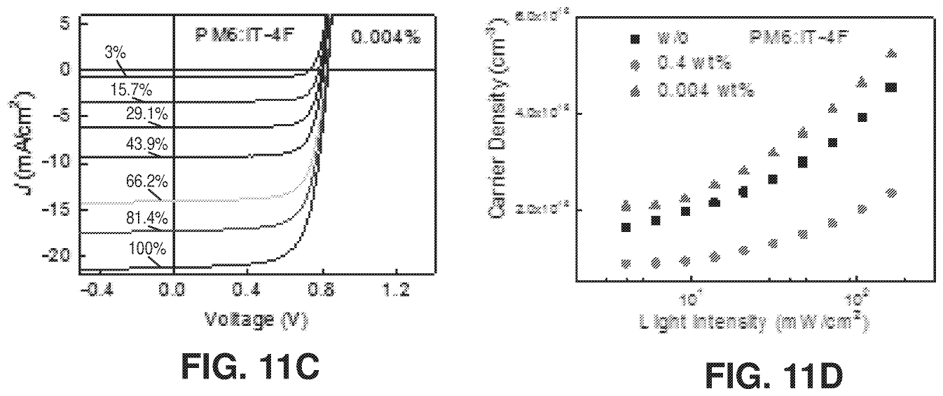

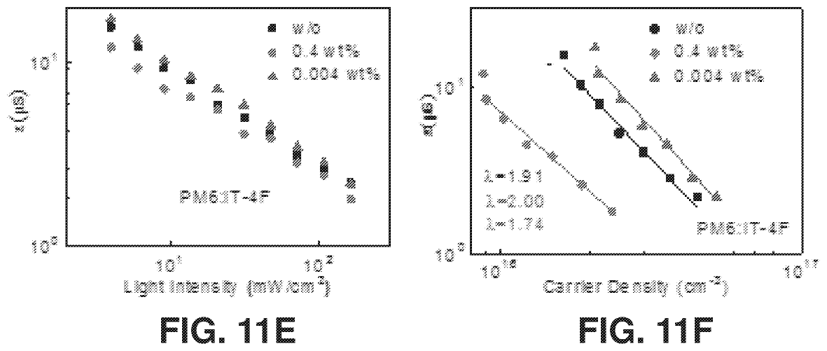

In certain embodiments, the impact of BV dopant on charge carrier recombination in all OPV cells can be examined via light intensity (Pᵢₙ in W/cm²) dependence J-V measurements (FIG. 11A-11C). For organic BHJ cells, the J_{SC} usually follows the power-law J_{SC}∝Pᵢₙ^{S} where S is the power factor. A linear dependence of J_{SC} on Pᵢₙ(S≈1) can be expected in the absence of any bimolecular recombination loses where all photogenerated carriers are successfully extracted from the device. A value of S<1, on the other hand, can be indicative of the existence of bimolecular recombination. FIG. 9D displays the results and the corresponding S values. For cells doped with 0.004 wt. % BV, an S value of 0.99 can be obtained, compared to 0.97 and 0.91 measured for undoped and 0.4 wt. % BV-doped cells, respectively. The presence of BV at ultralow concentration thus can lead to more efficient carrier collection and negligible bimolecular recombination.

In certain embodiments, further insights into charge recombination across the device with respect to the BV employed can be inferred from charge extraction (CE) and transient-photovoltage (TPV) measurements. As shown in FIG. 11D, the carrier density (n) within the cell can increase upon addition of about 0.004 wt. % BV. Surprisingly, increasing the BV concentration to about 0.4 wt. % can result in a sharp drop in the charge density across the entire studied range of light intensities. This trend can be in agreement with the dependence of J_{SC} seen in the J-V curves (FIGS. 11A-11C). The carrier lifetime (z) can also depend on the BV concentration (FIG. 11E). Devices with 0.004 wt. % BV can exhibit slightly longer lifetimes as compared to undoped (w/o) and 0.4 wt. % doped cells. Using this information, the bimolecular recombination rate constants (k_{rec}) can be inferred using k_{rec}=1/(λ+1)nτ, where λ is the recombination order determined from the data analysis presented in FIG. 11F. FIG. 9E shows the dependence of k_{rec} as a function of the carrier densities, for all three cells i.e. w/o, 0.004 wt. %, and 0.4 wt. % doped. In line with the previous CE analysis, ultra-low BV doping (0.004 wt. %) can yield the lowest k_{rec} and higher n.

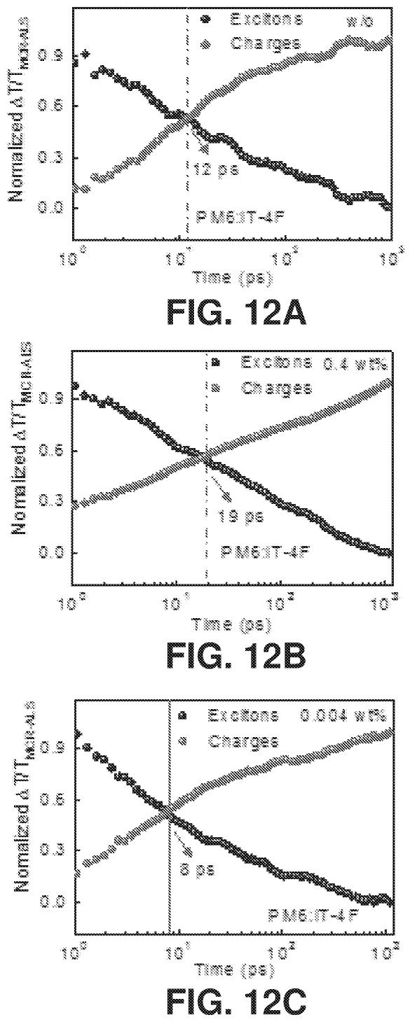

To investigate the possible impact of BV-doping on the charge generation dynamics within the BHJ layer, picosecond-nanosecond transient absorption (ps-ns TA) spectroscopy measurements can be performed. To de-convolute the contributions of singlet excitons and charges from the TA spectra, multivariate curve resolution alternative least square (MCR-ALS) method can be used. The MCR-ALS analysis can show singlet excitons at early delay times and charges on longer time scales. The component-associated dynamics obtained by MCR-ALS analysis for the undoped (w/o) and BV-doped (0.004 and 0.4 wt. %) PM6:IT-4F systems are plotted in FIGS. 12A-12C. As mentioned, the exciton decay starts after 1 ps, and the charge generation immediately follows. A direct comparison of the charge carrier dynamics of the PM6:IT-4F system can show a delayed and diffusion-limited charge generation in all three systems, where the process takes about 12, 19, and 8 ps for w/o, 0.4 wt. %, and 0.004 wt. % systems, respectively, to reach ≈50% of the maximum charge signal. Accordingly, ultra-low doping with BV (0.004 wt. %) can improve the charge carrier generation.

The impact of BV doping on shelf-stability of PM6:IT-4F solar cells can be evaluated. In certain embodiments, as-fabricated and unencapsulated devices can be stored inside a nitrogen glove box (O₂ and H₂O<10 ppm) for over 1000 h and characterized via intermittent J-V measurements under simulated solar irradiation. Such studies can, for example, provide valuable information on the evolution of the BHJ microstructure from an often kinetically frozen state reached during layer processing to a more thermodynamically stable phase over time, and/or changes occurring at the BHJ-electrode(s) interface(s). FIG. 9F shows the evolution of PCE for undoped PM6:IT-4F (0 wt. %) and n-type doped PM6:IT-4F:BV (0.004 wt. %) BHJ solar cells. For both cells, the PCE can decrease during the first 200 h. While not wishing to be bound to a theory, it is believed that this can be attributed to morphology changes and/or diffusion of atmospheric oxidants that remain present inside the glovebox albeit at low concentrations. In certain embodiments, the PCE of BV-doped solar cells can remain at ≈91% of its initial value as compared to that of the undoped device (≈84%). In certain embodiments, the doped device can retain its superior stability even after 1000 h of storage with its PCE reducing by only ≈23% as compared to that of undoped device (≈50%). Since, in both cells, the BHJ-electrode(s) interface(s) remain the same, any differences in the PCE degradation can likely be ascribed to changes in the microstructure of the BHJ layer. These results demonstrate the potential of BV-doping for stabilizing the microstructure of the BHJ.

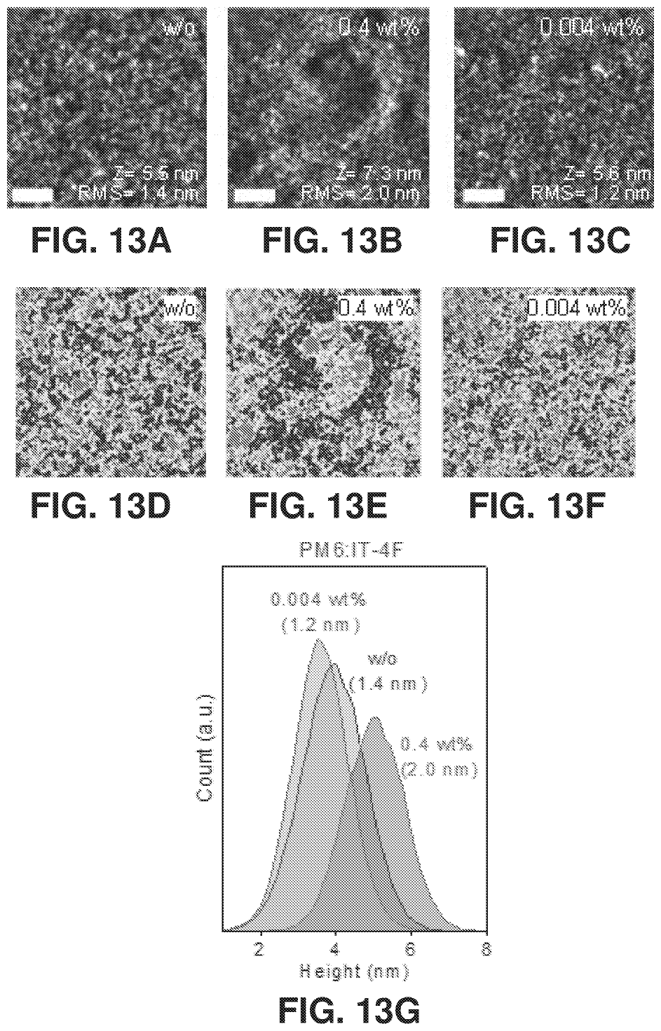

The impact of BV on the surface morphology of the BHJ can be further examined via atomic force microscopy (AFM). FIGS. 13A-13F presents the AFM topography images for the undoped and doped BHJ layers deposited on glass substrates. As shown, the surface of BHJs with 0.4 wt. % BV can contain large aggregates, while layers with 0.004 wt. % BV can show significantly smaller features that are comparable to those seen in the undoped film. The different layer topographies can result in differences in the surface root-mean-square (rms) roughness with the lightly doped (0.004 wt. %) layer exhibiting the lowest rms (1.2 nm), followed by the undoped (1.4 nm) and highly doped 0.4 wt. % (2.0 nm) films. This trend is illustrated in the surface height histograms shown in FIG. 13G, where the height distribution for the 0.004 wt. % layer undergoes a clear shift towards lower heights, which is indicative of surface smoothening.

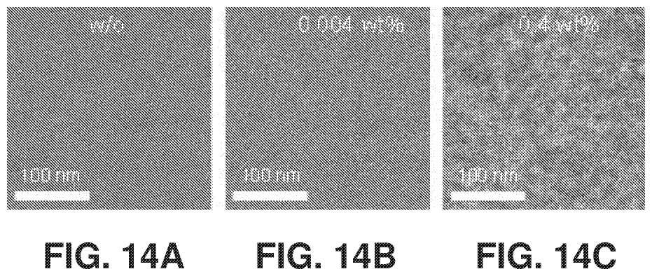

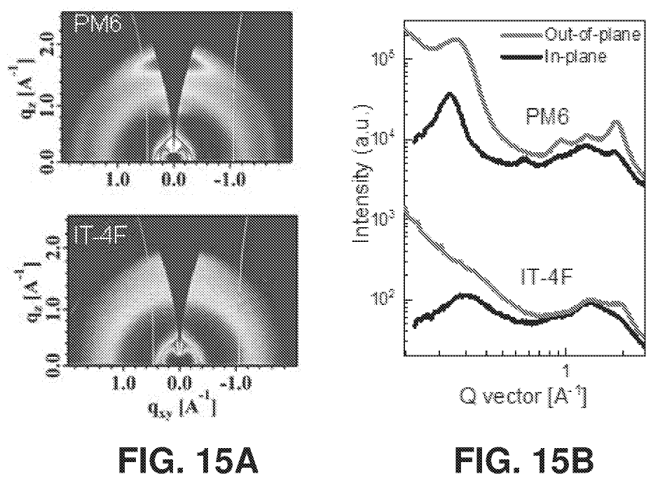

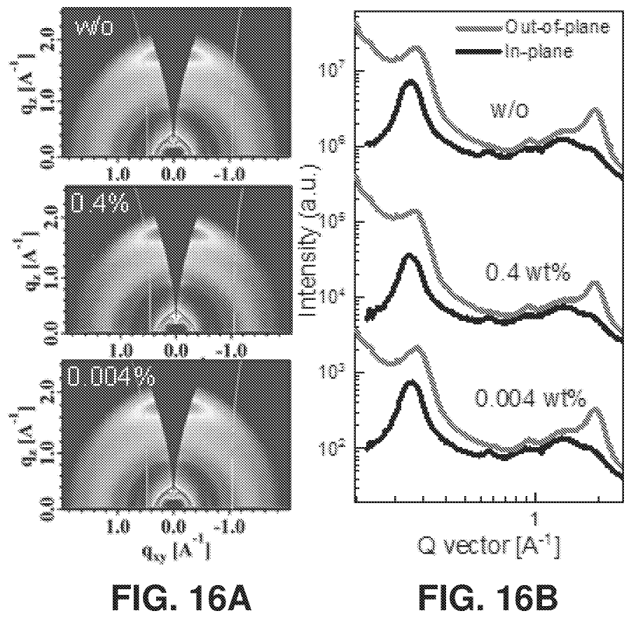

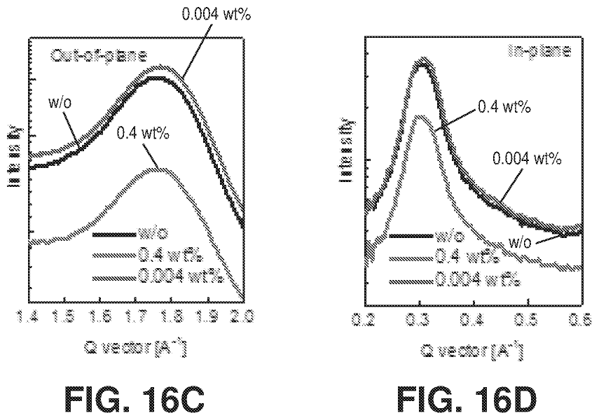

Complementary information to the aforementioned AFM data can be obtained via transmission electron microscopy (TEM) and grazing incident wide-angle X-ray scattering (GIWAXS) measurements. FIGS. 14A-14C show TEM images of the different layers, which can lead to a similar conclusion to that of the AFM analysis. Specifically, in certain embodiments, BHJs with ultralow BV-doping (0.004 wt. %) can exhibit similar morphologies to undoped layers. However, in certain embodiments, increasing the BV concentration to 0.4 wt. % can result in the formation of larger domains. FIGS. 15A-15B display GIWAXS data for the undoped PM6 and IT-4F films. FIGS. 16A-16D show data measured for the undoped and BV-doped BHJ layers. In certain embodiments, the 2-D diffraction images for the undoped (w/o) BHJ (FIG. 16A), the (100) peak located at 0.30 A⁻¹ is composed of PM6 and IT-4F lamellar packing features seen in FIG. 15A. The π-π stacking at 1.77 A⁻¹ is also composed of both material features since the π-π stacking of PM6 and IT-4F are located at 1.72 A⁻¹ and 1.80 A⁻¹, respectively. In certain embodiments, no obvious changes, i.e. appearance or vanishing of new peaks, are observed upon doping (FIG. 16B), meaning that the presence of BV does not affect the molecular orientation. The crystalline stacking order of the systems can be studied by comparing the crystal intensity in the various samples of the same thickness (FIGS. 16C-16D). Interestingly, in certain embodiments, the degree of microcrystallinity in the PM6:IT-4F film can reduce significantly in both out-of-plane and in-plane direction upon addition of 0.4 wt. % BV, suggesting high dopant concentrations can weaken both the lamellar packing and π-π stacking order. On the other hand, lowering the BV concentration to 0.004 wt. % can slightly enhance the crystal intensity in out-of-plane, indicating that ultralow concentrations of BV can strengthen the π-π stacking, but with negligible effect on the molecular orientation. The GIWAXS results thus can support the enhanced absorption characteristics of the PM6:IT-4F doped with 0.004 wt. % BV (FIG. 5E) and possibly the different charge generation dynamics (FIGS. 12A-12C), as well as the improved shelf stability of the cells based on PM6:IT-4F:BV (0.004 wt. %) BHJs.

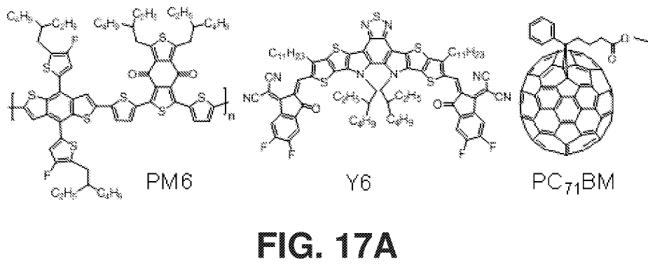

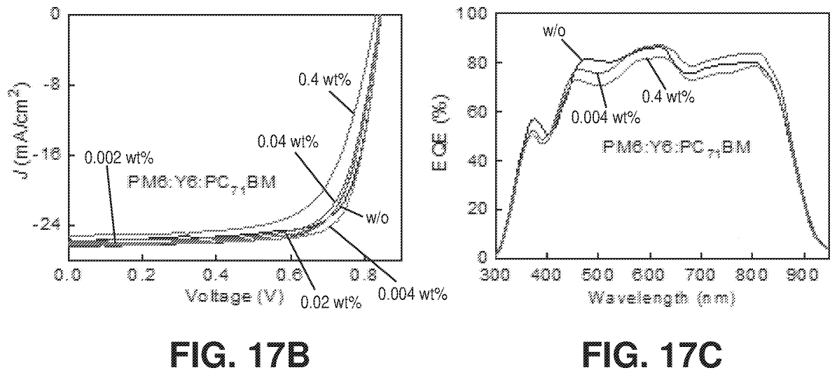

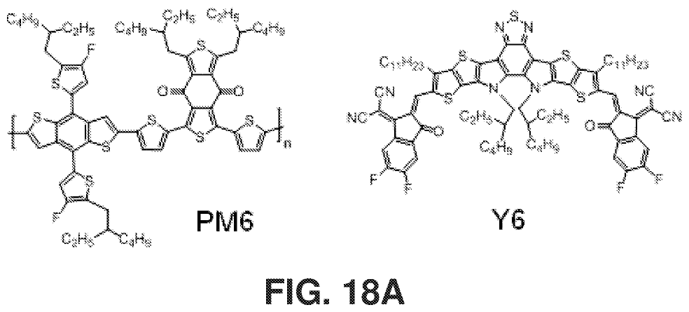

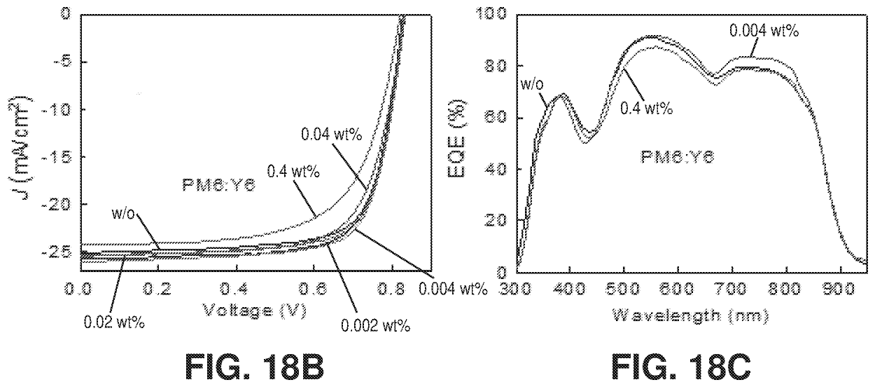

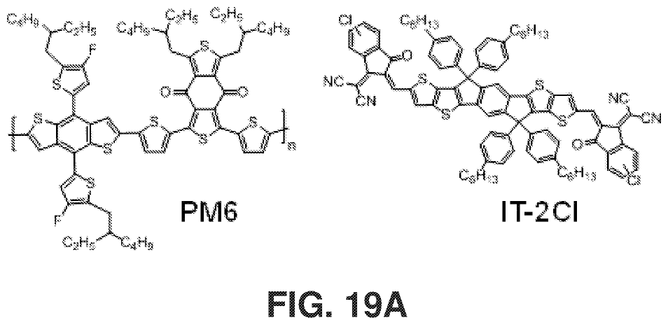

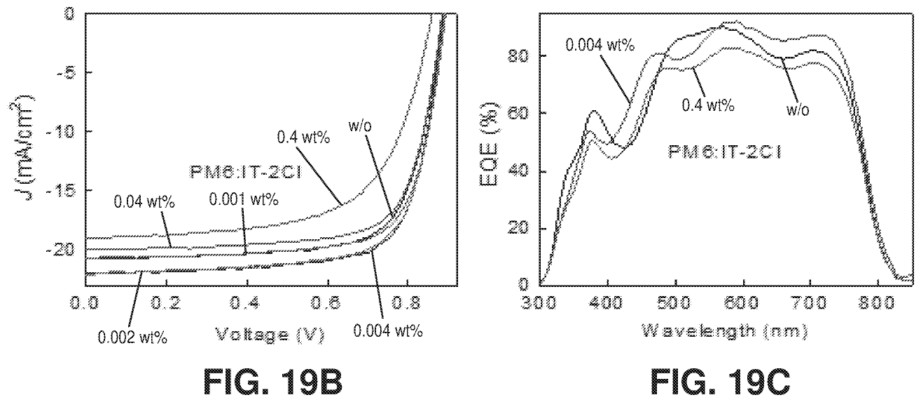

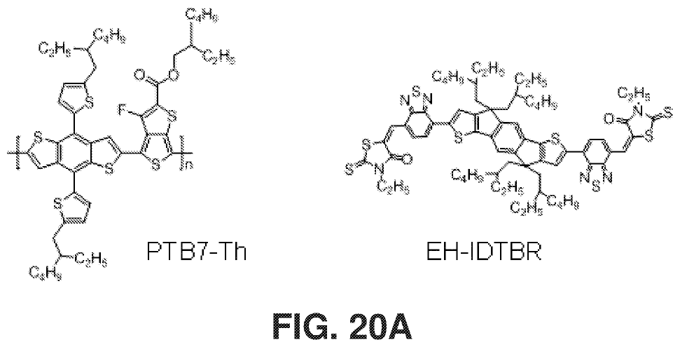

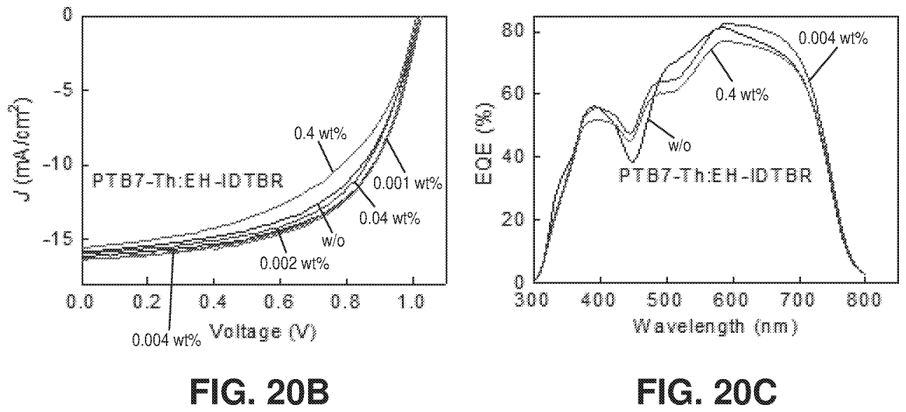

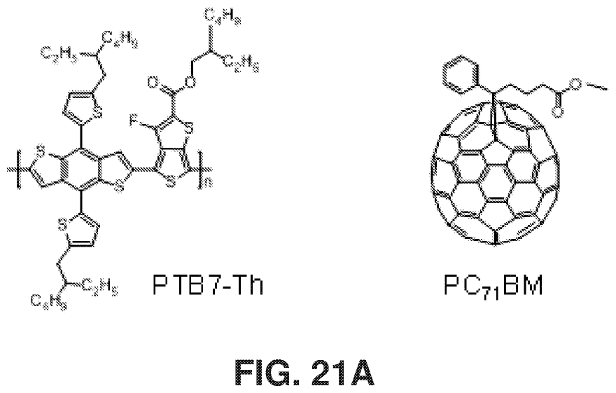

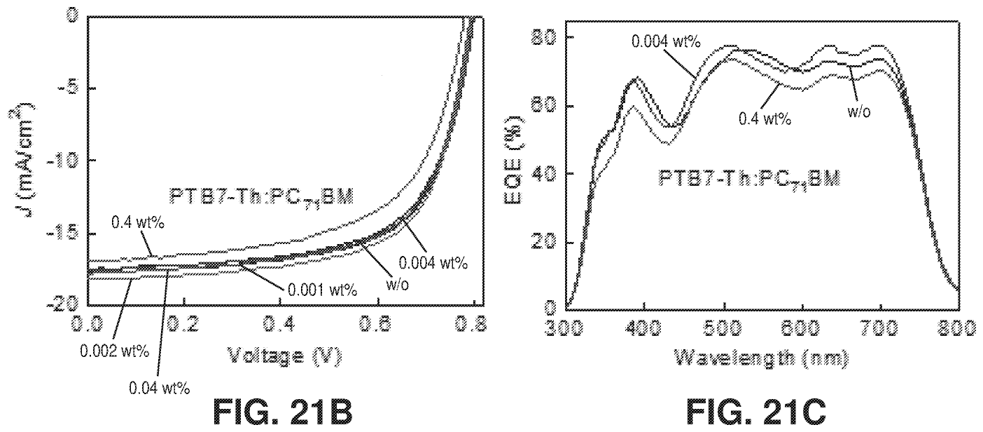

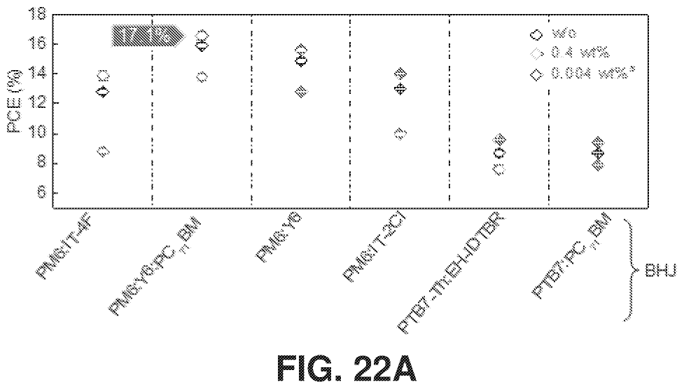

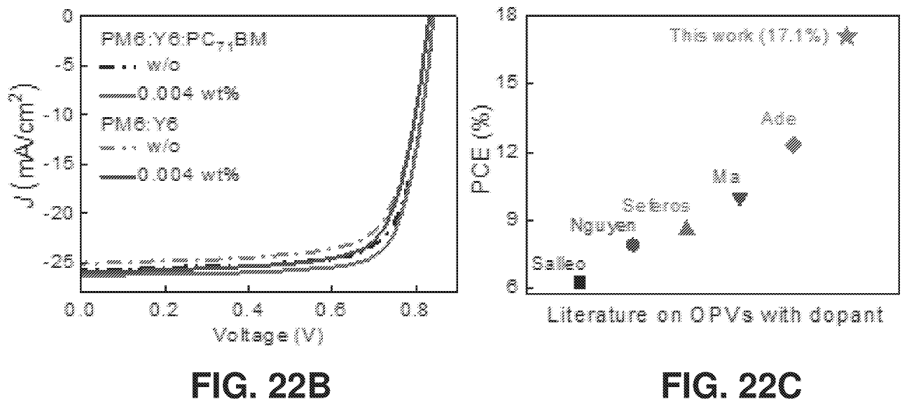

In certain embodiments, the BHJ systems include: (i) PM6:Y6:PC₇₁BM, (ii) PM6:Y6, (iii) PM6:IT-2Cl, (iv) poly[[4,8-bis[5-(2-ethylhexyl)thiophene-2-yl]benzo[1,2-b:4,5-b0]dithiophene-2,6-diyl] [3-fluoro-2-[(2-ethylhexyl)carbonyl]-thieno[3,4-b]thiophenediyl]] (PTB7-Th):EH-IDTBR, and (v) PTB7-Th:PC₇₁BM (FIGS. 17-21 and Table 6-10). The HOMO and LUMO energies of all materials used are shown in FIG. 5C. FIG. 22A presents the measured PCE for each BHJ system investigated without (w/o) and with BV in two different concentrations (0.004 and 0.4 wt. %) while Table 11 summarizes the cells' parameters. In certain embodiment, the optimal wt. % of BV for PTB7-Th:EH-IDTBR and PTB7-Th:PC₇₁BM blends is about 0.002 wt. %. In certain embodiments, the introduction of 0.004 wt. % BV in all BHJ systems can consistently enhance the cells' overall PCE when compared to undoped devices. In certain embodiments, increasing the BV concentration to 0.4 wt. % can result in performance deterioration as shown by plummeting PCE values. In certain embodiments, analysis of the device characteristics can show that, in the case of the optimally doped (0.004 wt. %) cells, the enhanced PCE can be mostly attributed to lower R_{S}, the improved J_{SC}, and the higher photoresponse, in agreement with the findings for the PM6:IT-4F-based cells. In certain embodiments, OPVs based on PM6:Y6 and PM6:Y6:PC₇₁BM can yield the highest performance with maximum PCEs of 16.0% and 17.1%, respectively (FIG. 22B). The latter value is amongst the highest reported to date for single junction OPV cells, and the highest for cells comprising molecularly-doped BHJs (FIG. 22C).

TABLE 6
Summary of photovoltaic operating parameters for PM6:Y6:PC₇₁BM
OPVs doped with different weight ratios of BV, measured under
illumination of AM 1.5 G (100 mW/cm²).

| BV | BV | V_{OC} | J_{SC} (J_{cal})^{a} | | PCEₘₐₓ |
|---|---|---|---|---|---|
| [wt. %] | [mol %] | [V] | [mA/cm²] | FF | (PCE_{avg})^{b} [%] |
| 0 | 0 | 0.84 | 25.7 (25.5) | 0.75 | 16.3 (15.9 ± 0.2) |
| 0.4 | 53.76 | 0.83 | 25.3 (24.6) | 0.67 | 14.2 (13.8 ± 0.2) |
| 0.04 | 5.38 | 0.84 | 25.8 | 0.73 | 15.9 (15.5 ± 0.2) |
| 0.02 | 2.69 | 0.84 | 26.5 | 0.73 | 16.3 (16.0 ± 0.1) |
| 0.004 | 0.54 | 0.84 | 26.3 (26.0) | 0.77 | 17.1 (16.6 ± 0.3) |
| 0.002 | 0.27 | 0.84 | 26.1 | 0.74 | 16.3 (16.0 ± 0.1) |

^{a}J_{cal} values in brackets were calculated from EQE measurements.
^{b}PCE_{avg} values in brackets represent averages from 20 devices.

TABLE 7
Summary of photovoltaic operating parameters for PM6:Y6
OPVs doped with different weight ratios of BV, measured
under illumination of AM 1.5 G (100 mW/cm²).

| BV | BV | V_{OC} | J_{SC} (J_{cal})^{a} | | PCEₘₐₓ (PCE_{avg})^{b} |
|---|---|---|---|---|---|
| [wt. %] | [mol %] | [V] | [mA/cm²] | FF | [%] |
| 0 | 0 | 0.83 | 25.1 (24.8)^{a} | 0.73 | 15.3 (14.9 ± 0.2)^{b} |
| 0.4 | 53.67 | 0.82 | 24.3 (24.2) | 0.66 | 13.1 (12.8 ± 0.1) |
| 0.04 | 5.34 | 0.83 | 25.3 | 0.71 | 14.9 (14.6 ± 0.1) |
| 0.02 | 2.67 | 0.83 | 25.7 | 0.74 | 15.7 (15.3 ± 0.2) |
| 0.004 | 0.53 | 0.83 | 26.0 (25.5) | 0.74 | 16.0 (15.6 ± 0.2) |
| 0.002 | 0.27 | 0.83 | 25.4 | 0.74 | 15.6 (15.5 ± 0.2) |

^{a}J_{cal} values in brackets were calculated from EQE measurements.
^{b}PCE_{avg} values in brackets represent averages from 20 devices.

TABLE 8
Summary of photovoltaic operating parameters for PM6:IT-2Cl
OPVs doped with different weight ratios of BV, measured under
illumination of AM 1.5 G (100 mW/cm²).

| BV | BV | V_{OC} | J_{SC} (Jcal)^{a} | | PCEₘₐₓ (PCE_{avg})^{b} |
|---|---|---|---|---|---|
| [wt. %] | [mol %] | [V] | [mA/cm²] | FF | [%] |
| 0 | 0 | 0.89 | 20.8 (20.4)^{a} | 0.72 | 13.3 (13.0 ± 0.1)^{b} |
| 0.4 | 51.52 | 0.86 | 19.1 (19.0) | 0.64 | 10.4 (10.0 ± 0.2) |
| 0.04 | 5.15 | 0.88 | 19.6 | 0.74 | 12.8 (12.2 ± 0.4) |
| 0.004 | 0.52 | 0.89 | 22.0 (21.7) | 0.73 | 14.3 (14.0 ± 0.1) |
| 0.002 | 0.26 | 0.89 | 22.0 | 0.72 | 14.2 (13.8 ± 0.2) |
| 0.001 | 0.13 | 0.89 | 20.1 | 0.74 | 13.6 (13.1 ± 0.3) |

^{a}J_{cal} values in brackets were calculated from EQE measurements.
^{b}PCE_{avg} values in brackets represent averages from 20 devices.

TABLE 9
Summary of photovoltaic operating parameters for PTB7-Th:EH-IDTBR
OPVs doped with different weight ratios of BV, measured under
illumination of AM 1.5 G (100 mW/cm²).

| BV | BV | V_{OC} | J_{SC} (J_{cal})a | | PCEₘₐₓ (PCE_{avg})^{b} |
|---|---|---|---|---|---|
| [wt. %] | [mol %] | [V] | [mA/cm²] | FF | [%] |
| 0 | 0 | 1.02 | 15.8 (15.9)^{a} | 0.57 | 9.1 (8.7 ± 0.2)^{b} |
| 0.4 | 38.78 | 1.01 | 15.6 (15.5) | 0.52 | 8.1 (7.6 ± 0.3) |
| 0.04 | 3.88 | 1.02 | 16.0 | 0.58 | 9.5 (9.1 ± 0.2) |
| 0.004 | 0.39 | 1.02 | 16.1 | 0.60 | 9.8 (9.3 ± 0.3) |
| 0.002 | 0.20 | 1.02 | 16.4 (15.5) | 0.60 | 9.9 (9.6 ± 0.1) |
| 0.001 | 0.10 | 1.02 | 16.3 | 0.61 | 9.8 (9.5 ± 0.1) |

^{a}J_{cal} values in brackets were calculated from EQE measurements.
^{b}PCE_{avg} values in brackets represent averages from 20 devices.

TABLE 10
Summary of photovoltaic operating parameters for PTB7-Th:PC₇₁BM
OPVs doped with different weight ratios of BV, measured under
illumination of AM 1.5 G (100 mW/cm²).

| BV | BV | V_{OC} | J_{SC} (J_{cal})^{a} | | PCEₘₐₓ (PCE_{avg})^{b} |
|---|---|---|---|---|---|
| [wt. %] | [mol %] | [V] | [mA/cm²] | FF | [%] |
| 0 | 0 | 0.80 | 17.5 (17.0)^{a} | 0.65 | 9.0 (8.7 ± 0.1)^{b} |
| 0.4 | 46.14 | 0.78 | 16.9 (16.4) | 0.61 | 8.0 (7.9 ± 0.1) |
| 0.04 | 4.61 | 0.80 | 17.5 | 0.66 | 9.2 (8.9 ± 0.1) |
| 0.004 | 0.46 | 0.80 | 17.7 | 0.66 | 9.3 (8.9 ± 0.2) |
| 0.002 | 0.23 | 0.80 | 18.2 (17.9) | 0.66 | 9.6 (9.4 ± 0.1) |
| 0.001 | 0.12 | 0.79 | 17.8 | 0.66 | 9.3 (9.2 ± 0.1) |

^{a}J_{cal} values in brackets were calculated from EQE measurements.
^{b}PCE_{avg} values in brackets represent averages from 20 devices.

TABLE 11
Summary of operating parameters of solar cell based on five different BHJ
systems without (w/o) and with two BV concentrations.

| | | | | J_{SC} (J_{cal})^{a} | | PCEₘₐₓ | R_{S} |
|---|---|---|---|---|---|---|---|
| BHJ system | BV [wt. %] | BV [mol %] | V_{OC} [V] | [mA/cm²] | FF | (PCE_{avg})^{b} [%] | [Ω cm²] |
| PM6:Y6: | 0 | 0 | 0.84 | 25.7 (25.5) | 0.75 | 16.3 (15.9) | 3.3 |
| PC₇₁BM | 0.4 | 53.76 | 0.83 | 25.3 (24.6) | 0.67 | 14.2 (13.8) | 4.5 |
| | 0.004 | 0.54 | 0.84 | 26.3 (26.0) | 0.77 | 17.1 (16.6) | 2.5 |
| | 0 | 0 | 0.83 | 25.1 (24.8) | 0.73 | 15.3 (14.9) | 2.9 |
| PM6:Y6 | 0.4 | 53.67 | 0.82 | 24.3 (24.2) | 0.66 | 13.1 (12.8) | 4.0 |
| | 0.004 | 0.54 | 0.83 | 26.0 (25.5) | 0.74 | 16.0 (15.6) | 2.8 |
| | 0 | 0 | 0.89 | 20.8 (20.4) | 0.72 | 13.3 (13.0) | 4.1 |
| PM6:IT-2C1 | 0.4 | 51.52 | 0.86 | 19.1 (19.0) | 0.64 | 10.4 (10) | 6.0 |
| | 0.004 | 0.52 | 0.89 | 22.0 (21.7) | 0.73 | 14.3 (14.0) | 3.3 |
| PTB7-Th' | 0 | 0 | 1.02 | 15.8 (15.9) | 0.57 | 9.1 (8.7) | 11.1 |
| EH-IDTBR | 0.4 | 38.78 | 1.01 | 15.6 (15.5) | 0.52 | 8.1 (7.6) | 11.3 |
| | 0.002 | 0.19 | 1.02 | 16.4 (15.5) | 0.60 | 9.9 (9.6) | 10.3 |
| PTB7-Th: | 0 | 0 | 0.80 | 17.5 (17.0) | 0.65 | 9.0 (8.7) | 5.4 |
| PC71BM | 0.4 | 46.13 | 0.78 | 16.9 (16.4) | 0.61 | 8.0 (7.9) | 6.2 |
| | 0.002 | 0.23 | 0.80 | 18.2 (17.9) | 0.66 | 9.6 (9.4) | 4.7 |

^{a}J_{cal} values in brackets were calculated from EQE measurements.
^{b}PCE_{avg} values in brackets represent averages from 20 devices.

TABLE 12
Summary of photovoltaic operating parameters for PM6:IT-4F
OPVs doped with different weight ratios of DQ, measured under
illumination of AM 1.5 G (100 mW/cm²).

| DQ | DQ | V_{OC} | J_{SC} | | PCEₘₐₓ |
|---|---|---|---|---|---|
| [wt. %] | [mol %] | [V] | [mA/cm²] | FF | [%] |
| w/o | w/o | 0.86 | 20.3 | 0.75 | 13.0 |
| 0.04 | 11.44 | 0.85 | 22.5 | 0.64 | 12.1 |
| 0.02 | 5.72 | 0.85 | 22.3 | 0.67 | 12.8 |
| 0.004 | 1.14 | 0.85 | 21.4 | 0.71 | 12.9 |
| 0.002 | 0.57 | 0.86 | 21.9 | 0.73 | 13.8 |

TABLE 13
Summary of photovoltaic operating parameters for PM6:Y6:PC₇₁BM
OPVs doped with different weight ratios of DQ, measured under
illumination of AM 1.5 G (100 mW/cm²).

| DQ | DQ | V_{OC} | J_{SC} | | PCEₘₐₓ |
|---|---|---|---|---|---|
| [wt. %] | [mol %] | [V] | [mA/cm²] | FF | [%] |
| w/o | w/o | 0.86 | 25.7 | 0.72 | 16.0 |
| 0.5 | 149.04 | 0.84 | 25.4 | 0.63 | 13.5 |
| 0.25 | 74.52 | 0.84 | 27.5 | 0.66 | 15.3 |
| 0.025 | 7.45 | 0.85 | 28.1 | 0.67 | 16.1 |
| 0.005 | 3.73 | 0.85 | 28.0 | 0.68 | 16.2 |
| 0.0025 | 0.75 | 0.85 | 28.3 | 0.68 | 16.5 |
| 0.0005 | 0.37 | 0.85 | 28.3 | 0.69 | 16.6 |

TABLE 14
Summary of photovoltaic operating parameters for PM6:IT-4F
OPVs doped with different weight ratios of EV, measured under
illumination of AM 1.5 G (100 mW/cm²).

| EV | V_{OC} | J_{SC} | | PCEₘₐₓ |
|---|---|---|---|---|
| [wt. %] | [V] | [mA/cm²] | FF | [%] |
| w/o | 0.86 | 20.3 | 0.74 | 12.9 |
| 0.4 | 0.79 | 18.2 | 0.54 | 7.8 |
| 0.2 | 0.82 | 20.4 | 0.60 | 10.1 |
| 0.04 | 0.85 | 20.1 | 0.73 | 12.8 |
| 0.02 | 0.85 | 21.4 | 0.71 | 13.0 |
| 0.004 | 0.86 | 22.2 | 0.74 | 14.2 |
| 0.002 | 0.86 | 20.5 | 0.74 | 13.0 |

TABLE 15
Summary of photovoltaic operating parameters for PM6:IT-4F
OPVs doped with different weight ratios of N-DMBI, measured
under illumination of AM 1.5 G (100 mW/cm²).

| N-DMBI | V_{OC} | J_{SC} | | PCEₘₐₓ |
|---|---|---|---|---|
| [wt. %] | [V] | [mA/cm²] | FF | [%] |
| w/o | 0.86 | 20.0 | 0.74 | 12.8 |
| 0.4 | 0.83 | 19.2 | 0.65 | 10.4 |
| 0.2 | 0.85 | 20.1 | 0.70 | 11.9 |
| 0.04 | 0.85 | 20.5 | 0.74 | 12.8 |
| 0.02 | 0.86 | 20.2 | 0.75 | 13.0 |
| 0.004 | 0.86 | 20.1 | 0.76 | 13.2 |
| 0.002 | 0.86 | 20.2 | 0.76 | 13.2 |

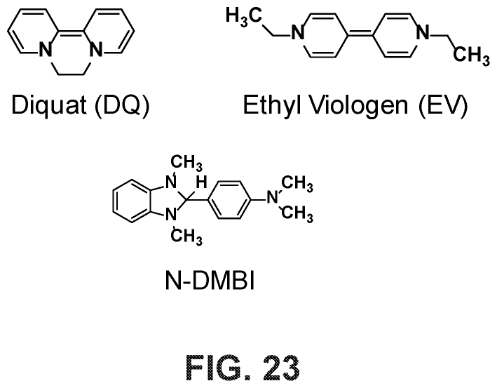

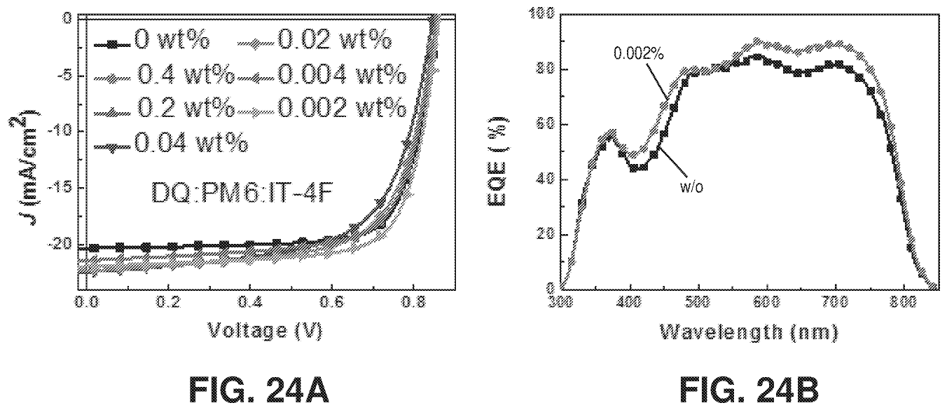

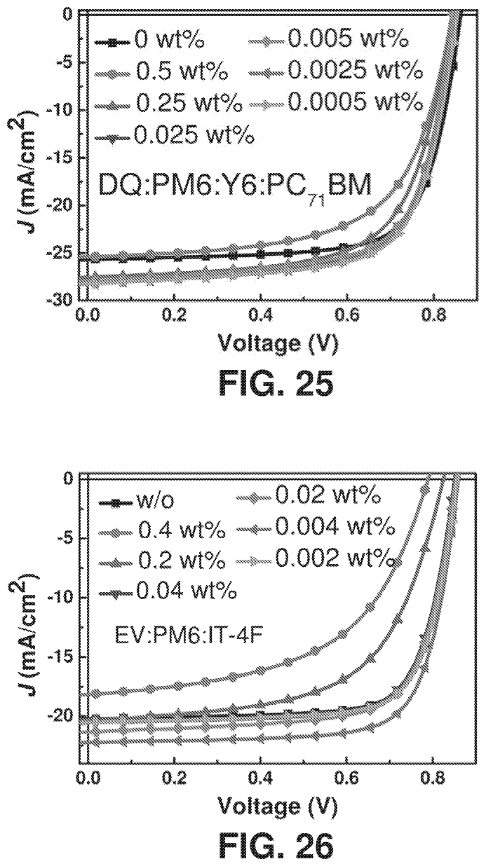

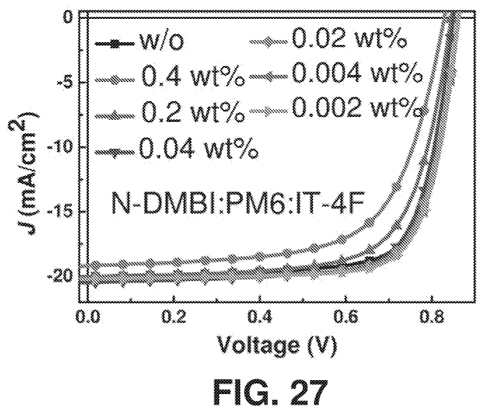

The addition of minute amounts of molecular n-type dopants, such as BV, directly into the BHJ layer thus can consistently improve and/or enhance performance of OPVs. In certain embodiments, for example, dopants like BV can be shown to act as an n-type dopant for the BHJ and secondly as a layer microstructure modifier. These synergistic effects can produce more balanced electron and hole mobilities and stronger light absorption by the photoactive layer. In embodiments comprising solar cells based on PM6:IT-4F blends, the addition of only 0.004 wt. % BV can increase the PCE from 13.2% to a maximum value of 14.4%. The enhanced PCE can be a direct result of the higher photoresponse in the longer wavelength range leading to a 7.6% increase of J_{SC}. In certain embodiments, increasing the BV concentration to 0.4 wt. % can rapidly degrade the cell's performance due to the unbalanced carrier mobilities. In certain embodiments, microstructural analysis of the as-processed BHJs indicates that the presence of BV, optionally in optimal concentrations, can strengthen the 71-71 stacking, without effecting molecular orientation. In certain embodiments, increasing the BV concentration beyond the optimized levels can weaken both the lamellar packing and 71-71 stacking order within the BHJ. In certain embodiments, the combination of these BV-induced effects can lead to a consistently improved charge generation, faster charge transport, higher charge extraction efficiency, and lower carrier recombination loses in a wide range of organic BHJs. The broad versatility of n-type dopants, such as BV, can be supported by application in ternary OPVs cells based on PM6:Y6:PC₇₁BM, among others, for which the PCE can increase from 16.3% (undoped) to 17.1% (0.004 wt. % BV). The universality of BV combined with the remarkably high PCE values obtained, makes this simple n-type dopant strategy promising for application in high-performance OPVs. Additionally, the use of other n-type dopants was explored, such as ethyl-viologen (EV), diquat (DQ), and N-DMBI for OPV (FIG. 23). As can be seen from Tables 12-15 and FIGS. 24-27, the addition of those n-dopants can improve device performance. Accordingly, the strategy, compositions, and methods disclosed herein are general and can be applied to OPVs using any of the n-type dopants and other materials disclosed herein.

In certain embodiments, device characterization is provided. UV-vis spectra were recorded on a Cary 5000 instrument in single beam mode in 1 cm quartz cuvettes. J-V measurements of solar cells were performed in an N₂ filled glove box using a Keithley 2400 source meter and an Oriel Sol3A Class AAA solar simulator calibrated to 1 sun, AM1.5G, with a KG-5 silicon reference cell certified by Newport. EQE was characterized using an EQE system (PV measurement Inc.). Measurements were performed at zero bias by illuminating the device with monochromatic light supplied from a Xenon arc lamp in combination with a dual-grating monochromator. The number of incident photons on the sample was calculated for each wavelength by using a silicon photodiode calibrated by The National Institute of Standards and Technology (NIST). The internal quantum efficiency (IQE) of each OPV cell was calculated using: IQE (%)=EQE (%)/(100%−Reflectance (%)−Parasitic Absorption (%)). The reflectance spectra were collected with the integrating sphere using the same EQE system while the parasitic absorption spectra were obtained from transfer matrix modelling. A Bruker AFM was used to image the surface of the various layers in tapping mode.

In certain embodiments, electron microscopy and x-ray diffraction measurements are performed. TEM analyses were performed using a FEI Titan 80-300 TEM equipped with an electron monochromator and a Gatan Imaging Filter (GIF) Quantum 966. GIWAXS characterization of active layer was performed at beamline 7.3.3, Advanced Light Source (ALS), Lawrence Berkeley National Lab (LBNL). X-ray energy was 10 keV and operated in top off mode. The scattering intensity was recorded on a 2D image plate (Pilatus 2M). The GIWAXS experiment was done in a closed chamber purged with Helium gas to suppress air scattering. The chamber was sealed using kapton films, which give rise to blank cell scattering features.

In certain embodiments, EPR measurements can be performed. All EPR spectra were recorded using X-band continuous wave Bruker EMX PLUS spectrometer (BrukerBioSpin, Rheinstetten, Germany) equipped with standard resonator for high sensitivity continuous-wave electron paramagnetic resonance and operating at (9.384688) GHz. The low temperature (100 K) spectra were measured using a liquid helium setup with 25 dB microwave attenuation with 5 GHz modulation amplitude and 100 kHz modulation frequency.

In certain embodiments, density functional theory calculations can be performed. The results were obtained with Density Functional Theory (DFT) calculations using the NWChem code, the hybrid B3LYP exchange-correlation functional, and the DZVP DFT Orbital basis. We have also obtained results with the less accurate 6-31 g* and 6-311 g* basis to facilitate comparison with previous theoretical studies. The HOMO and LUMO levels were rendered with VESTA.

In certain embodiments, light-intensity dependence measurements are performed. Light-intensity dependence measurements were performed with PAIOS instrumentation (Fluxim) (steady-state and transient modes). Transient photo-voltage (TPV) measurements monitor the photovoltage decay upon a small optical perturbation during various constant light-intensity biases and at open-circuit bias condition. Variable light-intensity biases lead to a range of measured V_{OC} values that were used for the analysis. During the measurements a small optical perturbation (<3% of the V_{OC}, so that ΔV_{OC}<<V_{OC}) is applied. The photovoltage decay kinetics of all devices follow a mono-exponential decay: δV=A exp(−t/τ), where t is the time and r is the charge carrier lifetime. The “charge extraction” (CE) technique was used to measure the charge carrier density n under open-circuit voltage condition. The device is illuminated and kept in open-circuit mode. After light turn-off, the voltage is switched to zero or taken to short-circuit condition to extract the charges. To obtain the number of extracted charges, the current is integrated. The carrier lifetimes follow a power law relationship with charge density: τ=τ₀n^{-λ}. The bimolecular recombination constant k_{rec} was then inferred from the carrier lifetimes and densities according to k_{rec}=1/(λ+1)/nτ², where is the recombination order.

In certain embodiments transient absorption spectroscopy is performed. Transient absorption (TA) spectroscopy was carried out using a home-built pump-probe setup. The output of titanium:sapphire amplifier (Coherent LEGEND DUO, 4.5 mJ, 3 kHz, 100 fs) was split into three beams (2 mJ, 1 mJ, and 1.5 mJ). Two of them were used to separately pump two optical parametric amplifiers (OPA) (Light Conversion TOPAS Prime). The TOPAS 1 generates pump pulses to excite the sample, while the TOPAS 2 generates signal (1300 nm) and idler (2000 nm) only. We used the TOPAS 1 for producing pump pulses while the probe pathway length to the sample was kept constant at approximately 5 meters between the output of the TOPAS 1 and the sample. The pump pathway length was varied between 5.12 and 2.6 m with a broadband retroreflector mounted on automated mechanical delay stage (Newport linear stage IMS600CCHA controlled by a Newport XPS motion controller), thereby generating delays between pump and probe from −400 ps to 8 ns. For measuring TA whole visible range, we used 1300 nm (signal) of TOPAS 2 to produce white-light super continuum from 350 to 1100 nm. The transmitted fraction of the white light was guided to a custom-made prism spectrograph (Entwicklungsburo Stresing) where it was dispersed by a prism onto a 512 pixel NMOS linear image sensor (Hamamatsu S8381-512). The probe pulse repetition rate was 3 kHz, while the excitation pulses were mechanically chopped to 1.5 kHz (100 fs to 8 ns delays) while the detector array was read out at 3 kHz. Adjacent diode readings corresponding to the transmission of the sample after excitation and in the absence of an excitation pulse were used to calculate ΔT/T. Measurements were averaged over several thousand shots to obtain a good signal-to-noise ratio. The chirp induced by the transmissive optics was corrected with a home-built Matlab code. The delay at which pump and probe arrive simultaneously on the sample (i.e. zero time) was determined from the point of maximum positive slope of the TA signal rise for each wavelength.

Other embodiments of the present disclosure are possible. Although the description above contains much specificity, these should not be construed as limiting the scope of the disclosure, but as merely providing illustrations of some of the presently preferred embodiments of this disclosure. It is also contemplated that various combinations or sub-combinations of the specific features and aspects of the embodiments may be made and still fall within the scope of this disclosure. It should be understood that various features and aspects of the disclosed embodiments can be combined with or substituted for one another in order to form various embodiments. Thus, it is intended that the scope of at least some of the present disclosure should not be limited by the particular disclosed embodiments described above.

Thus the scope of this disclosure should be determined by the appended claims and their legal equivalents. Therefore, it will be appreciated that the scope of the present disclosure fully encompasses other embodiments which may become obvious to those skilled in the art, and that the scope of the present disclosure is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present disclosure, for it to be encompassed by the present claims. Furthermore, no element, component, or method step in the present disclosure is intended to be dedicated to the public regardless of whether the element, component, or method step is explicitly recited in the claims.

The foregoing description of various preferred embodiments of the disclosure has been presented for purposes of illustration and description. It is not intended to be exhaustive or to limit the disclosure to the precise embodiments, and obviously many modifications and variations are possible in light of the above teaching. The example embodiments, as described above, were chosen and described in order to best explain the principles of the disclosure and its practical application to thereby enable others skilled in the art to best utilize the disclosure in various embodiments and with various modifications as are suited to the particular use contemplated. It is intended that the scope of the disclosure be defined by the claims appended hereto.

The following examples are intended to illustrate the above invention and should not be construed as to narrow its scope. One skilled in the art will readily recognize that the Examiners suggest many other ways in which the invention could be practiced. It should be understood that numerous variations and modifications may be made while remaining within the scope of the invention. These and other examples are within the scope of the following claims.

### EXAMPLES

### Example 1

### Benzyl Viologen Dopant Solution Preparation

To prepare the benzyl viologen (BV) dopant solution, 1,1′-dibenzyl-4,4′-bipyridinium dichloride hydrate (51 mg/0.12 mmol) was dissolved in distilled water (4.5 mL). Toluene (9.0 mL) was slowly dropped on the aqueous layer, and sodium borohydride (97 mg/2.5 mmol) was added into the bilayer system. The colourless aqueous layer immediately became a deep violet color with the generation of hydrogen gas. After 12 h, the aqueous layer became colourless while the top toluene layer became yellow. The toluene layer was separated and removed under vacuum for solvent exchange in chlorobenzene (CB) or chloroform (CF).

### Example 2

### Ethyl Viologen Dopant Solution Preparation

To prepare the ethyl viologen (EV) dopant solution, ethyl viologen dibromide (51 mg/0.12 mmol) was dissolved in distilled water (4.5 mL). Toluene (9.0 mL) was slowly dropped on the aqueous layer, and sodium borohydride (97 mg/2.5 mmol) was added into the bilayer system. After sodium borohydride addition, there is a generation of hydrogen gas. After 12 h, the toluene layer was separated and removed under vacuum for solvent exchange in chlorobenzene (CB) or chloroform (CF).

### Example 3

### Diquat Dopant Solution Preparation

To prepare the diquat (DQ) dopant solution, diquat dibromide monohydrate (51 mg/0.12 mmol) was dissolved in distilled water (4.5 mL). Toluene (9.0 mL) was slowly dropped on the aqueous layer, and sodium borohydride (97 mg/2.5 mmol) was added into the bilayer system. The colourless aqueous layer immediately became a red color with the generation of hydrogen gas. After 12 h, the aqueous layer became colourless while the top toluene layer became yellow. The toluene layer was separated and removed under vacuum for solvent exchange in chlorobenzene (CB) or chloroform (CF).

### Example 4

### N-DMBI Dopant Solution Preparation

To prepare the N-DMBI dopant solution, N-DMBI powder received from Sigma Aldrich was dissolved in chlorobenzene with concentration of 1 mg/ml.

### Example 5

Solar Cell Fabrication (BV-doped PM6:IT-4F)

PM6 (51.2 kDa), IT-4F, Y6, IT-2Cl, and PC₇₁BM were purchased from Solarmer Materials Inc. PTB7-Th (57.5 kDa) was purchased from 1-Materials Inc. EH-IDTBR was synthesized in-house.

The ZnO precursor solution was prepared by dissolving 200 mg of zinc acetate dihydrate in 2 mL of 2-methoxyethanol and 60 ul of 2-methoxyethanol. For the BHJ solutions, the PM6:IT-4F materials were dissolved in CB with the 1,8-diiodooctane (DIO) (0.5%, v/v). Addition of BV was performed by adding the required amount of solution directly into the BHJ solution using the same solvent. Indium tin oxide (ITO) coated glass substrates (Kintec Company, 10 Ωsq.⁻¹) were cleaned by sequential ultrasonication in dilute Extran 300 detergent solution, deionized water, acetone, and isopropyl alcohol for 10 min each. The substrates were then subjected to a UV-ozone treatment step for 20 min. Next, ZnO precursor solution was spin-coated onto the substrates and then dried on a heating plate at 200° C. for 0.5 h. The samples were then transferred into a dry nitrogen glove box (≈10 ppm O₂). The active solutions were then spun to obtain active-layer thickness in the narrow range of 95-105 nm. Finally, the samples were placed in a thermal evaporator and 7 nm of MoO₃ and 100 nm of silver were then thermally evaporated at 5×10⁻⁷ mbar through a 0.1 cm² pixel area shadow mask.

### Example 6

### Solar Cell Fabrication (BV-doped PM6:IT-2Cl)

For the BHJ solution, the PM6:IT-2Cl (D:A=1:1, 20 mg mL⁻¹ in total) materials were dissolved in CB with the 1,8-diiodooctane (DIO) (0.5%, v/v). Addition of BV was performed by adding the required amount of solution directly into the BHJ solution using the same solvent. Indium tin oxide (ITO) coated glass substrates (Kintec Company, 10 Ωsq.⁻¹) were cleaned by sequential ultrasonication in dilute Extran 300 detergent solution, deionized water, acetone, and isopropyl alcohol for 10 min each. The substrates were then subjected to a UV-ozone treatment step for 20 min. Next, ZnO precursor solution was spin-coated onto the substrates and then dried on a heating plate at 200° C. for 0.5 h. The samples were then transferred into a dry nitrogen glove box (≈10 ppm O₂). The active solutions were then spun to obtain active-layer thickness in the narrow range of 95-105 nm. Finally, the samples were placed in a thermal evaporator and 7 nm of MoO₃ and 100 nm of silver were then thermally evaporated at 5×10⁻⁷ mbar through a 0.1 cm² pixel area shadow mask.

### Example 7

### Solar Cell Fabrication (BV-doped PM6:Y6:PC₇₁BM)

For the BHJ solution, the PM6:Y6:PC₇₁BM (D:A=1:1:0.2, 15 mg mL⁻¹ in total) was dissolved in CF with chloronaphthalene (CN) (0.5%, v/v). Addition of BV was performed by adding the required amount of solution directly into the BHJ solution using the same solvent. Indium tin oxide (ITO) coated glass substrates (Kintec Company, 10 Ωsq.⁻¹) were cleaned by sequential ultrasonication in dilute Extran 300 detergent solution, deionized water, acetone, and isopropyl alcohol for 10 min each. The substrates were then subjected to a UV-ozone treatment step for 20 min. Next, ZnO precursor solution was spin-coated onto the substrates and then dried on a heating plate at 200° C. for 0.5 h. The samples were then transferred into a dry nitrogen glove box (≈10 ppm O₂). The active solutions were then spun to obtain active-layer thickness in the narrow range of 150-160 nm. Finally, the samples were placed in a thermal evaporator and 7 nm of MoO₃ and 100 nm of silver were then thermally evaporated at 5×10⁻⁷ mbar through a 0.1 cm² pixel area shadow mask.

### Example 8

### Solar Cell Fabrication (BV-doped PM6:Y6)

For the BHJ solution, the PM6:Y6 (D:A=1:1.2, 15 mg mL⁻¹ in total) was dissolved in CF with chloronaphthalene (CN) (0.5%, v/v). Addition of BV was performed by adding the required amount of solution directly into the BHJ solution using the same solvent. Indium tin oxide (ITO) coated glass substrates (Kintec Company, 10 Ωsq.⁻¹) were cleaned by sequential ultrasonication in dilute Extran 300 detergent solution, deionized water, acetone, and isopropyl alcohol for 10 min each. The substrates were then subjected to a UV-ozone treatment step for 20 min. Next, ZnO precursor solution was spin-coated onto the substrates and then dried on a heating plate at 200° C. for 0.5 h. The samples were then transferred into a dry nitrogen glove box (≈10 ppm O₂). The active solutions were then spun to obtain active-layer thickness in the narrow range of 150-160 nm. Finally, the samples were placed in a thermal evaporator and 7 nm of MoO₃ and 100 nm of silver were then thermally evaporated at 5×10⁻⁷ mbar through a 0.1 cm² pixel area shadow mask.

### Example 9

### Solar Cell Fabrication (BV-doped PTB7-Th:EH-IDTBR)

For the BHJ solution, the PTB7-Th:EH-IDTBR (D:A=1:2, 30 mg mL⁻¹ in total) was dissolved in CB. Addition of BV was performed by adding the required amount of solution directly into the BHJ solution using the same solvent. Indium tin oxide (ITO) coated glass substrates (Kintec Company, 10 Ωsq.⁻¹) were cleaned by sequential ultrasonication in dilute Extran 300 detergent solution, deionized water, acetone, and isopropyl alcohol for 10 min each. The substrates were then subjected to a UV-ozone treatment step for 20 min. Next, ZnO precursor solution was spin-coated onto the substrates and then dried on a heating plate at 200° C. for 0.5 h. The samples were then transferred into a dry nitrogen glove box (˜10 ppm O₂). The active solutions were then spun to obtain active-layer thickness in the narrow range of 95-105 nm. Finally, the samples were placed in a thermal evaporator and 7 nm of MoO₃ and 100 nm of silver were then thermally evaporated at 5×10⁻⁷ mbar through a 0.1 cm² pixel area shadow mask.

### Example 10

### Solar Cell Fabrication (BV-doped PTB7-Th:PC₇₁BM)

For the BHJ solution, the PTB7-Th:PC₇₁BM (D:A=1:1.5, 25 mg mL⁻¹ in total) was dissolved in CB with the DIO (3%, v/v). Addition of BV was performed by adding the required amount of solution directly into the BHJ solution using the same solvent. Indium tin oxide (ITO) coated glass substrates (Kintec Company, 10 Ωsq.⁻¹) were cleaned by sequential ultrasonication in dilute Extran 300 detergent solution, deionized water, acetone, and isopropyl alcohol for 10 min each. The substrates were then subjected to a UV-ozone treatment step for 20 min. Next, ZnO precursor solution was spin-coated onto the substrates and then dried on a heating plate at 200° C. for 0.5 h. The samples were then transferred into a dry nitrogen glove box (≈10 ppm O₂). The active solutions were then spun to obtain active-layer thickness in the narrow range of 95-105 nm. Finally, the samples were placed in a thermal evaporator and 7 nm of MoO₃ and 100 nm of silver were then thermally evaporated at 5×10⁻⁷ mbar through a 0.1 cm² pixel area shadow mask.

### Example 11

### Solar Cell Fabrication (EV-doped PM6:IT-4F)

For the BHJ solutions, the PM6:IT-4F materials were dissolved in CB with the 1,8-diiodooctane (DIO) (0.5%, v/v). Addition of EV was performed by adding the required amount of solution directly into the BHJ solution using the same solvent. Indium tin oxide (ITO) coated glass substrates (Kintec Company, 10 Ωsq.⁻¹) were cleaned by sequential ultrasonication in dilute Extran 300 detergent solution, deionized water, acetone, and isopropyl alcohol for 10 min each. The substrates were then subjected to a UV-ozone treatment step for 20 min. Next, PEDOT:PSS (CLEVIOS™ P VP AI 4083) solution was spin-coated onto the substrates and then dried on a heating plate at 150° C. for 10 min. The samples were then transferred into a dry nitrogen glove box (≈10 ppm O₂). The active solutions were then spun to obtain active-layer thickness in the narrow range of 95-105 nm. A layer of 3-5 nm of PFN—Br as electron transport layer (ETL) was spun from methanol solution (0.5 mg mL⁻¹). Finally, the samples were placed in a thermal evaporator and 100 nm of aluminium was then thermally evaporated at 5×10⁻⁷ mbar through a 0.1 cm² pixel area shadow mask.

### Example 12

### Solar Cell Fabrication (DQ-Doped PM6:IT-4F)

For the BHJ solutions, the PM6:IT-4F materials were dissolved in CB with the 1,8-diiodooctane (DIO) (0.5%, v/v). Addition of DQ was performed by adding the required amount of solution directly into the BHJ solution using the same solvent. Indium tin oxide (ITO) coated glass substrates (Kintec Company, 10 Ωsq.⁻¹) were cleaned by sequential ultrasonication in dilute Extran 300 detergent solution, deionized water, acetone, and isopropyl alcohol for 10 min each. The substrates were then subjected to a UV-ozone treatment step for 20 min. Next, PEDOT:PSS (CLEVIOS™ P VP AI 4083) solution was spin-coated onto the substrates and then dried on a heating plate at 150° C. for 10 min. The samples were then transferred into a dry nitrogen glove box (≈10 ppm O₂). The active solutions were then spun to obtain active-layer thickness in the narrow range of 95-105 nm. A layer of 3-5 nm of PFN—Br as electron transport layer (ETL) was spun from methanol solution (0.5 mg mL⁻¹). Finally, the samples were placed in a thermal evaporator and 100 nm of aluminium was then thermally evaporated at 5×10⁻⁷ mbar through a 0.1 cm² pixel area shadow mask.

### Example 13

### Solar Cell Fabrication (DQ-Doped PM6:Y6:PC₇TBM)

For the BHJ solution, the PM6:Y6:PC₇₁BM (D:A=1:1:0.2, 15 mg mL⁻¹ in total) was dissolved in CF with chloronaphthalene (CN) (0.5%, v/v). Addition of DQ was performed by adding the required amount of solution directly into the BHJ solution using the same solvent. Indium tin oxide (ITO) coated glass substrates (Kintec Company, 10 Ωsq.⁻¹) were cleaned by sequential ultrasonication in dilute Extran 300 detergent solution, deionized water, acetone, and isopropyl alcohol for 10 min each. The substrates were then subjected to a UV-ozone treatment step for 20 min. Next, PEDOT:PSS (CLEVIOS™ P VP AI4083) solution was spin-coated onto the substrates and then dried on a heating plate at 150° C. for 10 min. The samples were then transferred into a dry nitrogen glove box (≈10 ppm O₂). The active solutions were then spun to obtain active-layer thickness in the narrow range of 150-160 nm. A layer of 3-5 nm of PFN—Br as electron transport layer (ETL) was spun from methanol solution (0.5 mg mL⁻¹). Finally, the samples were placed in a thermal evaporator and 100 nm of aluminium was then thermally evaporated at 5×10⁻⁷ mbar through a 0.1 cm² pixel area shadow mask.

### Example 14

### Solar Cell Fabrication (N-DMBI-doped PM6:IT-4F)

For the BHJ solutions, the PM6:IT-4F materials were dissolved in CB with the 1,8-diiodooctane (DIO) (0.5%, v/v). Addition of N-DMBI was performed by adding the required amount of solution directly into the BHJ solution using the same solvent. Indium tin oxide (ITO) coated glass substrates (Kintec Company, 10 Ωsq.⁻¹) were cleaned by sequential ultrasonication in dilute Extran 300 detergent solution, deionized water, acetone, and isopropyl alcohol for 10 min each. The substrates were then subjected to a UV-ozone treatment step for 20 min. Next, PEDOT:PSS (CLEVIOS™ P VP AI4083) solution was spin-coated onto the substrates and then dried on a heating plate at 150° C. for 10 min. The samples were then transferred into a dry nitrogen glove box (≈10 ppm O₂). The active solutions were then spun to obtain active-layer thickness in the narrow range of 95-105 nm. A layer of 3-5 nm of PFN—Br as electron transport layer (ETL) was spun from methanol solution (0.5 mg mL⁻¹). Finally, the samples were placed in a thermal evaporator and 100 nm of aluminium was then thermally evaporated at 5×10⁻⁷ mbar through a 0.1 cm² pixel area shadow mask.

1. A photoactive region of an organic photovoltaic cell, the photoactive region comprising: an n-type dopant or mixture of n-type dopants, one or more electron donor materials, and one or more electron acceptor materials.

2. The photoactive region according to claim 1, wherein the n-type dopant is represented by formula I: 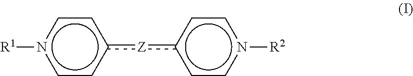
where: [symbol]
is a single or double bond;
Z is nothing, substituted or unsubstituted carboaryl, substituted or unsubstituted heteroaryl, substituted or unsubstituted alkenyl, substituted or unsubstituted cycloalkylene, or substituted or unsubstituted alkynylene;
R¹ and R² may be identical or different and each may be independently selected from a lone pair of electrons, hydrogen atom, substituted or unsubstituted alkyl, substituted or unsubstituted cycloalkyl, substituted or unsubstituted aryl, substituted or unsubstituted aralkyl, substituted or unsubstituted alkaryl, and substituted or unsubstituted heteroaryl.

3. The photoactive region of claim 1, wherein the n-type dopant is represented by formula II: 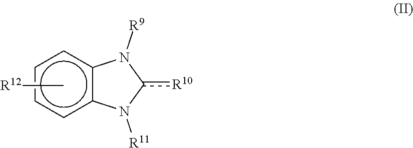
where: [symbol]
is a single or double bond;
R⁹ and R¹¹ may be identical or different and each may be independently selected from nothing, hydrogen, and substituted or unsubstituted alkyl;
R¹⁰ is a substituted or unsubstituted aryl or substituted or unsubstituted heteroaryl; and
R¹² is nothing or a substituent.

4. The photoactive region of claim 1, wherein the n-type dopant is represented by formula III: 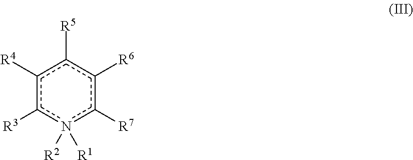
where: [symbol]
is a single or double bond; and
each of R¹ to R⁷ is independently a hydrogen, a substituted or unsubstituted C₁ to C₄ alkyl, or an amine, or at least two of R¹ to R⁷ bind with each other to form a 5- or 6-membered fused ring structure, wherein the 5- or 6-membered fused ring structure is optionally substituted, optionally comprises one or more nitrogen heteroatoms, and is optionally fused to one or more additional aliphatic or aromatic 5- or 6-membered ring structures, each ring structure optionally comprising one or more nitrogen heteroatoms.

5. The photoactive region of claim 1, wherein the n-type dopant comprises one or more of compounds (1) to (21):

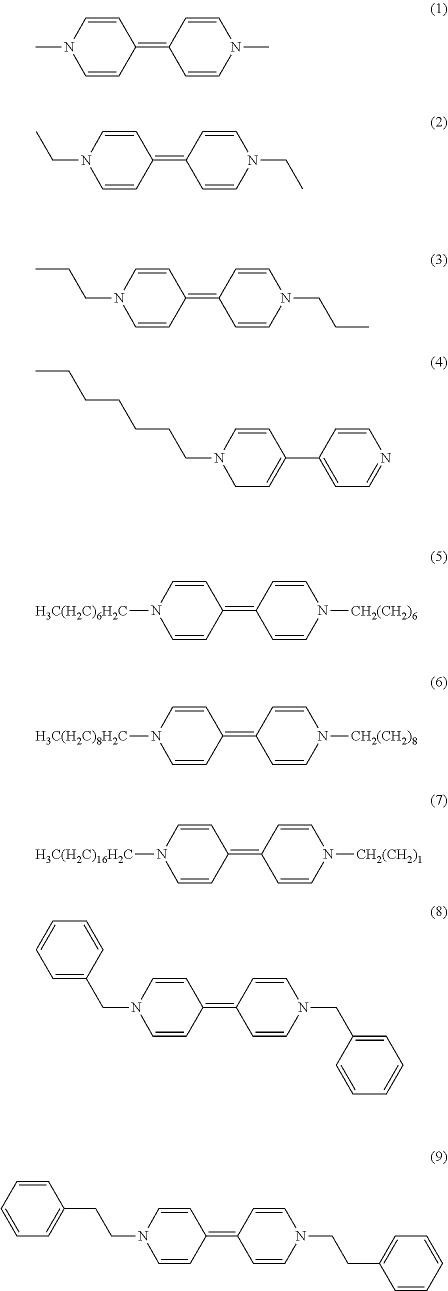

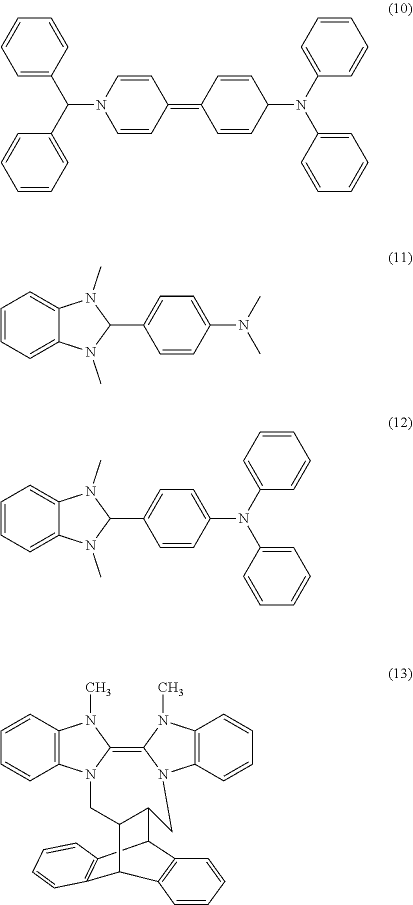 [SMILES: C1=CC(N(c2ccccc2)c2ccccc2)C=CC1=C1C=CN(C(c2ccccc2)c2ccccc2)C=C1 ; CN(C)c1ccc(C2N(C)c3ccccc3N2C)cc1 ; CN1c2ccccc2N(C)C1c1ccc(N(c2ccccc2)c2ccccc2)cc1 ; CN1/C2=C3\N(C)c4ccccc4N3CC3C4c5ccccc5C(c5ccccc54)C3CN2c2ccccc21]

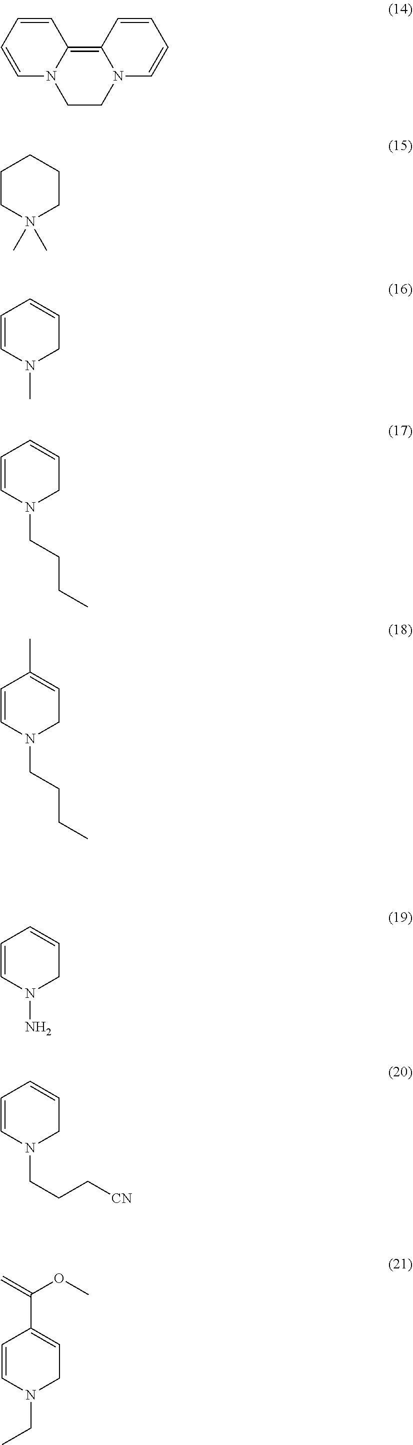

6. The photoactive region of claim 1, wherein the n-type dopant comprises one or more of benzyl viologen, ethyl viologen, diquat, and N-DMBI.

7. The photoactive region of claim 1, wherein the photoactive region comprises one or more of the following electron donor materials: poly[(2,6-(4,8-bis(5-(2-ethylhexyl-3-fluoro)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-c′]dithiophene-4,8-dione)] (known as PM6 or PBDB-T-2F), poly([2,6′-4,8-di(5-ethylhexylthienyl)benzo[1,2-b;3,3-b]dithiophene]{3-fluoro-2[(2-ethylhexyl)carbonyl]thieno[3,4-b]thiophenediyl}) (PTB7-Th), poly[(2,6-(4,8-bis(5-(2-ethylhexyl)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-c′]dithiophene-4,8-dione)] (PBDB-T), poly[(2,6-(4,8-bis(5-(2-ethylhexyl-3-chloro)thiophen-2-yl)-benzo[1,2-b:4,5-b′]dithiophene))-alt-(5,5-(1′,3′-di-2-thienyl-5′,7′-bis(2-ethylhexyl)benzo[1′,2′-c:4′,5′-c′]dithiophene-4,8-dione)] (known as PM7 or PBDB-T-2Cl), poly(3-hexylthiophene) (P3HT), poly[4,8-bis-(2-ethyl-hexyl-thiophene-5-yl)-benzo[1,2-b:4,5-b′]di-thiophene-2,6-diyl]-alt-[2-(2′-ethyl-hexanoyl)-thieno[3,4-b]thiophen-4,6-diyl] (PBDTTT-CT), poly[N-9′-hepta-decanyl-2,7-carbazole-alt-5,5-(4′,7′-di-2-thienyl-2′,1′,3-′-enzothiadiazole)] (PCDTBT), poly[6-fluoro-2,3-bis-(3-octyloxyphenyl) quinoxaline-5,8-diyl-alt-thiophene-2,5-diyl] (FTQ), subphthalocyanine (SubPC), copper phthalocyanine (CuPc), Zinc phthalocyanine (ZnPc), poly(3-hexylthiophene) (P3HT), poly(3-octylthiophene) (P3OT), poly(3-hexyloxythiophene) (P3DOT), poly(3-methylthiophene) (PmeT), poly(3-dodecylthiophene) (P3DDT), poly(3-dodecylthienylenevinylene) (PDDTV), poly(3,3 dialkylquarterthiophene) (PQT), poly-dioctyl-fluorene-co-bithiophene (F8T2), Poly[[4,8-bis[(2-ethylhexyl)oxy]benzo[1,2-b:4,5-b′]dithiophene-2,6-diyl][-3-fluoro-2-[(2-ethylhexyl)carbonyl]thieno[3,4-b]thiophenediyl]] (PTB7), poly-(2,5-bis(3-alkylthiophene-2-yl)thieno[3,2-b]thiophene) (PBTTT-C12), poly[2,7-(9,9′-dihexylfluorene)-alt-2,3-dimethyl-5,7-dithien-2-yl-2,1,3-b-enzothiadiazole] (PFDDTBT), poly{[2,7-(9,9-bis-(2-ethylhexyl)-fluorene)]-alt-[5,5-(4,7-di-20-thienyl-2,1,-3-benzothiadiazole)]} (BisEH-PFDTBT), poly{[2,7-(9,9-bis-(3,7-dimethyl-octyl)-fluorene)]-alt-[5,5-(4,7-di-20-th-ienyl-2,1,3-benzothiadiazole)]} (BisDMO-PFDTBT), poly[N-9′″-hepta-decanyl-2,7-carbazole-alt-5,5-(4′,7′-di-2-thienyl-2′,1′,-3′-benzothiadiazole)] (PCDTBT), poly[4,8-bis-substituted-benzo[1,2-b:4,5-b′]dithiophene-2,6-diyl-alt-4-substituted-thieno[3,4-b]thio-phene-2,6-diyl] (PBDTTT-C-T), Poly(benzo[1,2-b:4,5-b′]dithiophene-alt-thieno[3,4-c]pyrrole-4,6-dione (PBDTTPD), poly((4,4-dioctyldithieno(3,2-b:2′,3′-d)silole)-2,6-diyl-alt-(2,1,3-benzo-thiadiazole)-4,7-diyl) (PSBTBT), derivatives thereof, and combinations thereof.

8. The photoactive region of claim 1, wherein the photoactive region comprises one or more of the following electron acceptor materials: 2,2′-((2Z,2′Z)-((12,13-bis(2-ethylhexyl)-3,9-diundecyl-12,13-dihydro-[1,2,5]thiadiazolo[3,4-e]thieno[2,″30″:4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1-diylidene))dimalononitrile (Y6), [6,6]-phenyl-C71-butyric acid methyl ester (PC₇₁BM), 2,2′-((2Z, 2′Z)-((6,6,12,12-tetrakis(4-hexylphenyl)-6,12-dihydro-s-indaceno[1,2-b:5,6-b′]dithieno[3,2-b]thiophene-2,8-diyl)bis(methaneylylidene))bis(dichloro-3-oxo-2,3-dihydro-1H-indene-2,1-diylidene))dimalononitrile (IT-2Cl), 2,2′-((2Z, 2′Z)-((6,6,12,12-tetrakis(4-hexylphenyl)-6,12-dihydro-s-indaceno[1,2-b:5,6-b′]dithieno[3,2-b]thiophene-2,8-diyl)bis(methaneylylidene))bis(5,6-dichloro-3-oxo-2,3-dihydro-1H-indene-2,1-diylidene))dimalononitrile (IT-4Cl), IT-4F, ((5Z,5′Z)-5,5′-(((4,4,9,9-tetraoctyl-4,9-dihydro-s-indaceno[1,2-b:5,6-b′]dithiophene-2,7-diyl)bis(benzo[c][1,2,5]thiadiazole-7,4-diyl))bis(methanylylidene))bis(3-ethyl-2-thioxothiazolidin-4-one)) (O-IDTBR) or its structural analogue comprising 2-ethylhexyl side chains (5E, 5′E)-5,5′-(((4,4,9,9-tetrakis(2-ethylhexyl)-4,9-dihydro-s-indaceno[1,2-b:5,6-b′]dithiophene-2,7-diyl)bis(benzo[c][1,2,5]thiadiazole-7,4-diyl))bis(methaneylylidene))bis(3-ethyl-2-thioxothiazolidin-4-one) (EH-IDTBR), polypoly[[4,8-bis[5-(2-ethylhexyl)thiophene-2-yl]benzo[1,2-b;4,5-b′]dithiophene-2,6-diyl][3-fluoro-2-[(2-ethylhexyl)carbonyl]-thieno[3,4-b]thiophenediyl]], [6,6]-phenyl-C61-butyric acid (PC61BM), [6,6]-(4-fluoro-phenyl)-C61-butyric acid methyl ester (FPCBM), [6,6]-phenyl-C71 butyric acid methyl ester (PC₇₁BM), indene-C60 bisadduct (IC60BA), indene-C70 bisadduct (IC70BA), fullerene-C60, fullerene-C70, carbon nanotubes (CNT), a carbon onion, 3,4,9,10-perylenetetracarboxylic-bis-benzimidazole (PTCBI), perylenetetracarboxylic dianhydride (PTCDA), P(NDI2OD-T2), PNDIT, PNDIS-HD, PNDTI-BT-DT, PPDI2T, PPDIC, PPDIDTT, YF25, NIDCS-HO, NIBT, Bis-PDI-T-MO, SDIPBI, PDI-2DTT, PDI, derivatives thereof, and combinations thereof.

9. The photoactive region of claim 1, wherein the one or more electron acceptor materials are selected from rhodanine-benzothiadiazole-coupled indacenodithiophene (IDTBR); indacenodithieno[3,2-b]thiophene, IT), end-capped with 2-(3-oxo-2,3-dihydroinden-1-ylidene)malononitrile (INCN) groups (ITIC); indaceno[1,2-b:5,6-b′]dithiophene and 2-(3-oxo-2,3-dihydroinden-1-ylidene)malononitrile (IEIC); 2,2′-((2Z,2′Z)-((5,5′-(4,4,9,9-tetrakis(4-hexylphenyl)-4,9-dihydro-s-indaceno[1,2-b:5,6-b′]dithiophene-2,7-diyl)bis(4-((2-ethylhexyl)-oxy)thiophene-5,2-diyl))bis(methanylylidene))bis(3-oxo-2,3-di-hydro-1H-indene-2,1-diylidene))dimalononitrile (IEICO); naphthalene diimide (NDI); bay-linked perylene bisimide (di-PBI); perylene bisimide (PBI); Benzotriazole-Containing End-Capped with Thiazolidine-2,4-dione (TD); Naphthalocyanine (NC); Phthalocyanine (PC); Naphtho[1,2-c:5,6-c′]bis[1,2,5]thiadiazole; (2E,2′E)-3,3′-(2,5-dimethoxy-1,4-phenylene)bis(2-(5-(4-(N-(2-ethylhexyl)-1,8-naphthalimide)yl)thiophen-2-yl)acrylonitrile) (NIDCS-MO); thieno[3,4-b] thiophene and 2-(1,1-dicyanomethylene)rhodanine combination (ATT-1); (3,9-bis(4-(1,1-dicyanomethylene)-3-methylene-2-oxo-cyclopenta[b]thiophen)-5,5,11,11-tetrakis(4-hexylphenyl)-dithieno[2,3-d′:2,3-d′]-s-indaceno[1,2-b:5,6-b′]-dithiophene (ITCC); Indanedione; Dicyannovinyl; Benzothiadiazole; Diketopyrolopyrrole; arylene diimide; IDIC; and combinations thereof.

10. The photoactive region of claim 1, wherein the photoactive region further comprises a hole-scavenger material selected from thiophene, acene, fluorine, carbazole, indacenodithieno thiophene, indacenothieno thiphene, benzodithiazole, thieny-benzodithiophene-dione, benzotriazole, diketopyrrolopyrrole, and combinations thereof.

11. The photoactive region of claim 1, wherein the n-type dopant or mixture of n-type dopants, one or more electron acceptor materials, and one or more electron donor materials are included in one or more layers of the photoactive region to form a bulk heterojunction, planar heterojunction, mixed heterojunction, or hybrid mixed-planar heterojunction.

12. An organic photovoltaic cell, comprising: at least a first electrode, a second electrode, and a photoactive region of claim 1.

13. An organic photovoltaic cell with a normal or inverted structure comprising a photoactive region of claim 1.

14. An organic photovoltaic cell with a normal or inverted tandem structure comprising a photoactive region of claim 1.

15. An organic photovoltaic cell with an organic/silicon tandem structure comprising a photoactive region of claim 1.
